(19) United States
(12) Patent Application Publication
(10) Pub. No.: US 2026/0219576 A1
(43) Pub. Date: Jul. 30, 2026

(54) ACTINIC RAY-SENSITIVE OR RADIATION-SENSITIVE RESIN COMPOSITION, RESIST FILM, PATTERN FORMING METHOD, AND METHOD FOR PRODUCING ELECTRONIC DEVICE

(71) Applicant: FUJIFILM Corporation, Tokyo (JP)

(72) Inventors: Akihiro Kaneko, Shizuoka (JP); Tomotaka Tsuchimura, Shizuoka (JP)

(73) Assignee: FUJIFILM Corporation, Tokyo (JP)

(21) Appl. No.: 19/573,304

(22) Filed: Mar. 20, 2026

Related U.S. Application Data
(63) Continuation of application No. PCT/JP2024/032029, filed on Sep. 6, 2024.

(30) Foreign Application Priority Data
Sep. 29, 2023 (JP) 2023-170588

(51) Int. Cl. G03F 7/039; G03F 7/20

(52) U.S. Cl. CPC G03F 7/0397; G03F 7/2004

(57) ABSTRACT

A composition contains a resin (A), an onium salt (B-1), and an onium salt (B-2) as defined herein, the acid (AC_{B1}) has a pKa larger than a pKa of the acid (AC_{B2}) by 1.0 or more, the onium salt (B-1) has a specified structure and does not include fluorine atoms, or when the onium salt (B-1) includes a fluorine atom, a fluorine atom content relative to all atoms included in the onium salt (B-1) is 3 mass % or less, the onium salt (B-2) has a specified structure and does not include fluorine atoms, or when the onium salt (B-2) includes a fluorine atom, a fluorine atom content relative to all atoms included in the onium salt (B-2) is 3 mass % or less; a resist film, a pattern forming method, and a method for producing an electronic device including the pattern forming method.

### CROSS REFERENCE TO RELATED APPLICATION

This is a continuation of International Application No. PCT/JP2024/032029 filed on Sep. 6, 2024, and claims priority from Japanese Patent Application No. 2023-170588 filed on Sep. 29, 2023, the entire disclosures of which are incorporated herein by reference.

### BACKGROUND OF THE INVENTION

### 1. Field of the Invention

The present invention relates to an actinic ray-sensitive or radiation-sensitive resin composition, a resist film, a pattern forming method, and a method for producing an electronic device. More specifically, the present invention relates to an actinic ray-sensitive or radiation-sensitive resin composition that can be suitably used in ultramicrolithography processes applicable to, for example, processes for producing ultra-LSIs (Large Scale Integrations) and high-capacity microchips, processes for producing nanoimprint molds, and processes for producing high-density information recording media, and other photofabrication processes, a resist film, a pattern forming method, and a method for producing an electronic device.

### 2. Description of the Related Art

In fabrication processes for semiconductor devices such as ICs (Integrated Circuits) or LSIs (Large Scale Integrations), microprocessing by lithography using resist compositions has been performed. In recent years, with an increase in the degree of integration of integrated circuits, formation of ultrafine patterns in the submicron range or the quarter micron range has come to be in demand. With this, there is a trend for exposure wavelengths toward shorter wavelengths from the g-line to the i-line further to the KrF excimer laser beam; currently, exposure apparatuses using, as light sources, the ArF excimer laser having a wavelength of 193 nm have been developed. In addition, as a technique of further increasing the resolving power, a technique in which the space between a projection lens and a sample is filled with a liquid having a high refractive index (hereafter, also referred to as “immersion liquid”), what is called, the immersion method is being developed.

In addition, currently, lithography using, instead of excimer laser beams, an electron beam (EB), X-rays, extreme ultraviolet rays (EUV), or the like is also being developed. With this, resist compositions effectively sensitive to various actinic rays or radiations have been developed.

JP2018-49177A describes a radiation-sensitive resin composition containing a polymer having a structural unit including an acid-dissociable group and a specified radiation-sensitive acid generator.

JP2016-197242A describes a chemical amplification resist composition containing a polymer including a structural unit having a specified acid-dissociable group, a radiation-sensitive acid generator, and a compound that has a specified structure and generates upon exposure an acid relatively weaker than the acid generated from the radiation-sensitive acid generator upon exposure.

### SUMMARY OF THE INVENTION

There has recently been an increasing demand for higher performance for resist compositions. In particular, from the viewpoint of line width roughness (Line Width Roughness: LWR) performance and pattern profile (squareness of the cross-sectional profile of a pattern) when forming a pattern, there has been a demand for higher performance. The LWR performance refers to the performance of providing a pattern having a lower LWR.

Thus, an object of the present invention is to provide an actinic ray-sensitive or radiation-sensitive resin composition, a resist film, and a pattern forming method that can form a pattern having high LWR performance and a good pattern profile and a method for producing an electronic device including the pattern forming method.

The inventors of the present invention have found that the following features can address the above-described object.

[1]

An actinic ray-sensitive or radiation-sensitive resin composition including:
a resin (A) that is subjected to action of an acid to undergo an increase in polarity;
an onium salt (B-1) that generates an acid (AC_{B1}) upon irradiation with an actinic ray or a radiation; and
an onium salt (B-2) that generates an acid (AC_{B2}) upon irradiation with an actinic ray or a radiation,
wherein the acid (AC_{B1}) has a pKa larger than a pKa of the acid (AC_{B2}) by 1.0 or more, the onium salt (B-1) does not include fluorine atoms, or when the onium salt (B-1) includes a fluorine atom, a fluorine atom content relative to all atoms included in the onium salt (B-1) is 3 mass % or less,
the onium salt (B-2) does not include fluorine atoms, or when the onium salt (B-2) includes a fluorine atom, a fluorine atom content relative to all atoms included in the onium salt (B-2) is 3 mass % or less,
the onium salt (B-1) is at least one selected from the group consisting of an onium salt represented by a formula (b1-1) below and an onium salt represented by a formula (b1-2) below, and
the onium salt (B-2) is an onium salt represented by a formula (b2-1) below,

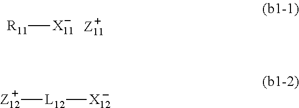

in the formula (b1-1) and the formula (b1-2), R₁₁ represents an organic group, L₁₂ represents a single bond or a divalent linking group, X₁₁⁻ represents —O⁻, —COO⁻, —SO₃⁻, or —SO₂N⁻Y₁₁(R₁₁₁)ₖ, R₁₁₁ represents an alkyl group, a cycloalkyl group, or an aryl group, Y₁₁ represents —CO—, —SO—, —SO₂—, or a single bond, k represents 0 or 1; when k represents 0, R₁₁₁ is not present, and Y₁₁ is bonded to R₁₁; when k represents 1, R₁₁₁ may be bonded to R₁₁; X₁₂⁻ represents —O⁻, —COO⁻, —SO₃⁻, or —SO₂N⁻Y₁₂(R₁₁₂)ₕ, R₁₁₂ represents an alkyl group, a cycloalkyl group, or an aryl group, Y₁₂ represents —CO—, —SO—, —SO₂—, or a single bond, h represents 0 or 1; when h represents 0, R₁₁₂ is not present, and Y₁₂ is bonded to L₁₂ or Z₁₂⁺; when h represents 1, R₁₁₂ may be bonded to L₁₂ or Z₁₂⁺; Z₁₁⁺ represents an organic cation, Z₁₂⁺ represents an organic cation group,
provided that R₁₁—X₁₁⁻ in the formula (b1-1) is not an anion represented by any of formulas (i)-1 to (i)-3 below,

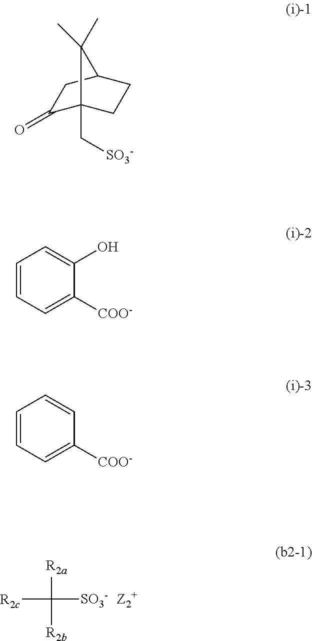

in the formula (b2-1), R₂ₐ represents an electron-withdrawing group, R_{2b} and R_{2c} each independently represent a hydrogen atom or an organic group, at least two selected from the group consisting of R₂ₐ, R_{2b}, and R_{2c} may be bonded together to form a ring, provided that R_{2b} and R_{2c} do not simultaneously represent hydrogen atoms, and Z₂⁺ represents an organic cation.
   [2]

The actinic ray-sensitive or radiation-sensitive resin composition according to [1], wherein, in the formula (b2-1), R₂ₐ represents a cyano group, a nitro group, a dicyanomethyl group, or a group represented by a formula (1A) below:

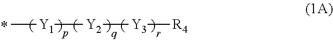

in the formula (1A), Y₁ and Y₃ each independently represent —O— or —NR₃—, R₃ represents a hydrogen atom or an alkyl group, Y₂ represents —C(═O)— or —SO₂—, R₄ represents an alkyl group, a cycloalkyl group, or an aryl group, at least two selected from the group consisting of R₃ and R₄ may be bonded together to form a ring, p and r each independently represent 0 or 1, q represents 1 or 2, and * represents a bonding site.
   [3]

The actinic ray-sensitive or radiation-sensitive resin composition according to [1] or [2], wherein the onium salt (B-1) is at least one selected from the group consisting of onium salts each represented by any one of formulas (b1-2a) to (b1-2e) below and the onium salt represented by the formula (b1-2):

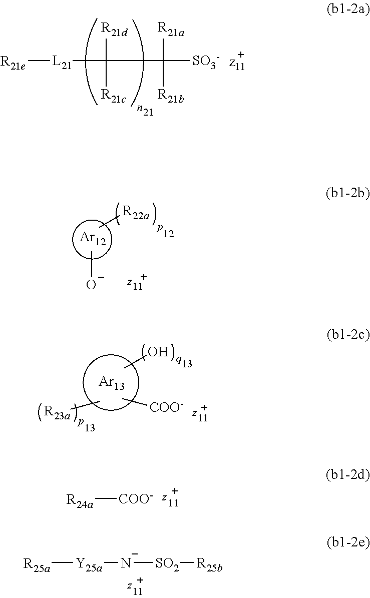

in the formula (b1-2a), R₂₁ₐ to R₂₁ₑ each independently represent a hydrogen atom or an organic group, provided that at least one selected from the group consisting of R_{21c} and R_{21d} represents a group selected from the group consisting of a cyano group, a nitro group, a group represented by a formula (2A) below, and a group represented by a formula (2B) below, and R₂₁ₐ and R_{21b} each do not represent groups selected from the group consisting of a cyano group, a nitro group, the group represented by the formula (2A) below, and the group represented by the formula (2B) below; L₂₁ represents a single bond or a divalent linking group, n₂₁ represents an integer of 1 to 4; when n₂₁ represents an integer of 2 or more, a plurality of R_{21c} may be the same or different, and a plurality of R_{21d} may be the same or different; at least two selected from the group consisting of R₂₁ₐ, R_{21b}, R_{21c}, R_{21d}, and L₂₁ may be bonded together to form a ring, Z₁₁⁺ represents an organic cation,

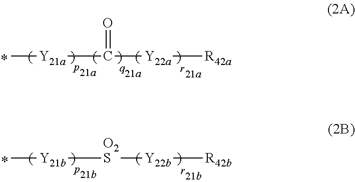

in the formula (2A), Y₂₁ₐ and Y₂₂ₐ each independently represent —O— or —NR₃₂ₐ—, R₃₂ₐ represents a hydrogen atom or an alkyl group, R₄₂ₐ represents an alkyl group, a cycloalkyl group, or an aryl group, p₂₁ₐ and r₂₁ₐ each independently represent 0 or 1, provided that p₂₁ₐ and r₂₁ₐ do not simultaneously represent 0, q₂₁ₐ represents 1 or 2, * represents a bonding site, in the formula (2B), Y_{21b} and Y_{22b} each independently represent —O— or —NR_{32b}—, R_{32b} represents a hydrogen atom or an alkyl group, R_{42b} represents an alkyl group, a cycloalkyl group, or an aryl group, p_{21b} and r_{21b} each independently represent 0 or 1, * represents a bonding site, in the formula (b1-2b), R₂₂ₐ represents a halogen atom, a hydroxy group, or an organic group other than a carboxyl group, Ar₁₂ represents an aromatic group, p₁₂ represents an integer of 0 or more; when p₁₂ represents an integer of 2 or more, a plurality of R₂₂ₐ may be the same or different; Z₁₁⁺ represents an organic cation,
in the formula (b1-2c), Ar₁₃ represents an aromatic group, R₂₃ₐ represents a halogen atom or an organic group, p₁₃ and q₁₃ each independently represent an integer of 0 or more; when p₁₃ represents an integer of 2 or more, a plurality of R₂₃ₐ may be the same or different, provided that p₁₃ and q₁₃ do not simultaneously represent 0; when q₁₃ represents 1, p₁₃ represents an integer of 1 or more; Z₁₁⁺ represents an organic cation,
in the formula (b1-2d), R₂₄ₐ represents an organic group, provided that when R₂₄ₐ has an aromatic ring, the carbon atom of —COO⁻ specified in the formula (b1-2d) is not directly bonded to the aromatic ring; Z₁₁⁺ represents an organic cation,
in the formula (b1-2e), Y₂₅ₐ represents —CO—, —SO—, —SO₂—, or a single bond, R₂₅ₐ and R_{25b} each independently represent an alkyl group, a cycloalkyl group, or an aryl group, R₂₅ₐ and R_{25b} may be bonded together to form a ring, and Z₁₁⁺ represents an organic cation.
   [4]

The actinic ray-sensitive or radiation-sensitive resin composition according to any one of [1] to [3], further including a resin (D) different from the resin (A), provided that the resin (D) satisfies a requirement (i) below:
(i) the resin (D) has an SP value that is smaller than an SP value of the resin (A) and is 17.2 or less.
   [5]

The actinic ray-sensitive or radiation-sensitive resin composition according to any one of [1] to [4], wherein the onium salt (B-1) does not include fluorine atoms.

[6]

The actinic ray-sensitive or radiation-sensitive resin composition according to any one of [1] to [5], wherein the onium salt (B-2) does not include fluorine atoms.

[7]

The actinic ray-sensitive or radiation-sensitive resin composition according to any one of [1] to [6], wherein the resin (A) has a repeating unit represented by a formula (AP-1) below:

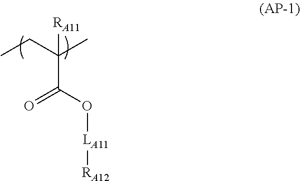

in the formula (AP-1), R_{A11} represents a hydrogen atom, a halogen atom, or an alkyl group, L_{A11} represents a single bond or a divalent linking group, and R_{A12} represents a cyclic group including an SO₂ group.
   [8]

The actinic ray-sensitive or radiation-sensitive resin composition according to any one of [1] to [7], wherein the resin (A) has a repeating unit represented by a formula (AP-2) below:

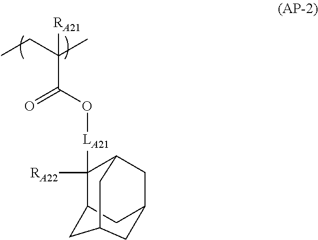

in the formula (AP-2), R_{A21} represents a hydrogen atom, a halogen atom, or an alkyl group, L_{A21} represents a single bond or a divalent linking group, and R_{A22} represents an alkyl group.
   [9]

The actinic ray-sensitive or radiation-sensitive resin composition according to any one of [1] to [8], wherein the resin (A) has a repeating unit represented by a formula (AP-3) below:

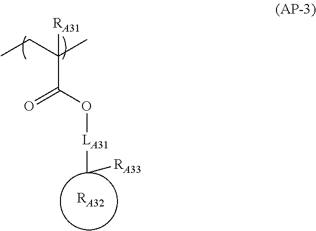

in the formula (AP-3), R_{A31} represents a hydrogen atom, a halogen atom, or an alkyl group, L_{A31} represents a single bond or a divalent linking group, R_{A32} represents an alicyclic hydrocarbon group, and R_{A33} represents a substituent having a double bond.
   [10]

The actinic ray-sensitive or radiation-sensitive resin composition according to [4], further satisfying all of requirements (ii) and (iii) below:
(ii) for repeating units of the resin (D), a total content of repeating units not including fluorine atoms relative to all repeating units in the resin (D) is 80 mol % or more; and
(iii) a content of the resin (D) relative to a total solid content in the actinic ray-sensitive or radiation-sensitive resin composition is 0.01 to 10 mass %.
   [11]

A resist film formed using the actinic ray-sensitive or radiation-sensitive resin composition according to any one of [1] to [10].

[12]

A pattern forming method including a step of using the actinic ray-sensitive or radiation-sensitive resin composition according to any one of [1] to [10] to form a resist film on a substrate; a step of exposing the resist film; and a step of developing the exposed resist film using a developer.

[13]

A method for producing an electronic device, the method including the pattern forming method according to [12].

The present invention can provide an actinic ray-sensitive or radiation-sensitive resin composition, a resist film, and a pattern forming method that can form a pattern having high LWR performance and a good pattern profile and a method for producing an electronic device including the pattern forming method.

### DESCRIPTION OF THE PREFERRED EMBODIMENTS

Hereinafter, the present invention will be described in detail.

Features may be described below on the basis of representative embodiments of the present invention; however, the present invention is not limited to such embodiments.

In this Specification, “actinic ray” or “radiation” means, for example, the emission line spectrum of a mercury lamp, far-ultraviolet rays represented by excimer lasers, extreme ultraviolet rays (EUV: Extreme Ultraviolet), X-rays, soft X-rays, or an electron beam (EB: Electron Beam).

In this Specification, “light” means an actinic ray or a radiation.

In this Specification, “exposure” includes, unless otherwise specified, not only exposure using, for example, the emission line spectrum of a mercury lamp, far-ultraviolet rays represented by excimer lasers, extreme ultraviolet rays, X-rays, or EUV, but also patterning using a corpuscular beam such as an electron beam or an ion beam.

In this Specification, “a value ‘to’ another value” is used to mean that it includes the value and the other value as the lower limit value and the upper limit value.

In this Specification, (meth)acrylate represents at least one of acrylate or methacrylate. (Meth)acrylic acid represents at least one of acrylic acid or methacrylic acid.

In this Specification, for resins, the weight-average molecular weight (Mw), the number-average molecular weight (Mn), and the dispersity (also referred to as molecular weight distribution) (Mw/Mn) are defined as polystyrene-equivalent values measured, using a GPC (Gel Permeation Chromatography) apparatus (HLC-8120GPC, manufactured by Tosoh Corporation), by GPC measurement (solvent: tetrahydrofuran, flow rate (sample injection amount): 10 μL, column: TSK gel Multipore HXL-M, manufactured by Tosoh Corporation, column temperature: 40° C., flow rate: 1.0 mL/min, detector: differential refractive index detector (Refractive Index Detector)).

In this Specification, for written forms of groups (atomic groups), written forms without referring to substituted or unsubstituted encompass, in addition to groups not having a substituent, groups including a substituent without departing from the spirit and scope of the present invention. For example, “alkyl group” encompasses not only alkyl groups not having a substituent (unsubstituted alkyl groups), but also alkyl groups having a substituent (substituted alkyl groups). In this Specification, “organic group” refers to a group including at least one carbon atom.

The substituent is preferably a monovalent substituent unless otherwise specified. Examples of the substituent include monovalent non-metallic atomic groups except for the hydrogen atom and, for example, can be selected from the group consisting of the following Substituents T.

### Substituents T

Examples of the substituents T include halogen atoms such as a fluorine atom, a chlorine atom, a bromine atom, and an iodine atom; alkoxy groups such as a methoxy group, an ethoxy group, and a tert-butoxy group; cycloalkyloxy groups; aryloxy groups such as a phenoxy group and a p-tolyloxy group; alkoxycarbonyl groups such as a methoxycarbonyl group and a butoxycarbonyl group; cycloalkyloxycarbonyl groups; aryloxycarbonyl groups such as a phenoxycarbonyl group; acyloxy groups such as an acetoxy group, a propionyloxy group, and a benzoyloxy group; acyl groups such as an acetyl group, a benzoyl group, an isobutyryl group, an acryloyl group, a methacryloyl group, and a methoxalyl group; a sulfanyl group; alkylsulfanyl groups such as a methylsulfanyl group and a tert-butylsulfanyl group; arylsulfanyl groups such as a phenylsulfanyl group and a p-tolylsulfanyl group; alkyl groups; alkenyl groups; cycloalkyl groups; aryl groups; aromatic heterocyclic groups; a hydroxy group; a carboxyl group; a formyl group; a sulfo group; a cyano group; alkylaminocarbonyl groups; arylaminocarbonyl groups; a sulfonamide group; a silyl group; an amino group; and a carbamoyl group. When such a substituent can additionally have one or more substituents, a group having, as the additional substituents, one or more substituents selected from the group consisting of the substituents described above (such as a monoalkylamino group, a dialkylamino group, an arylamino group, or a trifluoromethyl group) is also included in examples of the substituents T. Note that the substituents in the onium salt (A) and the onium salt (B) do not include fluorine atoms as the substituents T.

In this Specification, the bonding directions of divalent groups described are not limited unless otherwise specified. For example, in a compound represented by a formula “X—Y—Z” where Y is —COO—, Y may be —CO—O— or may be —O—CO—. The compound may be “X—CO—O—Z” or may be “X—O—CO—Z”.

In this Specification, the acid dissociation constant (pKa) represents pKa in an aqueous solution, specifically, a value determined using the following Software package 1, on the basis of the Hammett's substituent constant and the database of values in publicly known documents, by calculation. All the values of pKa described in this Specification are values determined by calculation using this software package.

Software package 1: Advanced Chemistry Development (ACD/Labs) Software V8.14 for Solaris (1994-2007 ACD/Labs)

Alternatively, pKa can be determined by a molecular orbital calculation method. Specifically, this method may be a calculation method of calculating H⁺ dissociation free energy in an aqueous solution based on a thermodynamic cycle. The H⁺ dissociation free energy can be calculated by a method such as DFT (density functional theory); however, the calculation method is not limited thereto and various other methods have been reported in documents and the like. Note that there are a plurality of pieces of software for performing DFT, such as Gaussian 16.

In this Specification, as described above, pKa refers to a value determined using Software package 1, on the basis of the Hammett's substituent constant and the database of values in publicly known documents, by calculation; however, when use of this method cannot determine pKa, a value determined on the basis of DFT (density functional theory) using Gaussian 16 is employed.

In this Specification, as described above, pKa refers to “pKa in an aqueous solution”; however, when pKa in an aqueous solution cannot be determined, “pKa in a dimethyl sulfoxide (DMSO) solution” is employed.

In this Specification, “solid content” means components forming a film (preferably a resist film) formed using the actinic ray-sensitive or radiation-sensitive resin composition and does not include solvents. As long as a component forms a film (preferably a resist film) formed using the actinic ray-sensitive or radiation-sensitive resin composition, even when the component has the form of liquid, it is regarded as the solid content.

### Actinic Ray-Sensitive or Radiation-Sensitive Resin Composition

An actinic ray-sensitive or radiation-sensitive resin composition of the present invention (also referred to as “composition of the present invention”) includes:
a resin (A) that is subjected to action of an acid to undergo an increase in polarity;
an onium salt (B-1) that generates an acid (AC_{B1}) upon irradiation with an actinic ray or a radiation; and
an onium salt (B-2) that generates an acid (AC_{B2}) upon irradiation with an actinic ray or a radiation,
wherein the acid (AC_{B1}) has a pKa larger than a pKa of the acid (AC_{B2}) by 1.0 or more,
the onium salt (B-1) does not include fluorine atoms, or when the onium salt (B-1) includes a fluorine atom, a fluorine atom content relative to all atoms included in the onium salt (B-1) is 3 mass % or less,
the onium salt (B-2) does not include fluorine atoms, or when the onium salt (B-2) includes a fluorine atom, a fluorine atom content relative to all atoms included in the onium salt (B-2) is 3 mass % or less,
the onium salt (B-1) is at least one selected from the group consisting of an onium salt represented by a formula (b1-1) below and an onium salt represented by a formula (b1-2) below, and
the onium salt (B-2) is an onium salt represented by a formula (b2-1) below,

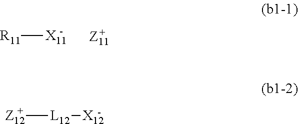

in the formula (b1-1) and the formula (b1-2), R₁₁ represents an organic group, L₁₂ represents a single bond or a divalent linking group, X₁₁⁻ represents —O—, —COO—, —SO₃—, or —SO₂N⁻Y₁₁(R₁₁₁)ₖ, R₁₁₁ represents an alkyl group, a cycloalkyl group, or an aryl group, Y₁₁ represents —CO—, —SO—, —SO₂—, or a single bond, k represents 0 or 1; when k represents 0, R₁₁₁ is not present, and Y₁₁ is bonded to R₁₁; when k represents 1, R₁₁ may be bonded to R₁₁; X₁₂⁻ represents —O—, —COO—, —SO₃—, or —SO₂N⁻Y₁₂(R₁₁₂)ₕ, R₁₁₂ represents an alkyl group, a cycloalkyl group, or an aryl group, Y₁₂ represents —CO—, —SO—, —SO₂—, or a single bond, h represents 0 or 1; when h represents 0, R₁₁₂ is not present, and Y₁₂ is bonded to L₁₂ or Z₁₂⁺; when h represents 1, R₁₁₂ may be bonded to L₁₂ or Z₁₂⁺; Z₁₂⁺ represents an organic cation, Z₁₂⁺ represents an organic cation group,
provided that R₁₁—X₁₁⁻ in the formula (b1-1) is not an anion represented by any of formulas (i)-1 to (i)-3 below,

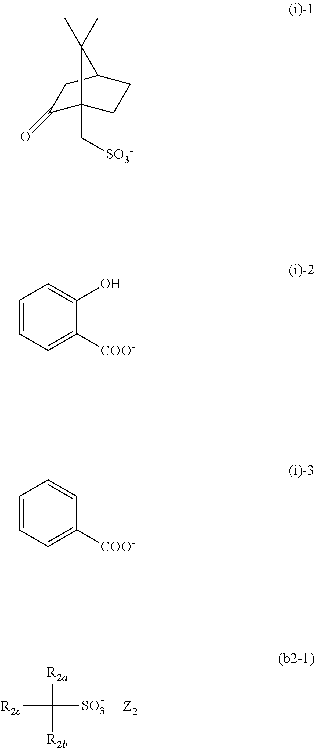

in the formula (b2-1), R₂ₐ represents an electron-withdrawing group, R_{2b} and R_{2c} each independently represent a hydrogen atom or an organic group, at least two selected from the group consisting of R₂ₐ, R_{2b}, and R_{2c} may be bonded together to form a ring, provided that R_{2b} and R_{2c} do not simultaneously represent hydrogen atoms, and Z₂⁺ represents an organic cation.

The mechanism by which the composition of the present invention can form a pattern having high LWR performance and a good pattern profile is not clear, but is inferred by the inventors of the present invention as follows. However, the present invention is not limited at all by the following inferred mechanism.

The acid (AC_{B1}) generated from the onium salt (B-1) upon irradiation with an actinic ray or a radiation has a pKa larger than the pKa of the acid (AC_{B2}) generated from the onium salt (B-2) upon irradiation with an actinic ray or a radiation by 1.0 or more; thus, in the composition of the present invention, the onium salt (B-2) can act as a compound (photoacid generator) that generates an acid for promoting the deprotection reaction of the acid-decomposable group of the resin (A) that is subjected to action of an acid to undergo an increase in polarity, and the onium salt (B-1) can act as a quencher (acid diffusion control agent) that traps acid generated from the photoacid generator and the like during exposure to inhibit the reaction of the resin (A) in the unexposed regions due to excess generated acid.

For each of the onium salt (B-1) and the onium salt (B-2), the onium salt does not include fluorine atoms or when the onium salt includes a fluorine atom, the fluorine atom content relative to all atoms included in the compound is 3 mass % or less. Hereafter, “onium salt does not include fluorine atoms or when the onium salt includes a fluorine atom, the fluorine atom content relative to all atoms included in the compound is 3 mass % or less” is also referred to as “the fluorine content is low” or “having a low fluorine content”. The onium salt (B-2) has a low fluorine content, hence has high compatibility with the resin (A), and is homogeneously dispersed. This suppresses variations in the concentration of the acid (AC_{B2}) generated from the onium salt (B-2) to thereby provide high LWR performance, inferentially. In addition, the onium salt (B-1) also has a low fluorine content and hence high compatibility is provided between the onium salt (B-1) and the onium salt (B-2). This can further suppress variations in the concentration of the acid (AC_{B2}) to further improve LWR performance, inferentially. The improvement in the pattern profile was an unexpected effect as described below. In general, the exposure dose increases to the resist film surface where the effect of absorption is smaller; and in order to form a pattern profile having an ideal squareness, the quencher may be adjusted so as to be slightly hydrophobic and localized in the resist film surface. When the onium salt (B-1) having a low fluorine content is used, there is a concern that the resist film has increased hydrophilicity and the pattern profile deteriorates; however, the pattern profile has been found to be rather improved. This is inferentially because the distributions of the onium salt (B-1) and the onium salt (B-2) are highly homogeneous, so that the effect of quenching the generated acid (AC_{B2}) without waste outweighs the variation in exposure dose due to the slight difference in absorption.

The composition of the present invention is typically a resist composition, and may be a positive resist composition or may be a negative resist composition. The composition of the present invention may be a resist composition for alkali development or may be a resist composition for organic-solvent development.

The composition of the present invention may be a chemical amplification resist composition or may be a non-chemical amplification resist composition. The composition of the present invention is preferably a chemical amplification resist composition.

The composition of the present invention can be used to form an actinic ray-sensitive or radiation-sensitive film. The actinic ray-sensitive or radiation-sensitive film formed using the composition of the present invention is typically a resist film.

Hereinafter, first, various components of the composition of the present invention will be described in detail.

### Onium Salt (B-1)

The onium salt (B-1) included in the composition of the present invention will be described.

The onium salt (B-1) is at least one selected from the group consisting of an onium salt represented by the following formula (b1-1) and an onium salt represented by the following formula (b1-2).

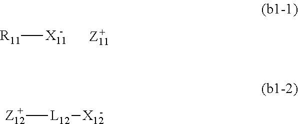

In the formula (b1-1) and the formula (b1-2), R₁₁ represents an organic group, L₁₂ represents a single bond or a divalent linking group, X₁₁⁻ represents —O—, —COO—, —SO₃—, or —SO₂N⁻Y₁₁(R₁₁₁)ₖ, R₁₁₁ represents an alkyl group, a cycloalkyl group, or an aryl group, Y₁₁ represents —CO—, —SO—, —SO₂—, or a single bond, k represents 0 or 1; when k represents 0, R₁₁₁ is not present, and Y₁₁ is bonded to R₁₁; when k represents 1, R₁₁₁ may be bonded to R₁₁; X₁₂⁻ represents —O—, —COO—, —SO₃—, or —SO₂N⁻Y₁₂(R₁₁₂)ₕ, R₁₁₂ represents an alkyl group, a cycloalkyl group, or an aryl group, Y₁₂ represents —CO—, —SO—, —SO₂—, or a single bond, h represents 0 or 1; when h represents 0, R₁₁₂ is not present, and Y₁₂ is bonded to L₁₂ or Z₁₂⁺; when h represents 1, R₁₁₂ may be bonded to L₁₂ or Z₁₂⁺; Z₁₂⁺ represents an organic cation, Z₁₂⁺ represents an organic cation group,
provided that R₁₁—X₁₁⁻ in the formula (b1-1) is not an anion represented by any of formulas (i)-1 to (i)-3 below.

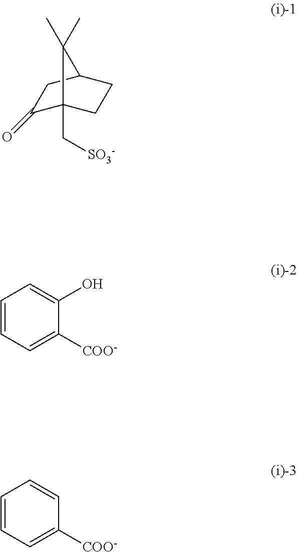

In the formula (b1-1), R₁₁ represents an organic group.
R₁₁ preferably represents a monovalent organic group, provided that when R₁₁ and Y₁₁ are bonded together and when R₁₁ and R₁₁₁ are bonded together, R₁₁ preferably represents a divalent organic group.

The organic group represented by R₁₁ is not particularly limited, but is preferably an alkyl group, a cycloalkyl group, an alkenyl group, an alkynyl group, an aryl group, a heteroaryl group, an aralkyl group, an alkoxy group, an aryloxy group, a carboxyl group, an acyl group, an acyloxy group, a formyloxy group, an alkoxycarbonyl group, an alkylsulfoxy group, an arylsulfoxy group, an alkylsulfonyl group, an arylsulfonyl group, —OCO(OR₈), or —OCO(NR₉R₁₀). R₈, R₉, and R₁₀ each independently represent a hydrogen atom, an alkyl group, a cycloalkyl group, an alkenyl group, an alkynyl group, an aryl group, a heteroaryl group, or an aralkyl group.

The alkyl group, cycloalkyl group, alkenyl group, alkynyl group, aryl group, heteroaryl group, aralkyl group, alkoxy group, aryloxy group, carboxyl group, acyloxy group, formyloxy group, alkoxycarbonyl group, alkylsulfoxy group, and arylsulfoxy group represented by R₁₁ may further have one or more substituents. For example, the alkyl group may be substituted with a hydroxy group. The hydrogen atom of the carboxyl group may be substituted with a substituent.

The groups represented by R₁₁ will be described below.

The number of carbon atoms of the alkyl group is not particularly limited, but, for example, may be 1 to 20, may be 1 to 10, or may be 1 to 6. The alkyl group may be either linear or branched. Examples of the alkyl group include a methyl group, an ethyl group, an n-propyl group, an i-propyl group, an n-butyl group, a t-butyl group, and an n-hexyl group. For the alkyl group moiety in the alkoxy group, the alkyl group moiety in the aralkyl group, the alkyl group moiety in the alkoxycarbonyl group, the alkyl group moiety in the alkylsulfonyl group, the alkyl group moiety in the alkylsulfoxy group, the alkyl group moiety when the acyl group is an alkylcarbonyl group, and the alkyl group moiety when the acyloxy group is an alkylcarbonyloxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but may be, for example, 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group. For the aryl group moiety in the aralkyl group, the aryl group moiety in the aryloxy group, the aryl group moiety in the arylsulfonyl group, the aryl group moiety in the arylsulfoxy group, the aryl group moiety when the acyl group is an arylcarbonyl group, and the aryl group moiety when the acyloxy group is an arylcarbonyloxy group, the above descriptions are also applied.

The heteroaryl group may be either monocyclic or polycyclic (for example, 2 to 6 rings). The number of heteroatoms that the heteroaryl group has as ring-member atoms is not particularly limited, but, for example, may be 1 to 10. Examples of the heteroatoms include a nitrogen atom, a sulfur atom, an oxygen atom, a selenium atom, a tellurium atom, a phosphorus atom, a silicon atom, and a boron atom. The number of ring-member atoms of the heteroaryl group is not particularly limited, but, for example, may be 5 to 15.

R₈, R₉, and R₁₀ each independently represent a hydrogen atom, an alkyl group, a cycloalkyl group, an alkenyl group, an alkynyl group, an aryl group, a heteroaryl group, or an aralkyl group. The description, specific examples, and preferred ranges of the alkyl groups, cycloalkyl groups, alkenyl groups, alkynyl groups, aryl groups, heteroaryl groups, and aralkyl groups represented by R₈, R₉, and R₁₀ are respectively the same as those described above for R₁₁.

X₁₁⁻ in the formula (b1-1) represents —O—, —COO—, —SO₃—, or —SO₂N⁻Y₁₁(R₁₁₁)ₖ. R₁₁₁ represents an alkyl group, a cycloalkyl group, or an aryl group. Y₁₁ represents —CO—, —SO—, —SO₂—, or a single bond. k represents 0 or 1. When k represents 0, R₁₁₁ is not present, and Y₁₁ is bonded to R₁₁. When k represents 1, R₁₁₁ may be bonded to R₁₁.

The number of carbon atoms of the alkyl group represented by R₁₁₁ is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group.

The cycloalkyl group represented by R₁₁₁ may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The aryl group represented by R₁₁₁ may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group.

X₁₁⁻ is preferably —COO⁻, —SO₃⁻, or —SO₂N⁻Y₁₁(R₁₁₁)ₖ, and more preferably —COO— or —SO₃⁻.

Z₁₁⁺ in the formula (b1-1) represents an organic cation.

Z₁₁⁺ is preferably a sulfonium cation or an iodonium cation.

The cation represented by Z₁₁⁺ is not particularly limited. The cation may have a valence of 1, 2, or more. The cation is preferably a cation represented by the following formula (ZaI) (hereinafter, also referred to as “cation (ZaI)”) or a cation represented by the following formula (ZaII) (hereinafter, also referred to as “cation (ZaII)”).

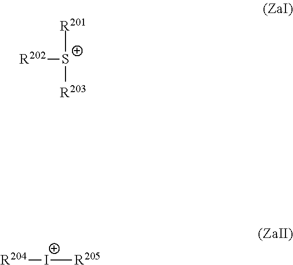

In the formula (ZaI), R²⁰¹, R²⁰², and R²⁰³ each independently represent an organic group. For R²⁰¹, R²⁰², and R²⁰³, the organic group preferably has 1 to 30 carbon atoms, and more preferably 1 to 20 carbon atoms. Of R²⁰¹ to R²⁰³, two may be bonded together to form a ring structure and the ring may include an oxygen atom, a sulfur atom, an ester group, an amide group, or a carbonyl group. Examples of the group formed by bonding together two of R²⁰¹ to R²⁰³ include alkylene groups (such as a butylene group and a pentylene group), and —CH₂—CH₂—O—CH₂—CH₂—.

Preferred examples of the organic cation in the formula (ZaI) include a cation (ZaI-1), a cation (ZaI-2), a cation (ZaI-3b), and a cation (ZaI-4b) described later.

First, the cation (ZaI-1) will be described.

The cation (ZaI-1) is an aryl sulfonium cation represented by the above-described formula (ZaI) where at least one of R²⁰¹ to R²⁰³ is an aryl group.

In the aryl sulfonium cation, all of R²⁰¹ to R²⁰³ may be aryl groups, or a part of R²⁰¹ to R²⁰³ may be an aryl group and the other may be an alkyl group or a cycloalkyl group.

Alternatively, one of R²⁰¹ to R²⁰³ may be an aryl group and the other two of R²⁰¹ to R²⁰³ may be bonded together to form a ring structure in which the ring may include an oxygen atom, a sulfur atom, an ester group, an amide group, or a carbonyl group. Examples of the group formed by bonding together two of R²⁰¹ to R²⁰³ include alkylene groups in which one or more methylene groups may be substituted with an oxygen atom, a sulfur atom, an ester group, an amide group, and/or a carbonyl group (such as a butylene group, a pentylene group, and —CH₂—CH₂—O—CH₂—CH₂—).

Examples of the aryl sulfonium cation include triaryl sulfonium cations, diaryl alkyl sulfonium cations, aryl dialkyl sulfonium cations, diaryl cycloalkyl sulfonium cations, and aryl dicycloalkyl sulfonium cations.

The aryl group included in the aryl sulfonium cation is preferably a phenyl group or a naphthyl group, and more preferably a phenyl group. The aryl group may be an aryl group having a heterocyclic structure having an oxygen atom, a nitrogen atom, a sulfur atom, or the like. Examples of the heterocyclic structure include a pyrrole residue, a furan residue, a thiophene residue, an indole residue, a benzofuran residue, and a benzothiophene residue. When the aryl sulfonium cation has two or more aryl groups, the two or more aryl groups may be the same or different.

The alkyl group or cycloalkyl group that the aryl sulfonium cation has as needed is preferably a linear alkyl group having 1 to 15 carbon atoms, a branched alkyl group having 3 to 15 carbon atoms, or a cycloalkyl group having 3 to 15 carbon atoms, and more preferably a methyl group, an ethyl group, a propyl group, an n-butyl group, a sec-butyl group, a t-butyl group, a cyclopropyl group, a cyclobutyl group, or a cyclohexyl group.

For R²⁰¹ to R²⁰³, a substituent that the aryl group, the alkyl group, and the cycloalkyl group may have is preferably an alkyl group (having, for example, 1 to 15 carbon atoms), a cycloalkyl group (having, for example, 3 to 15 carbon atoms), an aryl group (having, for example, 6 to 14 carbon atoms), an alkoxy group (having, for example, 1 to 15 carbon atoms), a cycloalkylalkoxy group (having, for example, 1 to 15 carbon atoms), a halogen atom except for the fluorine atom (for example, a chlorine atom, a bromine atom, or an iodine atom), a hydroxyl group, a carboxyl group, an ester group, a sulfinyl group, a sulfonyl group, an alkylthio group, or a phenylthio group.

The substituent may further have, when possible, a substituent.

Such substituents are also preferably combined appropriately to form an acid-decomposable group.

Hereinafter, the cation (ZaI-2) will be described.

The cation (ZaI-2) is a cation represented by the formula (ZaI) where R²⁰¹ to R²⁰³ each independently represent an organic group not having an aromatic ring. The aromatic ring also encompasses aromatic rings including a heteroatom.

For R²⁰¹ to R²⁰³, the organic group not having an aromatic ring preferably has 1 to 30 carbon atoms and more preferably 1 to 20 carbon atoms.

R²⁰¹ to R²⁰³ are each independently preferably an alkyl group, a cycloalkyl group, an allyl group, or a vinyl group, more preferably a linear or branched 2-oxoalkyl group, a 2-oxocycloalkyl group, or an alkoxycarbonylmethyl group, and still more preferably a linear or branched 2-oxoalkyl group.

For R²⁰¹ to R²⁰³, the alkyl group and the cycloalkyl group may be, for example, a linear alkyl group having 1 to 10 carbon atoms or a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

R²⁰¹ to R²⁰³ may be further substituted with a halogen atom except for the fluorine atom, an alkoxy group (having, for example, 1 to 5 carbon atoms), a hydroxy group, a cyano group, or a nitro group.

For R²⁰¹ to R²⁰³, substituents are also preferably provided independently as appropriate combinations of substituents to form acid-decomposable groups.

Hereinafter, the cation (ZaI-3b) will be described.

The cation (ZaI-3b) is a cation represented by the following formula (ZaI-3b).

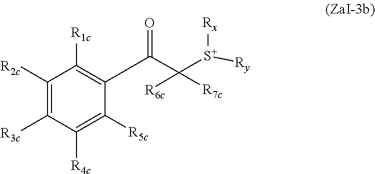

In the formula (ZaI-3b), R_{1c} to R_{5c} each independently represent a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom except for the fluorine atom, a hydroxy group, a nitro group, an alkylthio group, or an arylthio group.

R_{6c} and R_{7c} each independently represent a hydrogen atom, an alkyl group (for example, a t-butyl group), a cycloalkyl group, a halogen atom except for the fluorine atom, a cyano group, or an aryl group.

Rₓ and R_{y} each independently represent an alkyl group, a cycloalkyl group, a 2-oxoalkyl group, a 2-oxocycloalkyl group, an alkoxycarbonylalkyl group, an allyl group, or a vinyl group.

For R_{1c} to R_{7c} and Rₓ and R_{y}, such substituents are also preferably provided independently as appropriate combinations of substituents to form acid-decomposable groups.

Any two or more of R_{1c} to R_{5c}, R_{5c} and R_{6c}, R_{6c} and R_{7c}, R_{5c}, and Rₓ, and Rₓ and R_{y} may be individually bonded together to form rings; these rings may each independently include an oxygen atom, a sulfur atom, a ketone group, an ester bond, or an amide bond.

Such a ring may be an aromatic or non-aromatic hydrocarbon ring, an aromatic or non-aromatic heterocycle, or a polycyclic fused ring formed as a combination of two or more of these rings. The ring may be a 3- to 10-membered ring, and is preferably a 4- to 8-membered ring, and more preferably a 5- or 6-membered ring.

Examples of the groups formed by bonding together any two or more of R_{1c} to R_{5c}, R_{6c} and R_{7c}, and Rₓ and R_{y} include alkylene groups such as a butylene group and a pentylene group. In such an alkylene group, a methylene group may be substituted with a heteroatom such as an oxygen atom.

The groups formed by bonding together R_{5c} and R_{6c}, and R_{5c} and Rₓ are preferably single bonds or alkylene groups. Examples of the alkylene groups include a methylene group and an ethylene group.

R_{1c} to R_{5c}, R_{6c}, R_{7c}, Rₓ, R_{y}, and the rings formed by individually bonding together any two or more of R_{1c} to R_{5c}, R_{5c} and R_{6c}, R_{6c} and R_{7c}, R_{5c} and Rₓ, and Rₓ and R_{y} may have a substituent.

Hereinafter, the cation (ZaI-4b) will be described.

The cation (ZaI-4b) is a cation represented by the following formula (ZaI-4b).

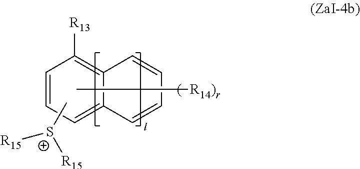

In the formula (ZaI-4b), 1 represents an integer of 0 to 2, and r represents an integer of 0 to 8.

R₁₃ represents a hydrogen atom, a halogen atom except for the fluorine atom (for example, a chlorine atom, a bromine atom, or an iodine atom), a hydroxyl group, an alkyl group, an alkyl group halogenated with a non-fluorine atom, an alkoxy group, a carboxyl group, an alkoxycarbonyl group, or a group including a cycloalkyl group (may be the cycloalkyl group itself or may be a group including, as a part thereof, the cycloalkyl group). These groups may have a substituent.

R₁₄ represents a hydroxyl group, a halogen atom except for the fluorine atom (for example, a chlorine atom, a bromine atom, or an iodine atom), an alkyl group, an alkyl group halogenated with a non-fluorine atom, an alkoxy group, an alkoxycarbonyl group, an alkylcarbonyl group, an alkylsulfonyl group, a cycloalkylsulfonyl group, or a group including a cycloalkyl group (may be the cycloalkyl group itself or may be a group including, as a part thereof, the cycloalkyl group). These groups may have a substituent. When a plurality of R₁₄'s are present, R₁₄'s each independently represent such a group, for example, a hydroxyl group. R₁₅'s each independently represent an alkyl group, a cycloalkyl group, or a naphthyl group. Two R₁₅'s may be bonded together to form a ring. When two R₁₅'s are bonded together to form a ring, the ring skeleton may include a heteroatom such as an oxygen atom or a nitrogen atom.

In an example, two R₁₅'s are preferably alkylene groups and bonded together to form a ring structure. Note that the alkyl group, the cycloalkyl group, the naphthyl group, and the ring formed by bonding together two R₁₅'s may have a substituent.

In the formula (ZaI-4b), for R₁₃, R₁₄, and R₁₅, the alkyl group may be linear or branched. The alkyl group preferably has 1 to 10 carbon atoms. Preferred examples of the alkyl group include a methyl group, an ethyl group, an n-butyl group, and a t-butyl group. For R₁₃ to R₁₅, and Rₓ and R_{y}, such substituents are also preferably provided independently as appropriate combinations of substituents to form acid-decomposable groups.

Hereinafter, the formula (ZaII) will be described.

In the formula (ZaII), R²⁰⁴ and R²⁰⁵ each independently represent an aryl group, an alkyl group, or a cycloalkyl group.

For R²⁰⁴ and R²⁰⁵, the aryl group is preferably a phenyl group or a naphthyl group, and more preferably a phenyl group. For R²⁰⁴ and R²⁰⁵, the aryl group may be an aryl group having a heterocycle having an oxygen atom, a nitrogen atom, a sulfur atom, or the like. Examples of the skeleton of the aryl group having a heterocycle include pyrrole, furan, thiophene, indole, benzofuran, and benzothiophene.

For R²⁰⁴ and R²⁰⁵, the alkyl group and the cycloalkyl group are preferably a linear alkyl group having 1 to 10 carbon atoms, a branched alkyl group having 3 to 10 carbon atoms (for example, a methyl group, an ethyl group, a propyl group, a butyl group, or a pentyl group), or a cycloalkyl group having 3 to 10 carbon atoms (for example, a cyclopentyl group, a cyclohexyl group, or a norbornyl group).

For R²⁰⁴ and R²⁰⁵, the aryl group, the alkyl group, and the cycloalkyl group may each independently have a substituent. For R²⁰⁴ and R²⁰⁵, examples of the substituent that the aryl group, the alkyl group, and the cycloalkyl group may have include alkyl groups (having, for example, 1 to 15 carbon atoms), cycloalkyl groups (having, for example, 3 to 15 carbon atoms), aryl groups (having, for example, 6 to 15 carbon atoms), alkoxy groups (having, for example, 1 to 15 carbon atoms), halogen atoms except for the fluorine atom, a hydroxy group, and a phenylthio group. For R²⁰⁴ and R²⁰⁵, substituents are also preferably provided independently as appropriate combinations of substituents to form acid-decomposable groups.

Specific examples of the organic cation represented by Z₁₁⁺ will be described below, but are not limited thereto.

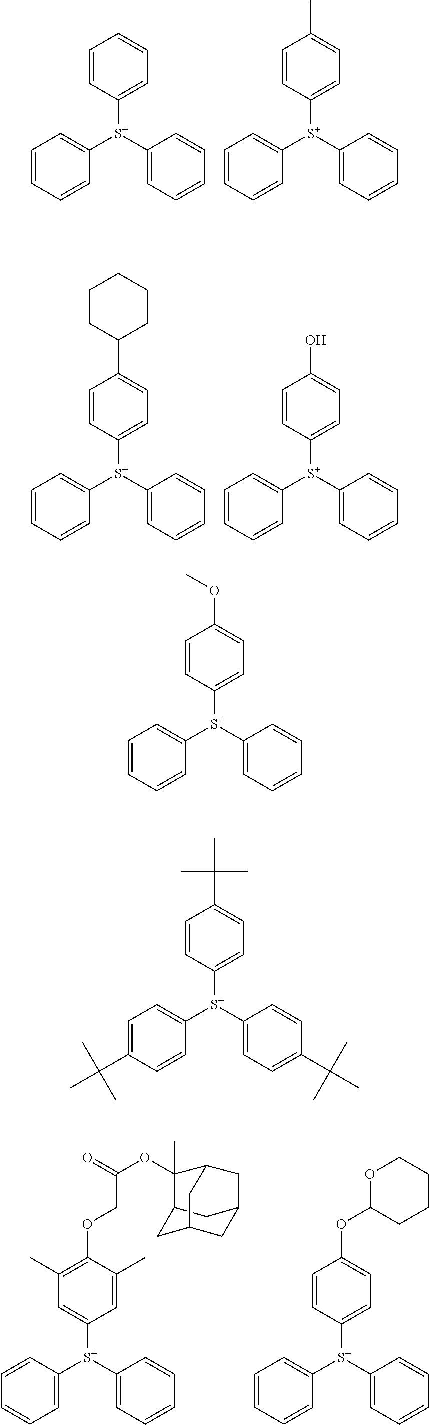

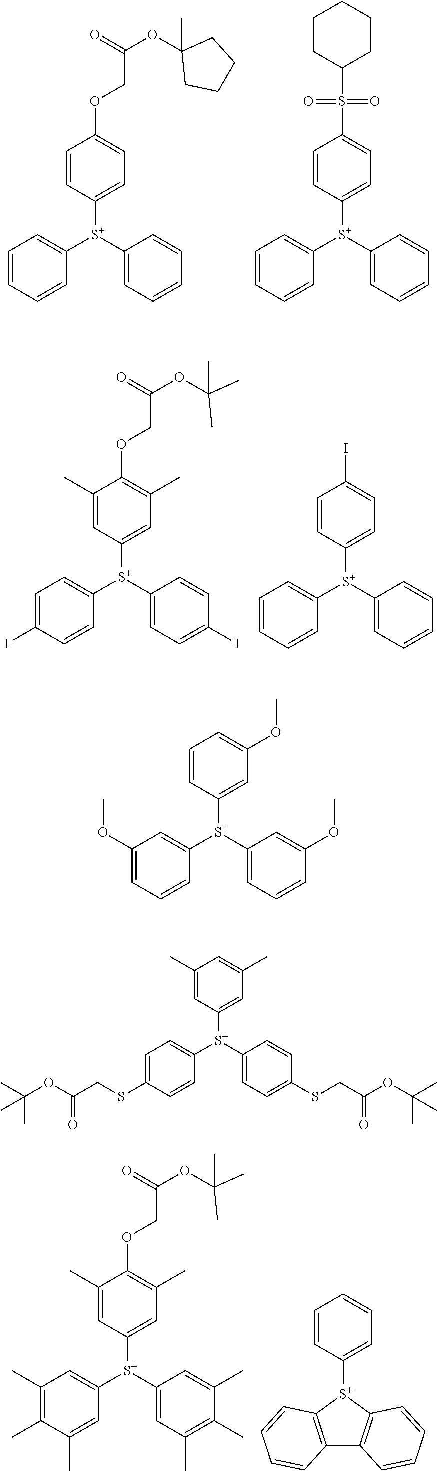

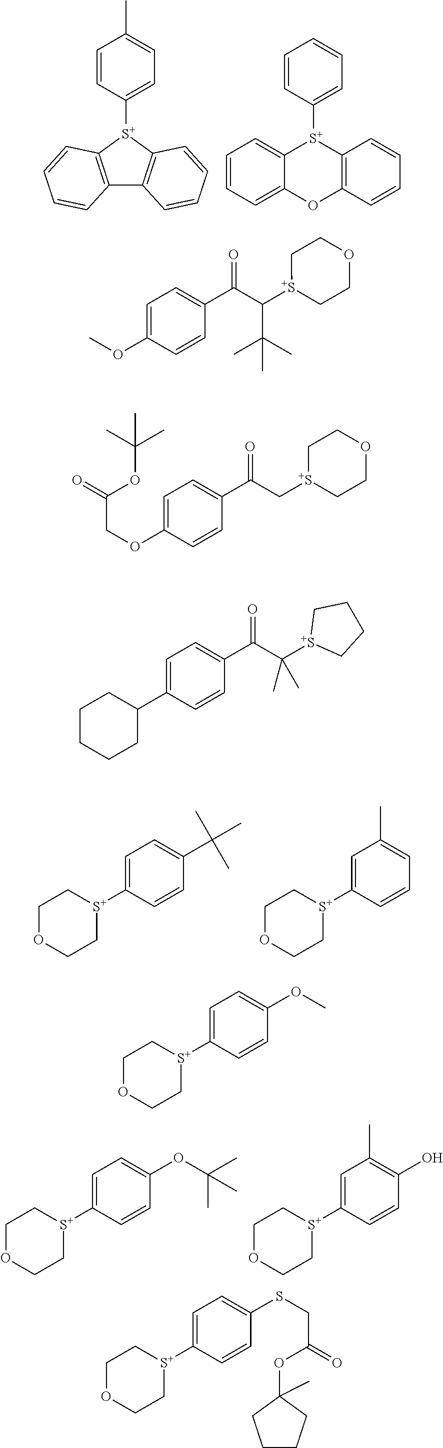

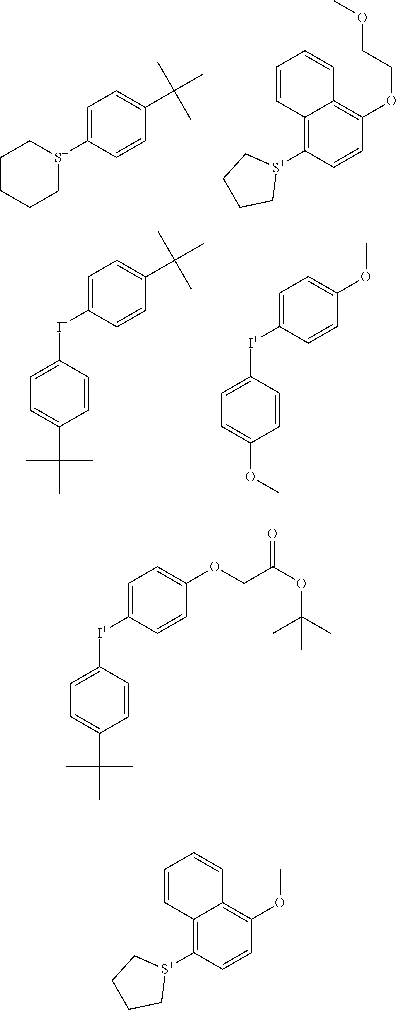 [SMILES: CC(C)(C)c1ccc([S+]2CCCCC2)cc1 ; COCCOc1ccc([S+]2CCCC2)c2ccccc12 ; CC(C)(C)c1ccc([I+]c2ccc(C(C)(C)C)cc2)cc1 ; COc1ccc([I+]c2ccc(OC)cc2)cc1 ; CC(C)(C)OC(=O)COc1ccc([I+]c2ccc(C(C)(C)C)cc2)cc1 ; COc1ccc([S+]2CCCC2)c2ccccc12]

However, R₁₁—X₁₁⁻ in the formula (b1-1) is not an anion represented by any of the above-described formulas (i)-1 to (i)-3. In other words, R₁₁—X₁₁⁻ in the formula (b1-1) is not the anion represented by the formula (i)-1, is not the anion represented by the formula (i)-2, and is not the anion represented by the formula (i)-3.

R₁₁ and Z₁₁⁺ in the formula (b1-1) preferably do not include a structure represented by the following formula (Am-1).

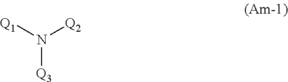

In the formula (Am-1), Q₁ to Q₃ each independently represent a hydrogen atom or an organic group, and at least two of Q₁ to Q₃ may be bonded together to form a ring.

Q₁ to Q₃ in the formula (Am-1) each independently represent a hydrogen atom or an organic group.

For Q₁ to Q₃, the organic group is not particularly limited, but is preferably an alkyl group, a cycloalkyl group, an alkenyl group, an alkynyl group, an aryl group, a heteroaryl group, an aralkyl group, an alkoxy group, an aryloxy group, a carboxyl group, an acyl group, an acyloxy group, a formyloxy group, an alkoxycarbonyl group, an alkylsulfoxy group, an arylsulfoxy group, an alkylsulfonyl group, an arylsulfonyl group, —OCO(OR₈), or —OCO(NR₉R₁₀). R₈, R₉, and R₁₀ each independently represent a hydrogen atom, an alkyl group, a cycloalkyl group, an alkenyl group, an alkynyl group, an aryl group, a heteroaryl group, or an aralkyl group.

For Q₁ to Q₃, the alkyl group, the cycloalkyl group, the alkenyl group, the alkynyl group, the aryl group, the heteroaryl group, the aralkyl group, the alkoxy group, the aryloxy group, the carboxyl group, the acyloxy group, the formyloxy group, the alkoxycarbonyl group, the alkylsulfoxy group, and the arylsulfoxy group may further have one or more substituents. For example, the alkyl group may be substituted with a hydroxy group. The hydrogen atom of the carboxyl group may be substituted with a substituent.

The groups represented by Q₁ to Q₃ will be described below.

The number of carbon atoms of the alkyl group is not particularly limited, but, for example, may be 1 to 20, may be 1 to 10, or may be 1 to 6. The alkyl group may be either linear or branched. Examples of the alkyl group include a methyl group, an ethyl group, an n-propyl group, an i-propyl group, an n-butyl group, a t-butyl group, and an n-hexyl group. For the alkyl group moiety in the alkoxy group, the alkyl group moiety in the aralkyl group, the alkyl group moiety in the alkoxycarbonyl group, the alkyl group moiety in the alkylsulfonyl group, the alkyl group moiety in the alkylsulfoxy group, the alkyl group moiety when the acyl group is an alkylcarbonyl group, and the alkyl group moiety when the acyloxy group is an alkylcarbonyloxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthranyl group, and more preferably a phenyl group. For the aryl group moiety in the aralkyl group, the aryl group moiety in the aryloxy group, the aryl group moiety in the arylsulfonyl group, the aryl group moiety in the arylsulfoxy group, the aryl group moiety when the acyl group is an arylcarbonyl group, and the aryl group moiety when the acyloxy group is an arylcarbonyloxy group, the above descriptions are also applied.

The heteroaryl group may be either monocyclic or polycyclic (for example, 2 to 6 rings). The number of heteroatoms that the heteroaryl group has as ring-member atoms is not particularly limited, but, for example, may be 1 to 10. Examples of the heteroatoms include a nitrogen atom, a sulfur atom, an oxygen atom, a selenium atom, a tellurium atom, a phosphorus atom, a silicon atom, and a boron atom. The number of ring-member atoms of the heteroaryl group is not particularly limited, but, for example, may be 5 to 15.

R₈, R₉, and R₁₀ each independently represent a hydrogen atom, an alkyl group, a cycloalkyl group, an alkenyl group, an alkynyl group, an aryl group, a heteroaryl group, or an aralkyl group. For R₈, R₉, and R₁₀, the descriptions, specific examples, and preferred ranges of the alkyl group, the cycloalkyl group, the alkenyl group, the alkynyl group, the aryl group, the heteroaryl group, and the aralkyl group are respectively the same as those described above for Q₁ to Q₃.

Q₁ to Q₃ may include a cation or an anion. In other words, the atom or atomic group included in Q₁ to Q₃ may become a cation by releasing an electron, or may become an anion by receiving an electron.

Note that the structure represented by the following formula (XX-1) and the structure represented by the following formula (XX-2) do not correspond to the structure represented by the formula (Am-1).

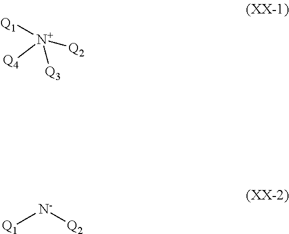

In the formula (XX-1) and the formula (XX-2), Q₁ to Q₄ each independently represent a hydrogen atom or an organic group. At least two of Q₁ to Q₄ may be bonded together to form a ring.

The organic groups represented by Q₁ to Q₃ are as described above. The descriptions of the organic group represented by Q₄ are the same as those described above for Q₁ to Q₃.

L₁₂ in the formula (b1-2) represents a single bond or a divalent linking group. The divalent linking group represented by L₁₂ is not particularly limited, but examples include —O—, —NR¹—, —S—, —SO—, —SO₂—, organic groups (preferably divalent organic groups), and groups that are combinations of two or more of these groups; preferred are —O—, —CO—, —COO—, —OCOO—, —NR¹—, —CONR¹—, —S—, —SO—, —SO₂—, alkylene groups, cycloalkylene groups, alkenylene groups, arylene groups, and groups that are combinations of two or more of these groups. R¹ represent a hydrogen atom or an alkyl group.

The alkylene group represented by L₁₂ is not particularly limited, but is preferably an alkylene group having 1 to 8 carbon atoms, such as a methylene group, an ethylene group, a propylene group, a butylene group, a hexylene group, or an octylene group.

The number of carbon atoms of the cycloalkylene group represented by L₁₂ is not particularly limited, but is preferably 3 to 20, and more preferably 4 to 15. The cycloalkylene group may be a monocyclic cycloalkylene group such as a cyclopentylene group or a cyclohexylene group, or may be a polycyclic cycloalkylene group such as a norbornylene group, a tetracyclodecanylene group, a tetracyclododecanylene group, or an adamantylene group. One of the methylene groups constituting the cycloalkane ring of the cycloalkylene group may be replaced by a heteroatom such as an oxygen atom, a group having a heteroatom such as a carbonyl group or an ester bond, or a vinylidene group. In the cycloalkylene group, one or more of the ethylene groups constituting the cycloalkane ring may be replaced by vinylene groups. The alkenylene group represented by L₁₂ is not particularly limited, but is, for example, preferably an alkenylene group having 2 to 8 carbon atoms.

The arylene group represented by L₁₂ is not particularly limited, but may be, for example, an arylene group having 6 to 20 carbon atoms, and is preferably an arylene group having 6 to 15 carbon atoms. The arylene group is preferably a phenylene group or a naphthylene group, and particularly preferably a phenylene group.

When R¹ represent an alkyl group, examples of the alkyl group include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

X₁₂⁻ in the formula (b1-2) represents —O—, —COO⁻, —SO₃⁻, or —SO₂N⁻Y₁₂(R₁₁₂)ₕ. R₁₁₂ represents an alkyl group, a cycloalkyl group, or an aryl group. Y₁₂ represents —CO—, —SO—, —SO₂—, or a single bond. h represents 0 or 1. When h represents 0, R₁₁₂ is not present, and Y₁₂ is bonded to L₁₂ or Z₁₂⁺. When h represents 1, R₁₁₂ may be bonded to L₁₂ or Z₁₂⁺.

The number of carbon atoms of the alkyl group represented by R₁₁₂ is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group.

The cycloalkyl group represented by R₁₁₂ may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The aryl group represented by R₁₁₂ may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group.

X₁₂⁻ is preferably —COO⁻, —SO₃⁻, or —SO₂N⁻Y₁₂(R₁₁₂)ₕ, and more preferably —COO— or —SO₃.

Z₁₂⁺ in the formula (b1-2) represents an organic cation group. The organic cation group is an organic group having a cation.

The organic cation group represented by Z₁₂⁺ is not particularly limited, but is preferably a group formed by removing any one hydrogen atom from the organic cation represented by Z₁₁⁺ in the above-described formula (b1-1).

The onium salt (B-1) is preferably at least one selected from the group consisting of onium salts each represented by any one of formulas (b1-2a) to (b1-2e) below and the onium salt represented by the formula (b1-2).

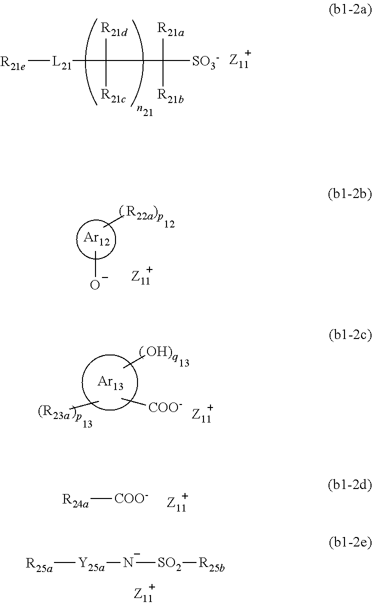

In the formula (b1-2a), R₂₁ₐ to R₂₁ₑ each independently represent a hydrogen atom or an organic group. However, at least one selected from the group consisting of R_{21c} and R_{21d} represents a group selected from the group consisting of a cyano group, a nitro group, a group represented by a formula (2A) below, and a group represented by a formula (2B) below, and R₂₁ₐ and R_{21b} each do not represent groups selected from the group consisting of a cyano group, a nitro group, the group represented by the formula (2A) below, and the group represented by the formula (2B) below. L₂₁ represents a single bond or a divalent linking group. n₂₁ represents an integer of 1 to 4. When n₂₁ represents an integer of 2 or more, a plurality of R_{21c} may be the same or different, and a plurality of R_{21d} may be the same or different. At least two selected from the group consisting of R₂₁ₐ, R_{21b}, R_{21c}, R_{21d}, and L₂₁ may be bonded together to form a ring. Z₁₁⁺ represents an organic cation.

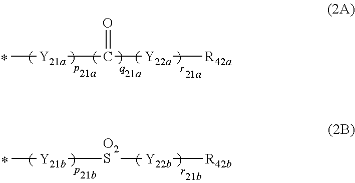

In the formula (2A), Y₂₁ₐ and Y₂₂ₐ each independently represent —O— or —NR₃₂ₐ—. R₃₂ₐ represents a hydrogen atom or an alkyl group. R₄₂ₐ represents an alkyl group, a cycloalkyl group, or an aryl group. p₂₁ₐ and r₂₁ₐ each independently represent 0 or 1. However, p₂₁ₐ and r₂₁ₐ do not simultaneously represent 0. q₂₁ₐ represents 1 or 2. * represents a bonding site.

In the formula (2B), Y_{21b} and Y₂₂b each independently represent —O— or —NR_{32b}—. R_{32b} represents a hydrogen atom or an alkyl group. R_{42b} represents an alkyl group, a cycloalkyl group, or an aryl group. p_{21b} and r_{21b} each independently represent 0 or 1. * represents a bonding site.

In the formula (b1-2b), R₂₂ₐ represents a halogen atom, a hydroxy group, or an organic group other than a carboxyl group. Ar₁₂ represents an aromatic group. p₁₂ represents an integer of 0 or more. When p₁₂ represents an integer of 2 or more, the plurality of R₂₂ₐ may be the same or different. Z₁₁⁺ represents an organic cation.

In the formula (b1-2c), Ar₁₃ represents an aromatic group. R₂₃ₐ represents a halogen atom or an organic group. p₁₃ and q₁₃ each independently represent an integer of 0 or more. When p₁₃ represents an integer of 2 or more, the plurality of R₂₃ₐ may be the same or different. However, p₁₃ and q₁₃ do not simultaneously represent 0. When q₁₃ represents 1, p₁₃ represents an integer of 1 or more. Z₁₁⁺ represents an organic cation.

In the formula (b1-2d), R₂₄ₐ represents an organic group. However, when R₂₄ₐ has an aromatic ring, the carbon atom of —COO− specified in the formula (b1-2d) is not directly bonded to the aromatic ring. Z₁₁⁺ represents an organic cation.

In the formula (b1-2e), Y₂₅ₐ represents —CO—, —SO—, —SO₂—, or a single bond. R₂₅ₐ and R_{25b} each independently represent an alkyl group, a cycloalkyl group, or an aryl group. R₂₅ₐ and R_{25b} may be bonded together to form a ring. Z₁₁⁺ represents an organic cation.

In the formula (b1-2a), R_{21c} and R_{21d} each independently represent a hydrogen atom or an organic group. However, at least one selected from the group consisting of R_{21c} and R_{21d} represents a group selected from the group consisting of a cyano group, a nitro group, the group represented by the formula (2A), and the group represented by the formula (2B).

For R_{21c} and R_{21d}, the organic group is not particularly limited, but is preferably an alkyl group, a cycloalkyl group, an alkenyl group, an alkynyl group, an aryl group, a heteroaryl group, an alkoxy group, an aryloxy group, a cyano group, the group represented by the formula (2A), or the group represented by the formula (2B).

For R_{21c} and R_{21d}, the alkyl group, the cycloalkyl group, the alkenyl group, the alkynyl group, the aryl group, the heteroaryl group, the alkoxy group, and the aryloxy group may further have one or more substituents. For example, the alkyl group may be substituted with a hydroxy group.

The groups represented by R_{21c} and R_{21d} will be described below.

The number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. For the alkyl group moiety in the alkoxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group. For the aryl group moiety in the aryloxy group, the above descriptions are also applied.

The heteroaryl group may be either monocyclic or polycyclic (for example, 2 to 6 rings). The number of heteroatoms that the heteroaryl group has as ring-member atoms is not particularly limited, but, for example, may be 1 to 10. Examples of the heteroatoms include a nitrogen atom, a sulfur atom, an oxygen atom, a selenium atom, a tellurium atom, a phosphorus atom, a silicon atom, and a boron atom. The number of ring-member atoms of the heteroaryl group is not particularly limited, but, for example, may be 5 to 15.

In the formula (b1-2a), n₂₁ represents an integer of 1 to 4. When n₂₁ represents an integer of 2 or more, the plurality of R_{21c} may be the same or different, and the plurality of R_{21d} may be the same or different. At least two selected from the group consisting of R₂₁ₐ, R_{21b}, R_{21c}, R_{21d}, and L₂₁ may be bonded together to form a ring. n₂₁ preferably represents 1 or 2. The ring formed by bonding together at least two selected from the group consisting of R₂₁ₐ, R_{21b}, R_{21c}, R_{21d}, and L₂₁ is not particularly limited, but is preferably a cycloalkane ring. The cycloalkane ring may be a monocyclic cycloalkane ring or may be a polycyclic cycloalkane ring. The cycloalkane ring is preferably a monocyclic or polycyclic cycloalkane ring having 5 to 20 ring carbon atoms. In the cycloalkane ring, one or more methylene groups constituting the ring may be replaced by a heteroatom such as an oxygen atom, a group having a heteroatom such as a carbonyl group, or a vinylidene group. One or more ethylene groups constituting the cycloalkane ring may be replaced by a vinylene group.

In the formula (2A), Y₂₁ₐ and Y₂₂ₐ each independently represent —O— or —NR₃₂ₐ—. R₃₂ₐ represents a hydrogen atom or an alkyl group.

The number of carbon atoms of the alkyl group represented by R₃₂ₐ is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group.

Y₂₁a and Y₂₂a preferably represent —O—.

R₄₂ₐ in the formula (2A) represents an alkyl group, a cycloalkyl group, or an aryl group, and preferably represents an alkyl group or a cycloalkyl group.

The alkyl group represented by R₄₂ₐ may be linear or branched, and is preferably an alkyl group having 1 to 12 carbon atoms, more preferably an alkyl group having 1 to 6 carbon atoms, and still more preferably an alkyl group having 1 to 3 carbon atoms. Examples of the alkyl group represented by R₄₂ₐ include a methyl group, an ethyl group, an n-propyl group, an isopropyl group, an n-butyl group, an isobutyl group, a sec-butyl group, and a t-butyl group. The alkyl group may further have a substituent.

The cycloalkyl group represented by R₄₂ₐ may be monocyclic or polycyclic, and is preferably a cycloalkyl group having 3 to 20 carbon atoms, more preferably a cycloalkyl group having 4 to 15 carbon atoms, and still more preferably a cycloalkyl group having 5 to 10 carbon atoms. Examples of the cycloalkyl group represented by R₄₂ₐ include a cyclopentyl group, a 1-methylcyclopentyl group, a cyclohexyl group, an adamantyl group, a 1-ethyladamantyl group, a norbornyl group, a tetracyclodecanyl group, and a tetracyclododecanyl group. One of the methylene groups constituting the cycloalkane ring of the cycloalkyl group may be replaced by a heteroatom such as an oxygen atom, a group having a heteroatom such as a carbonyl group or an ester bond, or a vinylidene group. In the cycloalkyl group, one or more ethylene groups constituting the cycloalkane ring may be replaced by a vinylene group. The cycloalkyl group may further have a substituent.

The aryl group represented by R₄₂ₐ is preferably an aryl group having 6 to 20 carbon atoms, more preferably an aryl group having 6 to 15 carbon atoms, still more preferably an aryl group having 6 to 10 carbon atoms, particularly preferably a phenyl group or a naphthyl group, and most preferably a phenyl group. The aryl group may further have a substituent.

In the formula (2A), p₂₁ₐ and r₂ₗₐ each independently represent 0 or 1. However, p₂₁ₐ and r₂ₗₐ do not simultaneously represent 0.

One of p₂₁ₐ and r₂₁ₐ preferably represents 1 and the other preferably represents 0. In the formula (2A), q₂₁ₐ represents 1 or 2, and preferably represents 1.

In the formula (2B), Y_{21b} and Y_{22b} each independently represent —O— or —NR_{32b}—. R_{32b} represents a hydrogen atom or an alkyl group.

The number of carbon atoms of the alkyl group represented by R_{32b} is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group.

Y_{21b} and Y_{22b} preferably represent —O—.

In the formula (2B), R_{42b} represents an alkyl group, a cycloalkyl group, or an aryl group, and preferably represents an alkyl group or a cycloalkyl group.

The alkyl group represented by R_{42b} may be linear or branched, and is preferably an alkyl group having 1 to 12 carbon atoms, more preferably an alkyl group having 1 to 6 carbon atoms, and still more preferably an alkyl group having 1 to 3 carbon atoms. Examples of the alkyl group represented by R_{42b} include a methyl group, an ethyl group, an n-propyl group, an isopropyl group, an n-butyl group, an isobutyl group, a sec-butyl group, and a t-butyl group. The cycloalkyl group represented by R_{42b} may be monocyclic or polycyclic, and is preferably a cycloalkyl group having 3 to 20 carbon atoms, more preferably a cycloalkyl group having 4 to 15 carbon atoms, and still more preferably a cycloalkyl group having 5 to 10 carbon atoms. Examples of the cycloalkyl group represented by R_{42b} include a cyclopentyl group, a 1-methylcyclopentyl group, a cyclohexyl group, an adamantyl group, a 1-ethyladamantyl group, a norbornyl group, a tetracyclodecanyl group, and a tetracyclododecanyl group. One of the methylene groups constituting the cycloalkane ring of the cycloalkyl group may be replaced by a heteroatom such as an oxygen atom, a group having a heteroatom such as a carbonyl group or an ester bond, or a vinylidene group. In the cycloalkyl group, one or more ethylene groups constituting the cycloalkane ring may be replaced by a vinylene group.

The aryl group represented by R_{42b} is preferably an aryl group having 6 to 20 carbon atoms, more preferably an aryl group having 6 to 15 carbon atoms, still more preferably an aryl group having 6 to 10 carbon atoms, particularly preferably a phenyl group or a naphthyl group, and most preferably a phenyl group.

In the formula (2B), p_{21b} and r_{21b} each independently represent 0 or 1.

At least one of p_{21b} or r_{21b} preferably represents 0, and p_{21b} and r_{21b} more preferably represent 0.

In the formula (b1-2a), R₂₁ₐ and R_{21b} each independently represent a hydrogen atom or an organic group. However, R₂₁ₐ and R_{21b} each do not represent groups selected from the group consisting of a cyano group, a nitro group, the group represented by the formula (2A), and the group represented by the formula (2B). The group represented by the formula (2A) and the group represented by the formula (2B) are as described above.

The organic groups represented by R₂₁ₐ and R_{21b} are not particularly limited as long as they are not a cyano group, the group represented by the formula (2A), or the group represented by the formula (2B), but are preferably an alkyl group, a cycloalkyl group, an alkenyl group, an alkynyl group, an aryl group, a heteroaryl group, an alkoxy group, or an aryloxy group.

The description, specific examples, and preferred ranges of the alkyl groups, cycloalkyl groups, alkenyl groups, alkynyl groups, aryl groups, heteroaryl groups, alkoxy groups, and aryloxy groups represented by R₂₁ₐ and R_{21b} are the same as those described above for R_{21c} and R_{21d}.

In the formula (b1-2a), R₂₁ₑ represents a hydrogen atom or an organic group.

The organic group represented by R₂₁ₑ is not particularly limited, but is preferably an alkyl group, a cycloalkyl group, an alkenyl group, an alkynyl group, an aryl group, a heteroaryl group, an alkoxy group, an aryloxy group, a cyano group, the group represented by the formula (2A), or the group represented by the formula (2B). The description, specific examples, and preferred ranges of these groups are the same as those described above for R_{21c} and R_{21d}.

In the formula (b1-2a), L₂₁ represents a single bond or a divalent linking group. The divalent linking group represented by L₂₁ is not particularly limited, but examples include —O—, —NR₁—, —S—, —SO—, —SO₂—, organic groups (preferably divalent organic groups), and groups that are combinations of two or more of these groups, and preferred are —O—, —CO—, —COO—, —OCOO—, —NR₁—, —CONR₁—, —S—, —SO—, —SO₂—, alkylene groups, cycloalkylene groups, alkenylene groups, arylene groups, and groups that are combinations of two or more of these groups. R¹ represent a hydrogen atom or an alkyl group.

The alkylene group represented by L₂₁ is not particularly limited, but is preferably an alkylene group having 1 to 8 carbon atoms such as a methylene group, an ethylene group, a propylene group, a butylene group, a hexylene group, or an octylene group.

The number of carbon atoms of the cycloalkylene group represented by L₂₁ is not particularly limited, but is, for example, preferably 3 to 20, and more preferably 4 to 15. The cycloalkylene group may be a monocyclic cycloalkylene group such as a cyclopentylene group or a cyclohexylene group, or may be a polycyclic cycloalkylene group such as a norbornylene group, a tetracyclodecanylene group, a tetracyclododecanylene group, or an adamantylene group. One of the methylene groups constituting the cycloalkane ring of the cycloalkylene group may be replaced by a heteroatom such as an oxygen atom, a group having a heteroatom such as a carbonyl group or an ester bond, or a vinylidene group. In the cycloalkylene group, one or more ethylene groups constituting the cycloalkane ring may be replaced by a vinylene group. The alkenylene group represented by L₂₁ is not particularly limited, but is, for example, preferably an alkenylene group having 2 to 8 carbon atoms.

The arylene group represented by L₂₁ is not particularly limited, but may be, for example, an arylene group having 6 to 20 carbon atoms, and is preferably an arylene group having 6 to 15 carbon atoms. The arylene group is preferably a phenylene group or a naphthylene group, and particularly preferably a phenylene group.

When R¹ represent an alkyl group, examples of the alkyl group include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

Z₁₁⁺ in the formula (b1-2a) represents an organic cation. The description, specific examples, and preferred ranges of Z₁₁⁺ in the formula (b1-2a) are the same as those described above for Z₁₁⁺ in the formula (b1-1).

In the formula (b1-2b), R₂₂ₐ represents a halogen atom, a hydroxy group, or an organic group other than a carboxyl group.

The halogen atom represented by R₂₂ₐ is preferably a chlorine atom, a bromine atom, or an iodine atom.

The organic group represented by R₂₂ₐ is not particularly limited as long as it is not a carboxyl group, but is preferably an alkyl group, a cycloalkyl group, an alkenyl group, an alkynyl group, an aryl group, a heteroaryl group, an alkoxy group, or an aryloxy group. The alkyl group, cycloalkyl group, alkenyl group, alkynyl group, aryl group, heteroaryl group, alkoxy group, or aryloxy group represented by R₂₂ₐ may further have one or more substituents. For example, the alkyl group may be substituted with a hydroxy group.

The groups represented by R₂₂ₐ will be described below.

The number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. For the alkyl group moiety in the alkoxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group. For the aryl group moiety in the aryloxy group, the above descriptions are also applied.

The heteroaryl group may be either monocyclic or polycyclic (for example, 2 to 6 rings). The number of heteroatoms that the heteroaryl group has as ring-member atoms is not particularly limited, but, for example, may be 1 to 10. Examples of the heteroatoms include a nitrogen atom, a sulfur atom, an oxygen atom, a selenium atom, a tellurium atom, a phosphorus atom, a silicon atom, and a boron atom. The number of ring-member atoms of the heteroaryl group is not particularly limited, but, for example, may be 5 to 15.

Ar₁₂ in the formula (b1-2b) represents an aromatic group (more specifically, p₁₂+1-valent aromatic group).

The aromatic group represented by Ar₁₂ may be an aromatic hydrocarbon group or may be an aromatic heterocyclic group.

When the aromatic group represented by Ar₁₂ is an aromatic hydrocarbon group, the aromatic hydrocarbon group may be either monocyclic or polycyclic. The number of carbon atoms of the aromatic hydrocarbon group is not particularly limited, but is, for example, preferably 6 to 20, and more preferably 6 to 14.

The aromatic hydrocarbon group may be a group obtained by removing any p₁₂+1 hydrogen atoms from a fused cyclic compound having a structure in which an aromatic hydrocarbon (for example, benzene or naphthalene) is fused with a cycloalkane (for example, cyclopentane or cyclohexane).

When the aromatic group represented by Ar₁₂ is an aromatic heterocyclic group, the aromatic heterocyclic group may be either monocyclic or polycyclic. The aromatic heterocyclic group preferably includes, as a ring member, at least one heteroatom selected from the group consisting of a nitrogen atom, an oxygen atom, and a sulfur atom. The number of carbon atoms of the aromatic heterocyclic group is not particularly limited, but is, for example, preferably 2 to 18, more preferably 3 to 12, and still more preferably 4 to 12. The number of ring-member atoms of the aromatic heterocyclic group is not particularly limited, but is, for example, preferably 5 to 20, and more preferably 6 to 15. The aromatic heterocyclic group may be, for example, a group formed by removing any p₁₂+1 hydrogen atoms from a five-membered aromatic heterocyclic compound such as pyrrole, imidazole, pyrazole, oxazole, isoxazole, thiazole, isothiazole, triazole, thiophene, or furan, or a six-membered aromatic heterocyclic compound such as pyridine, pyrazine, pyrimidine, pyridazine, triazine, thiazine, or oxazine. The aromatic heterocyclic group may also be a group formed by removing any p₁₂+1 hydrogen atoms from a fused cyclic compound (for example, indole, quinoline, or isoquinoline) having a structure in which the above-described five-membered aromatic heterocyclic compound or the above-described six-membered aromatic heterocyclic compound is fused with at least one selected from the group consisting of the above-described five-membered aromatic heterocyclic compound, the above-described six-membered aromatic heterocyclic compound, aromatic hydrocarbons (for example, benzene and naphthalene), cycloalkanes (for example, cyclopentane and cyclohexane), and non-aromatic heterocyclic compounds (for example, five-membered non-aromatic heterocyclic compounds such as pyrrolidine, pyrroline, 2-oxazolidone, tetrahydrofuran, and tetrahydrothiophene, and six-membered non-aromatic heterocyclic compounds such as morpholine, piperidine, piperazine, and tetrahydropyran).

In the formula (b1-2b), p₁₂ represents an integer of 0 or more. When p₁₂ represents an integer of 2 or more, the plurality of R₂₂ₐ may be the same or different.

p₁₂ preferably represents 1 or 2.

Z₁₁⁺ in the formula (b1-2b) represents an organic cation. The description, specific examples, and preferred ranges of Z₁₁⁺ in the formula (b1-2b) are the same as those described above for Z₁₁⁺ in the formula (b1-1).

Ar₁₃ in the formula (b1-2c) represents an aromatic group (more specifically, a p₁₃+q₁₃+1-valent aromatic group).

The aromatic group represented by Ar₁₃ may be an aromatic hydrocarbon group or may be an aromatic heterocyclic group.

When the aromatic group represented by Ar₁₃ is an aromatic hydrocarbon group, the aromatic hydrocarbon group may be either monocyclic or polycyclic. The number of carbon atoms of the aromatic hydrocarbon group is not particularly limited, but is, for example, preferably 6 to 20, and more preferably 6 to 14.

The aromatic hydrocarbon group may also be a group formed by removing any p₁₃+q₁₃+1 hydrogen atoms from a fused cyclic compound having a structure in which an aromatic hydrocarbon (for example, benzene or naphthalene) is fused with a cycloalkane (for example, cyclopentane or cyclohexane).

When the aromatic group represented by Ar₁₃ is an aromatic heterocyclic group, the aromatic heterocyclic group may be either monocyclic or polycyclic. The aromatic heterocyclic group preferably includes, as a ring member, at least one heteroatom selected from the group consisting of a nitrogen atom, an oxygen atom, and a sulfur atom. The number of carbon atoms of the aromatic heterocyclic group is not particularly limited, but is, for example, preferably 2 to 18, more preferably 3 to 12, and still more preferably 4 to 12. The number of ring-member atoms of the aromatic heterocyclic group is not particularly limited, but is, for example, preferably 5 to 20, and more preferably 6 to 15. The aromatic heterocyclic group may be, for example, a group formed by removing any p₁₃+q₁₃+1 hydrogen atoms from a five-membered aromatic heterocyclic compound such as pyrrole, imidazole, pyrazole, oxazole, isoxazole, thiazole, isothiazole, triazole, thiophene, or furan, or a six-membered aromatic heterocyclic compound such as pyridine, pyrazine, pyrimidine, pyridazine, triazine, thiazine, or oxazine. The aromatic heterocyclic group may also be a group formed by removing any p₁₃+q₁₃+1 hydrogen atoms from a fused cyclic compound (for example, indole, quinoline, or isoquinoline) having a structure in which the above-described five-membered aromatic heterocyclic compound or the above-described six-membered aromatic heterocyclic compound is fused with at least one selected from the group consisting of the above-described five-membered aromatic heterocyclic compound, the above-described six-membered aromatic heterocyclic compound, aromatic hydrocarbons (for example, benzene and naphthalene), cycloalkanes (for example, cyclopentane and cyclohexane), and non-aromatic heterocyclic compounds (for example, five-membered non-aromatic heterocyclic compounds such as pyrrolidine, pyrroline, 2-oxazolidone, tetrahydrofuran, and tetrahydrothiophene, and six-membered non-aromatic heterocyclic compounds such as morpholine, piperidine, piperazine, and tetrahydropyran).

In the formula (b1-2c), R₂₃ₐ represents a halogen atom or an organic group.

The halogen atom represented by R₂₃ₐ is preferably a chlorine atom, a bromine atom, or an iodine atom.

The organic group represented by R₂₃ₐ is not particularly limited, but is preferably a carboxyl group, an alkyl group, a cycloalkyl group, an alkenyl group, an alkynyl group, an aryl group, a heteroaryl group, an alkoxy group, or an aryloxy group.

The carboxyl group, alkyl group, cycloalkyl group, alkenyl group, alkynyl group, aryl group, heteroaryl group, alkoxy group, or aryloxy group represented by R₂₃ₐ may further have one or more substituents. For example, the alkyl group may be substituted with a hydroxy group.

The groups represented by R₂₃ₐ will be described below.

The number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. For the alkyl group moiety in the alkoxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group. For the aryl group moiety in the aryloxy group, the above descriptions are also applied.

The heteroaryl group may be either monocyclic or polycyclic (for example, 2 to 6 rings). The number of heteroatoms that the heteroaryl group has as ring-member atoms is not particularly limited, but, for example, may be 1 to 10. Examples of the heteroatoms include a nitrogen atom, a sulfur atom, an oxygen atom, a selenium atom, a tellurium atom, a phosphorus atom, a silicon atom, and a boron atom. The number of ring-member atoms of the heteroaryl group is not particularly limited, but, for example, may be 5 to 15.

In the formula (b1-2c), p₁₃ and q₁₃ each independently represent an integer of 0 or more. When p₁₃ represents an integer of 2 or more, the plurality of R₂₃ₐ may be the same or different. However, p₁₃ and q₁₃ do not simultaneously represent 0. When q₁₃ represents 1, p₁₃ represents an integer of 1 or more. p₁₃ preferably represents 1 or 2. q₁₃ preferably represents 1 or 2.

Z₁₁⁺ in the formula (b1-2c) represents an organic cation. The description, specific examples, and preferred ranges of Z₁₁⁺ in the formula (b1-2c) are the same as those described above for Z₁₁⁺ in the formula (b1-1).

In the formula (b1-2d), R₂₄ₐ represents an organic group.

The organic group represented by R₂₄ₐ is not particularly limited, but is preferably an alkyl group, a cycloalkyl group, an alkenyl group, an alkynyl group, or an alkoxy group. The alkyl group, cycloalkyl group, alkenyl group, alkynyl group, or alkoxy group represented by R₂₄ₐ may further have one or more substituents. For example, the alkyl group may be substituted with a hydroxy group.

The groups represented by R₂₄ₐ will be described below.

The number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. For the alkyl group moiety in the alkoxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The organic group represented by R₂₄ₐ may have an aromatic ring, but when R₂₄ₐ has an aromatic ring, the carbon atom of —COO− specified in the formula (b1-2d) is not directly bonded to the aromatic ring.

Z₁₁⁺ in the formula (b1-2d) represents an organic cation. The description, specific examples, and preferred ranges for Z₁₁⁺ in the formula (b1-2d) are the same as those described above for Z₁₁⁺ in the formula (b1-1).

In the formula (b1-2e), Y₂₅ₐ represents —CO—, —SO—, —SO₂—, or a single bond.

In the formula (b1-2e), R₂₅ₐ and R_{25b} each independently represent an alkyl group, a cycloalkyl group, or an aryl group. R₂₅ₐ and R_{25b} may be bonded together to form a ring. For R₂₅ₐ and R_{25b}, the number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group.

For R₂₅ₐ and R_{25b}, the cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

For R₂₅ₐ and R_{25b}, the aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group.

Z₁₁⁺ in the formula (b1-2e) represents an organic cation. The description, specific examples, and preferred ranges of Z₁₁⁺ in the formula (b1-2e) are the same as those described above for Z₁₁⁺ in the formula (b1-1).

### Molecular Weight of Onium Salt (B-1)

The onium salt (B-1) may be in the form of a low molecular weight compound, or may be in the form of a polymer. Alternatively, the form of a low molecular weight compound and the form of a polymer may be used in combination.

When the onium salt (B-1) is in the form of a low molecular weight compound, the molecular weight of the onium salt (B-1) is not particularly limited, but is, for example, preferably 5000 or less, more preferably 3000 or less, and particularly preferably 2000 or less. The molecular weight of the onium salt (B-1) is preferably 100 or more, more preferably 200 or more.

When the onium salt (B-1) is in the form of a polymer, it may be incorporated into a portion of the resin (A) that is subjected to action of an acid to undergo an increase in polarity, or it may be incorporated into a resin different from the resin (A) that is subjected to action of an acid to undergo an increase in polarity.

When the onium salt (B-1) is incorporated into a portion of the resin (A), the resin (A) also serves as the onium salt (B-1) and the composition of the present invention may include or also preferably does not include an additional onium salt (B-1).

The onium salt (B-1) is preferably in the form of a low molecular weight compound.

### Fluorine Content of Onium Salt (B-1)

The onium salt (B-1) does not include fluorine atoms, or when the onium salt (B-1) includes a fluorine atom, the fluorine atom content (fluorine content) relative to all atoms included in the onium salt (B-1) is 3 mass % or less.

When the onium salt (B-1) includes a fluorine atom, the fluorine atom content relative to all atoms included in the onium salt (B-1) is preferably 2 mass % or less, and more preferably 1 mass % or less.

The onium salt (B-1) particularly preferably does not include fluorine atoms (in other words, has a fluorine content of 0 mass %).

The fluorine content of the onium salt (B-1) represents the mass ratio of fluorine atoms to all atoms of the onium salt (B-1). The fluorine content (mass %) can be calculated by the following formula (1).

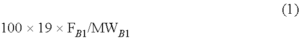

In the formula (1), F_{B1} represents the number of fluorine atoms included in the onium salt (B-1), and MW_{B1} represents the molecular weight of the onium salt (B-1).

In this Specification, the fluorine content of the onium salt (B-1) refers to a value determined by the above-described method; however, when use of the above-described method cannot determine the fluorine content, a value calculated by an analytical method such as elemental analysis on a film obtained by evaporating the solvent component of the composition is employed.

### Content of Onium Salt (B-1)

The content of the onium salt (B-1) in the composition of the present invention is not particularly limited, but is, relative to the total solid content of the composition of the present invention, preferably 0.1 to 30.0 mass %, more preferably 0.5 to 20.0 mass %, and still more preferably 1.0 to 15.0 mass %.

Such onium salts (B-1) may be used alone or in combination of two or more thereof. When two or more thereof are used, the total content thereof is preferably within such a preferred content range.

The onium salt (B-1) can be synthesized with reference to a publicly known method.

Specific examples of the onium salt (B-1) include, for example, B1-1 to B1-18 used in Examples described later, but are not limited thereto.

Onium salt (B-2)

The onium salt (B-2) included in the composition of the present invention will be described.

The onium salt (B-2) is an onium salt represented by the following formula (b2-1).

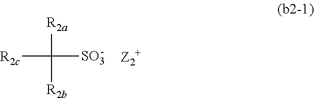

In the formula (b2-1), R₂ₐ represents an electron-withdrawing group. R_{2b} and R_{2c} each independently represent a hydrogen atom or an organic group. At least two selected from the group consisting of R₂ₐ, R_{2b}, and R_{2c} may be bonded together to form a ring. However, R_{2b} and R_{2c} do not simultaneously represent hydrogen atoms. Z₂⁺ represents an organic cation.

The onium salt (B-2) is a compound different from the above-described onium salt (B-1).

In the formula (b2-1), R₂ₐ represents an electron-withdrawing group.

The electron-withdrawing group is preferably a group having a Hammett's substituent constant 6p value of more than 0, more preferably a group having a ap value of 0.1 or more, and still more preferably a group having a ap value of 0.2 or more. For the Hammett's substitution constant 6p value, for example, “Chemical Reviews, 1991, No. 91, pages 165 to 195” can be referred to.

Examples of the electron-withdrawing group include halogen atoms (for example, a fluorine atom, a chlorine atom, a bromine atom, and an iodine atom), halogenated alkyl groups (for example, a —CF₃ group), a formyl group, a carboxyl group, a cyano group, a nitro group, a dicyanomethyl group (—(CH)CN₂), and a group represented by a formula (1A) below.

R₂ₐ preferably represents a cyano group, a nitro group, a dicyanomethyl group, or the group represented by the formula (1A) below, and more preferably represents a cyano group, a dicyanomethyl group, or the group represented by the formula (1A) below.

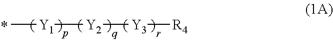

In the formula (1A), Y₁ and Y₃ each independently represent —O— or —NR₃—. R₃ represents a hydrogen atom or an alkyl group. Y₂ represents —C(═O)— or —SO₂—, R₄ represents an alkyl group, a cycloalkyl group, or an aryl group. At least two selected from the group consisting of R₃ and R₄ may be bonded together to form a ring. p and r each independently represent 0 or 1. q represents 1 or 2. * represents a bonding site.

Y₁ and Y₃ in the formula (1A) each independently represent —O— or —NR₃—. R₃ represents a hydrogen atom or an alkyl group.

The number of carbon atoms of the alkyl group represented by R₃ is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group.

Y₁ and Y₃ preferably represent —O—.

In the formula (1A), R₄ represents an alkyl group, a cycloalkyl group, or an aryl group, and preferably represents an alkyl group or a cycloalkyl group.

The alkyl group represented by R₄ may be linear or branched, and is preferably an alkyl group having 1 to 12 carbon atoms, more preferably an alkyl group having 1 to 6 carbon atoms, and still more preferably an alkyl group having 1 to 3 carbon atoms. Examples of the alkyl group represented by R₄ include a methyl group, an ethyl group, an n-propyl group, an isopropyl group, an n-butyl group, an isobutyl group, a sec-butyl group, and a t-butyl group, The alkyl group may further have a substituent.

The cycloalkyl group represented by R₄ may be monocyclic or polycyclic, and is preferably a cycloalkyl group having 3 to 20 carbon atoms, more preferably a cycloalkyl group having 4 to 15 carbon atoms, and still more preferably a cycloalkyl group having 5 to 10 carbon atoms. Examples of the cycloalkyl group represented by R₄ include a cyclopentyl group, a 1-methylcyclopentyl group, a cyclohexyl group, an adamantyl group, a 1-ethyladamantyl group, a norbornyl group, a tetracyclodecanyl group, and a tetracyclododecanyl group. One of the methylene groups constituting the cycloalkane ring of the cycloalkyl group may be replaced by a heteroatom such as an oxygen atom, a group having a heteroatom such as a carbonyl group or an ester bond, or a vinylidene group. In the cycloalkyl group, one or more ethylene groups constituting the cycloalkane ring may be replaced by a vinylene group. The cycloalkyl group may further have a substituent.

The aryl group represented by R₄ is preferably an aryl group having 6 to 20 carbon atoms, more preferably an aryl group having 6 to 15 carbon atoms, still more preferably an aryl group having 6 to 10 carbon atoms, particularly preferably a phenyl group or a naphthyl group, and most preferably a phenyl group. The aryl group may further have a substituent.

In the formula (1A), Y₂ represents —C(═O)— or —SO₂—.

In the formula (1A), p and r each independently represent 0 or 1.

In the formula (1A), q represents 1 or 2, and preferably represents 1.

The group represented by the formula (1A) is preferably —O(C═O)R₄, —(C═O)OR₄, —O(SO₂)R₄, —(SO₂)OR₄, or —(SO₂)R₄, and more preferably —O(C═O)R₄, —(C═O)OR₄, or —(SO₂)R₄.

In the formula (b2-1), R_{2b} and R_{2c} each independently represent a hydrogen atom or an organic group. However, R_{2b} and R_{2c} do not simultaneously represent hydrogen atoms.

For R_{2b} and R_{2c}, the organic group is not particularly limited, but is preferably an alkyl group, a cycloalkyl group, an alkenyl group, an alkynyl group, an aryl group, a heteroaryl group, an alkoxy group, an aryloxy group, a cyano group, a dicyanomethyl group, or the group represented by the formula (1A).

For R_{2b} and R_{2c}, the alkyl group, the cycloalkyl group, the alkenyl group, the alkynyl group, the aryl group, the heteroaryl group, the alkoxy group, and the aryloxy group may further have one or more substituents. For example, the alkyl group may be substituted with a hydroxy group.

The groups represented by R_{2b} and R_{2c} will be described below.

The number of carbon atoms of the alkyl group is not particularly limited, but, for example, may be 1 to 20, may be 1 to 10, or may be 1 to 6. The alkyl group may be either linear or branched. The alkyl group may be, for example, a methyl group, an ethyl group, an n-propyl group, an i-propyl group, an n-butyl group, a t-butyl group, or an n-hexyl group. For the alkyl group moiety in the alkoxy group, the above descriptions are also applied.

The cycloalkyl group may be a monocyclic cycloalkyl group such as a cyclopentyl group or a cyclohexyl group, or may be a polycyclic cycloalkyl group such as a norbornyl group, a tetracyclodecanyl group, a tetracyclododecanyl group, or an adamantyl group. The number of carbon atoms of the cycloalkyl group is not particularly limited, but, for example, may be 5 to 20, or may be 5 to 15.

The alkenyl group may be either linear or branched. The number of carbon atoms of the alkenyl group is not particularly limited, but, for example, may be 2 to 20, may be 2 to 10, or may be 2 to 6.

The alkynyl group may be either linear or branched. The number of carbon atoms of the alkynyl group is not particularly limited, but, for example, may be 2 to 20, may be 2 to 10, or may be 2 to 6.

The aryl group may be either monocyclic or polycyclic (for example, 2 to 6 rings). The number of ring-member atoms of the aryl group is not particularly limited, but, for example, may be 6 to 20, may be 6 to 15, or may be 6 to 10. The aryl group is preferably a phenyl group, a naphthyl group, or an anthryl group, and more preferably a phenyl group. For the aryl group moiety in the aryloxy group, the above descriptions are also applied.

The heteroaryl group may be either monocyclic or polycyclic (for example, 2 to 6 rings). The number of heteroatoms that the heteroaryl group has as ring-member atoms is not particularly limited, but, for example, may be 1 to 10. Examples of the heteroatoms include a nitrogen atom, a sulfur atom, an oxygen atom, a selenium atom, a tellurium atom, a phosphorus atom, a silicon atom, and a boron atom. The number of ring-member atoms of the heteroaryl group is not particularly limited, but, for example, may be 5 to 15.

At least two selected from the group consisting of R₂ₐ, R_{2b}, and R_{2c} may be bonded together to form a ring.

The ring formed by bonding together at least two selected from the group consisting of R₂ₐ, R_{2b}, and R_{2c} is not particularly limited, but is preferably a cycloalkane ring. The cycloalkane ring may be a monocyclic cycloalkane ring or a polycyclic cycloalkane ring. The cycloalkane ring is preferably a monocyclic or polycyclic cycloalkane ring having 5 to 20 ring carbon atoms. In the cycloalkane ring, one or more methylene groups constituting the ring may be replaced by a heteroatom such as an oxygen atom, a group having a heteroatom such as a sulfonyl group or a carbonyl group, or a vinylidene group. One or more ethylene groups constituting the cycloalkane ring may be replaced by a vinylene group.

Z₂⁺ in the formula (b2-1) represents an organic cation. The description, specific examples, and preferred ranges of Z₂⁺ in the formula (b2-1) are the same as those described above for Z₁₁⁺ in the formula (b1-1).

### Molecular Weight of Onium Salt (B-2)

The onium salt (B-2) may be in the form of a low molecular weight compound or may be in the form of a polymer. Alternatively, the form of a low molecular weight compound and the form of a polymer may be used in combination.

When the onium salt (B-2) is in the form of a low molecular weight compound, the molecular weight of the onium salt (B-2) is not particularly limited, but is preferably 5000 or less, more preferably 3000 or less, and particularly preferably 2000 or less. The molecular weight of the onium salt (B-2) is preferably 100 or more, more preferably 200 or more.

When the onium salt (B-2) is in the form of a polymer, it may be incorporated into a portion of the resin (A) that is subjected to action of an acid to undergo an increase in polarity, or it may be incorporated into a resin different from the resin (A) that is subjected to action of an acid to undergo an increase in polarity.

When the onium salt (B-2) is incorporated into a portion of the resin (A), the resin (A) also serves as the onium salt (B-2) and the composition of the present invention may include or also preferably does not include an additional onium salt (B-2).

The onium salt (B-2) is preferably in the form of a low molecular weight compound.

### Fluorine Content of Onium Salt (B-2)

The onium salt (B-2) does not include fluorine atoms, or when the onium salt (B-2) includes a fluorine atom, the fluorine atom content (fluorine content) relative to all atoms included in the onium salt (B-2) is 3 mass % or less.

When the onium salt (B-2) includes a fluorine atom, the fluorine atom content relative to all atoms included in the onium salt (B-2) is preferably 2 mass % or less, and more preferably 1 mass % or less.

The onium salt (B-2) particularly preferably does not include fluorine atoms (in other words, has a fluorine content of 0 mass %).

The fluorine content of the onium salt (B-2) represents the mass ratio of fluorine atoms to all atoms of the onium salt (B-2). The fluorine content (mass %) can be calculated by the following formula (2).

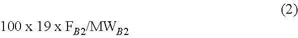

In the formula (2), F_{B2} represents the number of fluorine atoms included in the onium salt (B-2), and MW_{B2} represents the molecular weight of the onium salt (B-2).

In this Specification, the fluorine content of the onium salt (B-2) refers to a value determined by the above-described method; however, when use of the above-described method cannot determine the fluorine content, a value calculated by an analytical method such as elemental analysis on a film obtained by evaporating the solvent component of the composition is employed.

### Content of Onium Salt (B-2)

The content of the onium salt (B-2) in the composition of the present invention is not particularly limited, but is, relative to the total solid content of the composition of the present invention, preferably 1.0 to 50.0 mass %, more preferably 3.0 to 45.0 mass %, and still more preferably 5.0 to 40.0 mass %.

Such onium salts (B-2) may be used alone or in combination of two or more thereof. When two or more thereof are used, the total content thereof is preferably within such a preferred content range.

The onium salt (B-2) can be synthesized, for example, by the method described in Examples.

Specific examples of the onium salt (B-2) include, but are not limited to, B2-1 to B2-30 used in Examples described later, and the following compounds.

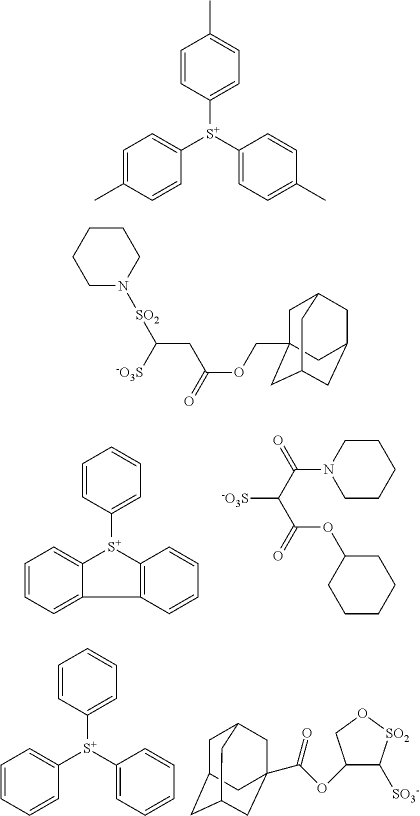

pKa of acid (AC_{B1}) and acid (AC_{B2})

The onium salt (B-1) generates an acid (AC_{B1}) upon irradiation with an actinic ray or a radiation. The acid (AC_{B1}) has a pKa (also referred to as “pKa^{B1}”) larger than the pKa of an acid (AC_{B2}) generated by the onium salt (B-2) upon irradiation with an actinic ray or a radiation (also referred to as “pKa^{B2}”) by 1.0 or more. pKa^{B1}-pKa^{B2} (also referred to as “ΔpKa”) is 1.0 or more, preferably 1.3 or more, more preferably 1.5 or more, and still more preferably 2.0 or more. ΔpKa is also preferably 15.0 or less, more preferably 13.0 or less, and still more preferably 10.0 or less.

pKa^{B1} is preferably −2.0 to 12.0, more preferably −1.0 to 11.0, and still more preferably 0.0 to 10.0.

pKa^{B2} is preferably −8.0 to 1.0, more preferably −7.0 to 0.5, and still more preferably −6.0 to 0.0.

pKa^{B1} and pKa^{B2} are specifically determined in the following manner.

For each of the onium salts, a structure in which the anion moiety is protonated (for example, when the anion moiety is SO₃—, SO₃H) is calculated using software (Advanced Chemistry Development (ACD/Labs) Software V8.14 for Solaris (1994-2007 ACD/Labs)). When use of this method cannot determine pKa, a value obtained on the basis of DFT (density functional theory) using Gaussian16 is employed.

When a plurality of onium salts are included as the onium salt (B-1), the calculated value of the onium salt species having the lowest pKa is used to calculate ΔpKa (pKa^{B1}-pKa^{B2}). When a plurality of onium salts are included as the onium salt (B-2), the calculated value of the onium salt species having the highest pKa is used to calculate ΔpKa (pKa^{B1}-pKa^{B2}).

The mass ratio (B-2)/(B-1) of the content of the onium salt (B-2) to the content of the onium salt (B-1) included in the composition of the present invention is preferably 1 to 25, more preferably 1 to 20, and still more preferably 1 to 15.

Resin (A) that is Subjected to Action of Acid to Undergo Increase in Polarity

The composition of the present invention contains a resin (A) that is subjected to action of an acid to undergo an increase in polarity (also simply referred to as “resin (A)”).

The resin (A) includes a group that is decomposed by action of an acid to undergo an increase in polarity (also referred to as “acid-decomposable group”), and preferably includes a repeating unit having an acid-decomposable group. When the resin (A) has an acid-decomposable group, in a pattern forming method using the composition of the present invention, typically, when an alkali developer is employed as the developer, a positive-type pattern is suitably formed, and when an organic-based developer is employed as the developer, a negative-type pattern is suitably formed.

The repeating unit having an acid-decomposable group is, in addition to the repeating unit having an acid-decomposable group, preferably a repeating unit having an acid-decomposable group including an unsaturated bond.

### Repeating Unit Having Acid-Decomposable Group

The acid-decomposable group refers to a group that is decomposed by action of an acid to generate a polar group. The acid-decomposable group preferably has a structure in which the polar group is protected with a group (leaving group) that leaves by action of an acid. Thus, the resin (A) has a repeating unit having a group that is decomposed by action of an acid to generate a polar group. The resin having the repeating unit is subjected to action of an acid to undergo an increase in polarity to undergo an increase in the degree of solubility in the alkali developer, but undergo a decrease in the degree of solubility in organic solvents.

The polar group is preferably an alkali-soluble group; examples include acidic groups such as a carboxyl group, a phenolic hydroxyl group, fluorinated alcohol groups, a sulfonic acid group, a phosphoric acid group, a sulfonamide group, a sulfonylimide group, (alkylsulfonyl)(alkylcarbonyl)methylene groups, (alkylsulfonyl)(alkylcarbonyl)imide groups, bis(alkylcarbonyl)methylene groups, bis(alkylcarbonyl)imide groups, bis(alkylsulfonyl)methylene groups, bis(alkylsulfonyl)imide groups, tris(alkylcarbonyl)methylene groups, and tris(alkylsulfonyl)methylene groups, and an alcoholic hydroxyl group.

In particular, the polar group is preferably a carboxyl group, a phenolic hydroxy group, a fluorinated alcohol group (preferably a hexafluoroisopropanol group), or a sulfonic acid group.

Examples of the group that leaves by action of an acid include groups represented by formulas (Y1) to (Y4).

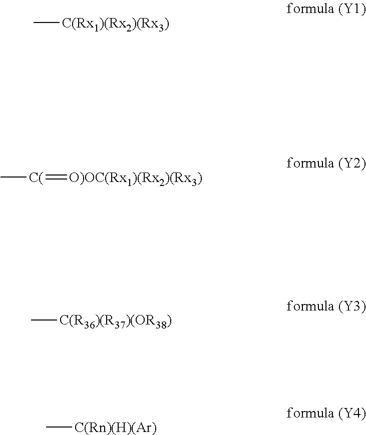

In the formula (Y1) and the formula (Y2), Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two of Rx₁ to Rx₃ are preferably methyl groups.

In particular, Rx₁ to Rx₃ preferably each independently represent a linear or branched alkyl group, and Rx₁ to Rx₃ more preferably each independently represent a linear alkyl group. Two of Rx₁ to Rx₃ may be bonded together to form a monocycle or a polycycle.

For Rx₁ to Rx₃, the alkyl group is preferably an alkyl group having 1 to 5 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms, and may be, for example, a phenyl group, a naphthyl group, or an anthryl group.

For Rx₁ to Rx₃, the alkenyl group is preferably a vinyl group.

The ring formed by bonding together two of Rx₁ to Rx₃ is preferably a cycloalkyl group. The cycloalkyl group formed by bonding together two of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group, and more preferably a monocyclic cycloalkyl group having 5 to 6 carbon atoms.

In the cycloalkyl group formed by bonding together two of Rx₁ to Rx₃, one of methylene groups constituting the ring may be replaced by a heteroatom such as an oxygen atom, a group including a heteroatom such as a carbonyl group, or a vinylidene group. In the cycloalkyl group, one or more ethylene groups constituting the cycloalkane ring may be replaced by a vinylene group.

The group represented by the formula (Y1) or the formula (Y2) preferably has a form in which, for example, Rx₁ is a methyl group or an ethyl group, and Rx₂ and Rx₃ are bonded together to form the above-described cycloalkyl group.

When the actinic ray-sensitive or radiation-sensitive resin composition is, for example, a resist composition used for EUV exposure, the alkyl groups, cycloalkyl groups, alkenyl groups, and aryl groups represented by Rx₁ to Rx₃ and the ring formed by bonding together two of Rx₁ to Rx₃ also preferably further have, as a substituent, a fluorine atom or an iodine atom.

In the formula (Y3), R₃₆ to R₃₈ each independently represent a hydrogen atom or a monovalent organic group. R₃₇ and R₃₈ may be bonded together to form a ring. The monovalent organic group may be an alkyl group, a cycloalkyl group, an aryl group, an aralkyl group, or an alkenyl group. R₃₆ is also preferably a hydrogen atom.

Note that the alkyl group, the cycloalkyl group, the aryl group, and the aralkyl group may include a heteroatom such as an oxygen atom and/or a group including a heteroatom such as a carbonyl group. For example, in the alkyl group, the cycloalkyl group, the aryl group, and the aralkyl group, one or more methylene groups may be replaced by a heteroatom such as an oxygen atom and/or a group including a heteroatom such as a carbonyl group.

R₃₈ and another substituent of the main chain of the repeating unit may be bonded together to form a ring. The group formed by bonding together R₃₈ and another substituent of the main chain of the repeating unit is preferably an alkylene group such as a methylene group.

When the actinic ray-sensitive or radiation-sensitive resin composition is, for example, a resist composition used for EUV exposure, the monovalent organic groups represented by R₃₆ to R₃₈ and the ring formed by bonding together R₃₇ and R₃₈ also preferably further have, as a substituent, a fluorine atom or an iodine atom.

The formula (Y3) is preferably a group represented by the following formula (Y3-1).

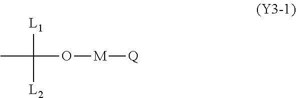

L₁ and L₂ above each independently represent a hydrogen atom, an alkyl group, a cycloalkyl group, an aryl group, or a group that is a combination of the foregoing (for example, a group that is a combination of an alkyl group and an aryl group).

M represents a single bond or a divalent linking group.

Q represents an alkyl group that may include a heteroatom, a cycloalkyl group that may include a heteroatom, an aryl group that may include a heteroatom, an amino group, an ammonium group, a mercapto group, a cyano group, an aldehyde group, or a group that is a combination of the foregoing (for example, a group that is a combination of an alkyl group and a cycloalkyl group).

In the alkyl group and the cycloalkyl group, for example, one of methylene groups may be replaced by a heteroatom such as an oxygen atom or a group including a heteroatom such as a carbonyl group.

Note that one of L₁ and L₂ is preferably a hydrogen atom and the other is preferably an alkyl group, a cycloalkyl group, an aryl group, or a group that is a combination of an alkylene group and an aryl group.

At least two of Q, M, and L₁ may be bonded together to form a ring (preferably a 5-membered or 6-membered ring).

From the viewpoint of forming finer patterns, L₂ is preferably a secondary or tertiary alkyl group, and more preferably a tertiary alkyl group. Examples of the secondary alkyl group include an isopropyl group, a cyclohexyl group, and a norbornyl group; examples of the tertiary alkyl group include a tert-butyl group and an adamantane group. In such examples, Tg (glass transition temperature) and activation energy are increased, so that film hardness is ensured and fogging can also be suppressed.

When the actinic ray-sensitive or radiation-sensitive resin composition is, for example, a resist composition used for EUV exposure, the alkyl groups, cycloalkyl groups, aryl groups, and groups that are combinations of the foregoing represented by L₁ and L₂ also preferably further have, as a substituent, a fluorine atom or an iodine atom. The alkyl groups, the cycloalkyl groups, the aryl groups, and the aralkyl groups also preferably include, in addition to a fluorine atom and an iodine atom, a heteroatom such as an oxygen atom. Specifically, in the alkyl groups, the cycloalkyl groups, the aryl groups, and the aralkyl groups, for example, one of methylene groups may be replaced by a heteroatom such as an oxygen atom or a group including a heteroatom such as a carbonyl group.

When the actinic ray-sensitive or radiation-sensitive resin composition is, for example, a resist composition used for EUV exposure, in the alkyl group that may include a heteroatom, cycloalkyl group that may include a heteroatom, aryl group that may include a heteroatom, amino group, ammonium group, mercapto group, cyano group, aldehyde group, and group that is a combination of the foregoing represented by Q, such a heteroatom is also preferably a heteroatom selected from the group consisting of a fluorine atom, an iodine atom, and an oxygen atom.

In the formula (Y4), Ar represents an aromatic ring group. Rn represents an alkyl group, a cycloalkyl group, or an aryl group. Rn and Ar may be bonded together to form a non-aromatic ring. Ar is preferably an aryl group.

When the actinic ray-sensitive or radiation-sensitive resin composition is, for example, a resist composition used for EUV exposure, the aromatic ring group represented by Ar and the alkyl group, cycloalkyl group, and aryl group represented by Rn also preferably have, as a substituent, a fluorine atom or an iodine atom.

From the viewpoint of providing a repeating unit having high acid-decomposability, in the leaving group protecting the polar group, when a non-aromatic ring is directly bonded to the polar group (or its residue), in the non-aromatic ring, a ring-member atom adjacent to a ring-member atom directly bonded to the polar group (or its residue) also preferably does not have, as a substituent, halogen atoms such as fluorine atoms.

Alternatively, the group that leaves by action of an acid may be a 2-cyclopentenyl group having a substituent (such as an alkyl group) such as a 3-methyl-2-cyclopentenyl group, or a cyclohexyl group having a substituent (such as an alkyl group) such as a 1,1,4,4-tetramethylcyclohexyl group.

The repeating unit having an acid-decomposable group is also preferably a repeating unit represented by a formula (A).

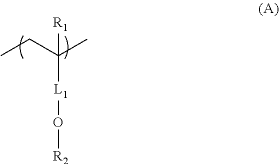

L₁ represents a divalent linking group that may have a fluorine atom or an iodine atom; R₁ represents a hydrogen atom, a fluorine atom, an iodine atom, an alkyl group that may have a fluorine atom or an iodine atom, or an aryl group that may have a fluorine atom or an iodine atom; R₂ represents a leaving group that leaves by action of an acid and that may have a fluorine atom or an iodine atom. Note that at least one of L₁, R₁, or R₂ has a fluorine atom or an iodine atom.

Examples of the divalent linking group that is represented by L₁ and may have a fluorine atom or an iodine atom include —CO—, —O—, —S—, —SO—, —SO₂—, hydrocarbon groups that may have a fluorine atom or an iodine atom (for example, alkylene groups, cycloalkylene groups, alkenylene groups, and arylene groups), and linking groups in which a plurality of the foregoing are linked together. In particular, L₁ is preferably —CO—, an arylene group, or an -arylene group-alkylene group having a fluorine atom or an iodine atom-, and more preferably —CO— or an -arylene group-alkylene group having a fluorine atom or an iodine atom-.

The arylene group is preferably a phenylene group.

The alkylene group may be linear or may be branched. The number of carbon atoms of the alkylene group is not particularly limited, but is preferably 1 to 10, and more preferably 1 to 3.

In the alkylene group having a fluorine atom or an iodine atom, the total number of fluorine atoms and iodine atoms is not particularly limited, but is preferably 2 or more, more preferably 2 to 10, and still more preferably 3 to 6.

The alkyl group represented by R₁ may be linear or may be branched. The number of carbon atoms of the alkyl group is not particularly limited, but is preferably 1 to 10, and more preferably 1 to 3.

In the alkyl group represented by R₁ and having a fluorine atom or an iodine atom, the total number of fluorine atoms and iodine atoms is not particularly limited, but is preferably 1 or more, more preferably 1 to 5, and still more preferably 1 to 3.

The alkyl group represented by R₁ may include a heteroatom other than halogen atoms, such as an oxygen atom.

Examples of the leaving group that is represented by R₂ and may have a fluorine atom or an iodine atom include leaving groups that are represented by the above-described formulas (Y1) to (Y4) and that have a fluorine atom or an iodine atom.

The repeating unit having an acid-decomposable group is also preferably a repeating unit represented by a formula (AI).

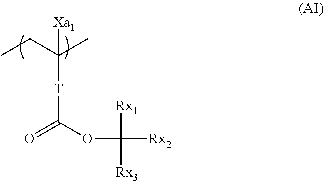

In the formula (AI), Xa₁ represents a hydrogen atom or an alkyl group that may have a substituent. T represents a single bond or a divalent linking group. Rx₁ to Rx₃ each independently represent an alkyl group (linear or branched), a cycloalkyl group (monocyclic or polycyclic), an alkenyl group (linear or branched), or an aryl group (monocyclic or polycyclic). Note that, when Rx₁ to Rx₃ are all alkyl groups (linear or branched), at least two of Rx₁ to Rx₃ are preferably methyl groups.

Two of Rx₁ to Rx₃ may be bonded together to form a monocycle or a polycycle (such as a monocyclic or polycyclic cycloalkyl group).

The alkyl group that is represented by Xa₁ and may have a substituent may be, for example, a methyl group or a group represented by —CH₂—R₁₁. R₁₁ represents a halogen atom (such as a fluorine atom), a hydroxy group, or a monovalent organic group. The monovalent organic group represented by R₁₁ is, for example, an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, and is preferably an alkyl group having 3 or less carbon atoms, and more preferably a methyl group. Xa₁ is preferably a hydrogen atom, a methyl group, a trifluoromethyl group, or a hydroxymethyl group.

For T, the divalent linking group may be an alkylene group, an aromatic ring group, a —COO-Rt- group, or an —O-Rt- group. In the formulas, Rt represent an alkylene group or a cycloalkylene group.

T is preferably a single bond or a —COO-Rt- group. When T represents a —COO-Rt- group, Rt is preferably an alkylene group having 1 to 5 carbon atoms, and more preferably a —CH₂— group, a —(CH₂)₂— group, or a —(CH₂)₃— group.

For Rx₁ to Rx₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Rx₁ to Rx₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Rx₁ to Rx₃, the aryl group is preferably an aryl group having 6 to 10 carbon atoms and may be, for example, a phenyl group, a naphthyl group, or an anthryl group.

For Rx₁ to Rx₃, the alkenyl group is preferably a vinyl group.

The cycloalkyl group formed by bonding together two of Rx₁ to Rx₃ is preferably a monocyclic cycloalkyl group such as a cyclopentyl group or a cyclohexyl group. Also preferred are polycyclic cycloalkyl groups such as a norbornyl group, a tetracyclodecanyl group, a tetracyclododecanyl group, and an adamantyl group. In particular, preferred is a monocyclic cycloalkyl group having 5 to 6 carbon atoms.

In the cycloalkyl group formed by bonding together two of Rx₁ to Rx₃, for example, one of methylene groups constituting the ring may be replaced by a heteroatom such as an oxygen atom, a group including a heteroatom such as a carbonyl group, or a vinylidene group. In the cycloalkyl group, one or more of the ethylene groups constituting the cycloalkane ring may be replaced by a vinylene group.

The repeating unit represented by the formula (AI) preferably has a form in which, for example, Rx₁ is a methyl group or an ethyl group, and Rx₂ and Rx₃ are bonded together to form the above-described cycloalkyl group.

When the above-described groups each have a substituent, examples of the substituent include alkyl groups (having 1 to 4 carbon atoms), halogen atoms, a hydroxyl group, alkoxy groups (having 1 to 4 carbon atoms), a carboxyl group, and alkoxycarbonyl groups (having 2 to 6 carbon atoms). The substituent preferably has 8 or less carbon atoms.

The repeating unit represented by the formula (AI) is preferably an acid-decomposable (meth)acrylic acid tertiary alkyl ester-based repeating unit (the repeating unit where Xa₁ represents a hydrogen atom or a methyl group and T represents a single bond).

The following are non-limiting specific examples of the repeating unit having an acid-decomposable group. Note that, in the formulas, Xa₁ represent H, CH₃, CF₃, or CH₂OH, and Rxa and Rxb each independently represent a linear or branched alkyl group having 1 to 5 carbon atoms.

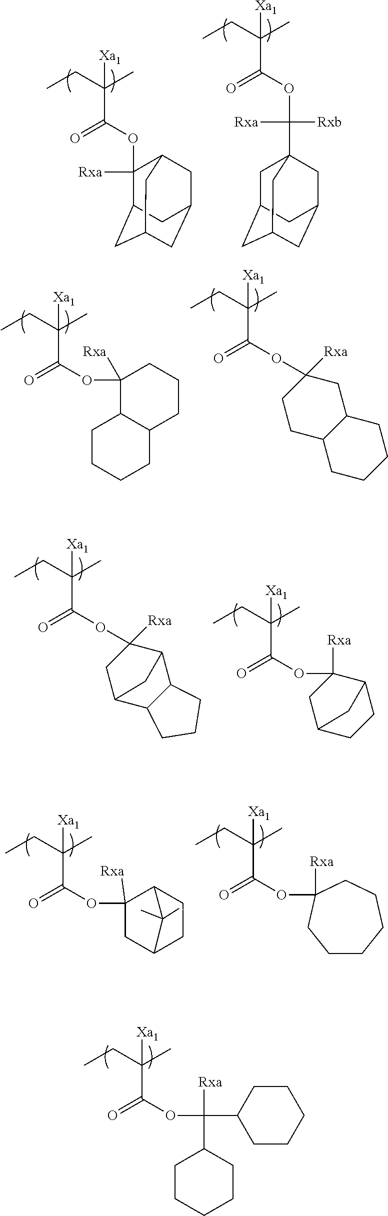

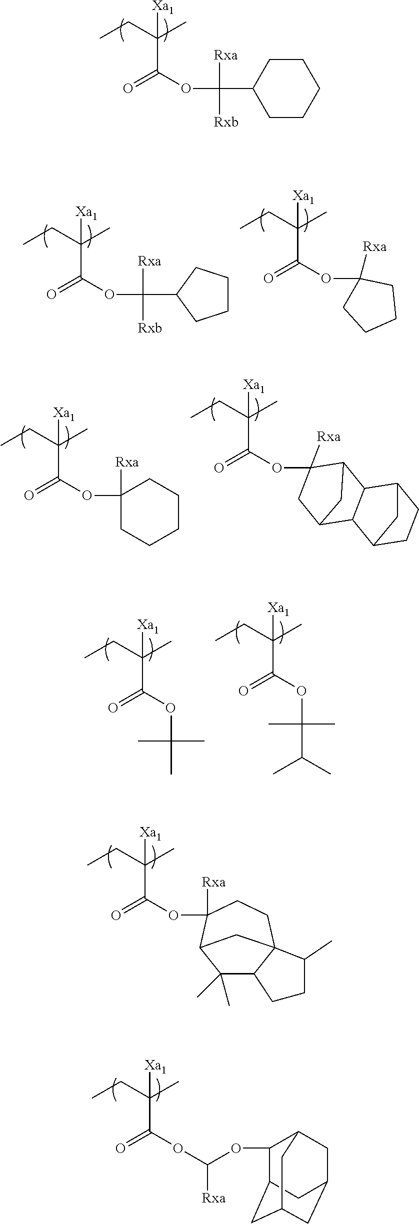

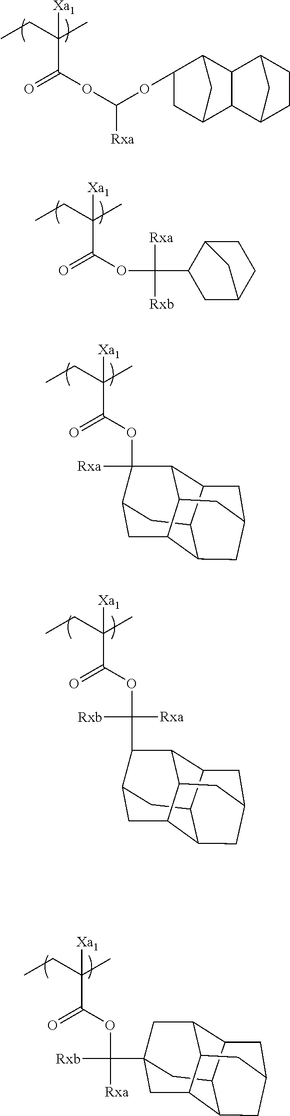

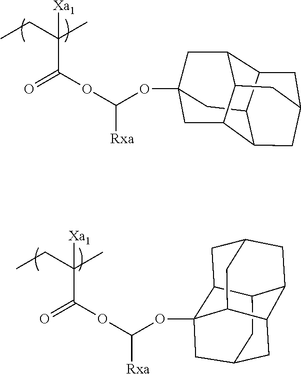

The resin (A) may have, as a repeating unit having an acid-decomposable group, a repeating unit having an acid-decomposable group including an unsaturated bond.

The repeating unit having an acid-decomposable group including an unsaturated bond is preferably a repeating unit represented by a formula (B).

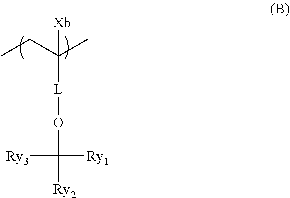

In the formula (B), Xb represents a hydrogen atom, a halogen atom, or an alkyl group that may have a substituent. L represents a single bond or a divalent linking group that may have a substituent. Ry₁ to Ry₃ each independently represent a linear or branched alkyl group, a monocyclic or polycyclic cycloalkyl group, an alkenyl group, an alkynyl group, or a monocyclic or polycyclic aryl group. Note that at least one of Ry₁ to Ry₃ represents an alkenyl group, an alkynyl group, a monocyclic or polycyclic cycloalkenyl group, or a monocyclic or polycyclic aryl group.

Two of Ry₁ to Ry₃ may be bonded together to form a monocycle or a polycycle (such as a monocyclic or polycyclic cycloalkyl group or cycloalkenyl group).

For Xb, the alkyl group that may have a substituent may be, for example, a methyl group or a group represented by —CH₂—R₁₁. R₁₁ represents a halogen atom (such as a fluorine atom), a hydroxy group, or a monovalent organic group such as an alkyl group that has 5 or less carbon atoms and that may be substituted with a halogen atom, an acyl group that has 5 or less carbon atoms and that may be substituted with a halogen atom, or an alkoxy group that has 5 or less carbon atoms and that may be substituted with a halogen atom, is preferably an alkyl group having 3 or less carbon atoms, and more preferably a methyl group. Xb is preferably a hydrogen atom, a fluorine atom, a methyl group, a trifluoromethyl group, or a hydroxymethyl group.

For L, the divalent linking group may be an -Rt- group, a —CO— group, a —COO-Rt- group, a —COO-Rt-CO— group, an -Rt-CO— group, or an —O-Rt- group. In the formulas, Rt represent an alkylene group, a cycloalkylene group, or an aromatic ring group, and is preferably an aromatic ring group.

L is preferably an -Rt- group, a —CO— group, a —COO-Rt-CO— group, or an -Rt-CO— group. Rt may have a substituent such as a halogen atom, a hydroxy group, or an alkoxy group.

For Ry₁ to Ry₃, the alkyl group is preferably an alkyl group having 1 to 4 carbon atoms such as a methyl group, an ethyl group, an n-propyl group, an isopropyl group, an n-butyl group, an isobutyl group, or a t-butyl group.

For Ry₁ to Ry₃, the cycloalkyl group is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

For Ry₁ to Ry₃, the aryl group is preferably an aryl group having 6 to 10 carbon atoms, and may be, for example, a phenyl group, a naphthyl group, or an anthryl group.

For Ry₁ to Ry₃, the alkenyl group is preferably a vinyl group.

For Ry₁ to Ry₃, the alkynyl group is preferably an ethynyl group.

For Ry₁ to Ry₃, the cycloalkenyl group is preferably a structure in which a monocyclic cycloalkyl group such as a cyclopentyl group or a cyclohexyl group includes partially a double bond.

The cycloalkyl group formed by bonding together two of Ry₁ to Ry₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. In particular, more preferred is a monocyclic cycloalkyl group having 5 to 6 carbon atoms.

In the cycloalkyl group or the cycloalkenyl group formed by bonding together two of Ry₁ to Ry₃, for example, one of methylene groups constituting the ring may be replaced by a heteroatom such as an oxygen atom, a group including a heteroatom such as a carbonyl group, a —SO₂— group, or a —SO₃— group, a vinylidene group, or a combination of the foregoing. In the cycloalkyl group or the cycloalkenyl group, one or more ethylene groups constituting the cycloalkane ring or the cycloalkene ring may be replaced by a vinylene group.

The repeating unit represented by the formula (B) preferably has a form in which, for example, Ry₁ is a methyl group, an ethyl group, a vinyl group, an allyl group, or an aryl group, and Ry₂ and Ry₃ are bonded together to form the above-described cycloalkyl group or cycloalkenyl group.

When the above-described groups each have a substituent, examples of the substituent include alkyl groups (having 1 to 4 carbon atoms), halogen atoms, a hydroxyl group, alkoxy groups (having 1 to 4 carbon atoms), a carboxyl group, and alkoxycarbonyl groups (having 2 to 6 carbon atoms). The substituent preferably has 8 or less carbon atoms.

The repeating unit represented by the formula (B) is preferably an acid-decomposable (meth)acrylic acid tertiary ester-based repeating unit (the repeating unit where Xb represents a hydrogen atom or a methyl group, and L represents a —CO— group), an acid-decomposable hydroxystyrene tertiary alkyl ether-based repeating unit (the repeating unit where Xb represents a hydrogen atom or a methyl group, and L represents a phenyl group), or an acid-decomposable styrenecarboxylic acid tertiary ester-based repeating unit (the repeating unit where Xb represents a hydrogen atom or a methyl group, and L represents an -Rt-CO— group (where Rt is an aromatic group)).

The content of the repeating unit having an acid-decomposable group including an unsaturated bond relative to all the repeating units in the resin (A) is preferably 15 mol % or more, more preferably 20 mol % or more, and still more preferably 30 mol % or more. The upper limit value relative to all the repeating units in the resin (A) is preferably 80 mol % or less, more preferably 70 mol % or less, and still more preferably 60 mol % or less.

Specific examples of the repeating unit having an acid-decomposable group including an unsaturated bond include, for example, the repeating units described in [0067] to [0071] of WO2022/024928A. The above descriptions are incorporated herein.

The content of the repeating unit having an acid-decomposable group relative to all the repeating units in the resin (A) is preferably 15 mol % or more, more preferably 20 mol % or more, and still more preferably 30 mol % or more. The upper limit value relative to all the repeating units in the resin (A) is preferably 90 mol % or less, more preferably 80 mol % or less, still more preferably 70 mol % or less, and particularly preferably 60 mol % or less.

The resin (A) may include at least one repeating unit species selected from the group consisting of the following Group A and/or at least one repeating unit species selected from the group consisting of the following Group B.
Group A: a group consisting of the following repeating units (20) to (25),
(20) a repeating unit (described later) having an acid group;
(21) a repeating unit (described later) not having an acid-decomposable group or an acid group, but having a fluorine atom, a bromine atom, or an iodine atom;
(22) a repeating unit (described later) having a lactone group, a sultone group, or a carbonate group;
(23) a repeating unit (described later) having a photoacid generation group;
(24) a repeating unit (described later) represented by a formula (V-1) or a formula (V-2) below; and
(25) a repeating unit for lowering the mobility of the main chain.

Note that the repeating units described later and represented by a formula (A) to a formula (E) correspond to the repeating unit (25) for lowering the mobility of the main chain.
Group B: the group consisting of the following repeating units (30) to (32),
(30) a repeating unit (described later) having at least one group species selected from the group consisting of a lactone group, a sultone group, a carbonate group, a hydroxy group, a cyano group, and an alkali-soluble group;
(31) a repeating unit (described later) having an alicyclic hydrocarbon structure and not exhibiting acid-decomposability; and
(32) a repeating unit (described later) not having a hydroxy group or a cyano group and represented by a formula (III).

The resin (A) preferably has an acid group and preferably includes a repeating unit having an acid group as described later. Note that the definition of the acid group will be described in a later part together with preferred examples of the repeating unit having an acid group. When the resin (A) has an acid group, a better interaction between the resin (A) and the acid generated from the photoacid generator is provided. This results in further suppression of diffusion of the acid, so that a pattern having a more square profile can be formed.

The resin (A) may have at least one repeating unit species selected from the group consisting of Group A above. When the actinic ray-sensitive or radiation-sensitive resin composition is used as an actinic ray-sensitive or radiation-sensitive resin composition for EUV exposure, the resin (A) preferably has at least one repeating unit species selected from the group consisting of Group A above.

The resin (A) may include at least one of a fluorine atom or an iodine atom. When the actinic ray-sensitive or radiation-sensitive resin composition is used as an actinic ray-sensitive or radiation-sensitive resin composition for EUV exposure, the resin (A) preferably includes at least one of a fluorine atom or an iodine atom. When the resin (A) includes both of a fluorine atom and an iodine atom, the resin (A) may have a repeating unit including both of a fluorine atom and an iodine atom, or the resin (A) may include two species that are a repeating unit having a fluorine atom and a repeating unit including an iodine atom.

The resin (A) may have a repeating unit having an aromatic group. When the actinic ray-sensitive or radiation-sensitive resin composition is used as an actinic ray-sensitive or radiation-sensitive resin composition for EUV exposure, the resin (A) also preferably has a repeating unit having an aromatic group.

The resin (A) may have at least one repeating unit species selected from the group consisting of Group B above. When the actinic ray-sensitive or radiation-sensitive resin composition is used as an actinic ray-sensitive or radiation-sensitive resin composition for ArF, the resin (A) preferably has at least one repeating unit species selected from the group consisting of Group B above.

Note that, when the actinic ray-sensitive or radiation-sensitive resin composition is used as an actinic ray-sensitive or radiation-sensitive resin composition for ArF, the resin (A) preferably does not include fluorine atoms or silicon atoms.

When the actinic ray-sensitive or radiation-sensitive resin composition is used as an actinic ray-sensitive or radiation-sensitive resin composition for ArF, the resin (A) preferably does not have aromatic groups.

### Repeating Unit Having Acid Group

The resin (A) may have a repeating unit having an acid group.

The acid group is preferably an acid group having a pKa of 13 or less. The acid group preferably has an acid dissociation constant of 13 or less, more preferably 3 to 13, and still more preferably 5 to 10.

When the resin (A) has an acid group having a pKa of 13 or less, the content of the acid group in the resin (A) is not particularly limited, but is often 0.2 to 6.0 mmol/g. In particular, preferred is 0.8 to 6.0 mmol/g, more preferred is 1.2 to 5.0 mmol/g, and still more preferred is 1.6 to 4.0 mmol/g. When the content of the acid group is within such a range, development suitably proceeds to form a pattern having a good profile at high resolution.

The acid group is preferably, for example, a carboxyl group, a phenolic hydroxyl group, a fluoroalcohol group (preferably a hexafluoroisopropanol group), a sulfonic acid group, a sulfonamide group, or an isopropanol group.

In the hexafluoroisopropanol group, one or more (preferably one to two) of the fluorine atoms may be substituted with groups other than fluorine atoms (such as alkoxycarbonyl groups). The acid group is also preferably —C(CF₃)(OH)—CF₂— formed in this manner. Alternatively, one or more of the fluorine atoms may be substituted with groups other than fluorine atoms, to form a ring including —C(CF₃)(OH)—CF₂—.

The repeating unit having an acid group is preferably a repeating unit different from the above-described repeating unit having a structure in which a polar group is protected with a group that leaves by action of an acid and repeating units described later and having a lactone group, a sultone group, or a carbonate group.

The repeating unit having an acid group may have a fluorine atom or an iodine atom.

Specific examples of the repeating unit having an acid group include, for example, the repeating units described in [0088] to [0089] and [0103] to [0110] of WO2022/024928A. The above descriptions are incorporated herein.

The repeating unit having an acid group is preferably a repeating unit represented by a formula (b1-1) below.

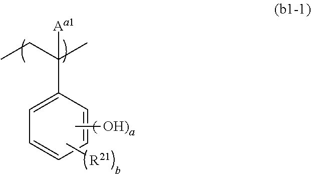

In the formula (b1-1), A^{a1} represents a hydrogen atom, an alkyl group, a cycloalkyl group, a halogen atom, or a cyano group. R²¹ represents a halogen atom, an alkyl group, a cycloalkyl group, an aryl group, an alkenyl group, an aralkyl group, an alkoxy group, an alkylcarbonyloxy group, an alkylsulfonyloxy group, an alkyloxycarbonyl group, or an aryloxycarbonyl group; when there are a plurality of R²¹'s, they may be the same or different. When the formula has a plurality of R²¹'s, they may together form a ring. A^{a1} is preferably a hydrogen atom. a represents an integer of 1 to 3. b represents an integer of 0 to (5-a).

When the resin (A) includes a repeating unit having an acid group, the content of the repeating unit having an acid group is, relative to all the repeating units in the resin (A), preferably 10 mol % or more, and more preferably 15 mol % or more. The upper limit value relative to all the repeating units in the resin (A) is preferably 70 mol % or less, more preferably 65 mol % or less, and still more preferably 60 mol % or less.

### Repeating Unit not Having Acid-Decomposable Group or Acid Group, but Having Fluorine Atom, Bromine Atom, or Iodine Atom

The resin (A) may have, in addition to the above-described <repeating unit having an acid-decomposable group> and <repeating unit having an acid group>, a repeating unit not having an acid-decomposable group or an acid group, but having a fluorine atom, a bromine atom, or an iodine atom (hereinafter, also referred to as unit X). This <repeating unit not having an acid-decomposable group or an acid group, but having a fluorine atom, a bromine atom, or an iodine atom> is preferably different from other repeating unit species belonging to Group A such as a <repeating unit having a lactone group, a sultone group, or a carbonate group> and a <repeating unit having a photoacid generation group> described later.

The unit X is preferably a repeating unit represented by a formula (C).

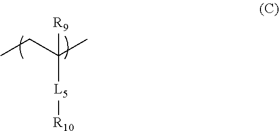

L₅ represents a single bond or an ester group. R₉ represents a hydrogen atom or an alkyl group that may have a fluorine atom or an iodine atom. R₁₀ represents a hydrogen atom, an alkyl group that may have a fluorine atom or an iodine atom, a cycloalkyl group that may have a fluorine atom or an iodine atom, an aryl group that may have a fluorine atom or an iodine atom, or a group that is a combination of the foregoing.

Specific examples of the repeating unit having a fluorine atom or an iodine atom include, for example, the repeating units described in [0116] to [0117] of WO2022/024928A. The above descriptions are incorporated herein.

The unit X content relative to all the repeating units in the resin (A) is preferably 0 mol % or more, more preferably 5 mol % or more, and still more preferably 10 mol % or more. The upper limit value relative to all the repeating units in the resin (A) is preferably 50 mol % or less, more preferably 45 mol % or less, and still more preferably 40 mol % or less.

Of the repeating units of the resin (A), the total content of the repeating unit including at least one of a fluorine atom, a bromine atom, or an iodine atom relative to all the repeating units of the resin (A) is preferably 10 mol % or more, more preferably 20 mol % or more, still more preferably 30 mol % or more, and particularly preferably 40 mol % or more. The upper limit value is not particularly limited, but is, for example, relative to all the repeating units of the resin (A), 100 mol % or less.

Note that examples of the repeating unit including at least one of a fluorine atom, a bromine atom, or an iodine atom include a repeating unit having a fluorine atom, a bromine atom, or an iodine atom and having an acid-decomposable group, a repeating unit having a fluorine atom, a bromine atom, or an iodine atom and having an acid group, and a repeating unit having a fluorine atom, a bromine atom, or an iodine atom.

### Repeating Unit Having Lactone Group, Sultone Group, or Carbonate Group

The resin (A) may have a repeating unit (hereinafter, also referred to as “unit Y”) having at least one selected from the group consisting of a lactone group, a sultone group, and a carbonate group.

The unit Y also preferably does not have acid groups such as a hydroxy group and a hexafluoropropanol group.

The lactone group or the sultone group has a lactone structure or a sultone structure. The lactone structure or the sultone structure is preferably a 5- to 7-membered lactone structure or a 5- to 7-membered sultone structure. In particular, more preferred is a 5- to 7-membered lactone structure to which another ring structure is fused so as to form a bicyclo structure or a spiro structure, or a 5- to 7-membered sultone structure to which another ring structure is fused so as to form a bicyclo structure or a spiro structure.

The resin (A) preferably has a repeating unit having a lactone group, a sultone group, or a carbonate group obtained by removing one or more hydrogen atoms from ring-member atoms of a lactone structure represented by any one of the following formulas (LC1-1) to (LC1-22), a sultone structure represented by any one of the following formulas (SL1-1) to (SL1-3), or a cyclic carbonic acid ester structure represented by any one of the following formulas (CC1-1) to (CC1-2), and the lactone group, the sultone group, or the carbonate group may be directly bonded to the main chain. For example, the ring-member atoms of the lactone group, the sultone group, or the carbonate group may constitute the main chain of the resin (A). The lactone group, the sultone group, and the carbonate group may have a substituent.

In the following structural formulas, R^{L} represent a substituent. When a plurality of R^{L} are present, the plurality of R^{L} may be the same or different. R^{L} may be, for example, an alkyl group having 1 to 8 carbon atoms, a cycloalkyl group having 4 to 10 carbon atoms, an alkoxy group having 1 to 8 carbon atoms, an alkoxycarbonyl group having 2 to 8 carbon atoms, a carboxyl group, a halogen atom, a cyano group, or an acid-decomposable group. e1 represent an integer of 0 to 4. When a plurality of e1 are present, the plurality of e1 may be the same or may be different. When e1 is 2 or more, the plurality of R^{L} present may be the same or different, and the plurality of R^{L} present may bonded together to form a ring.

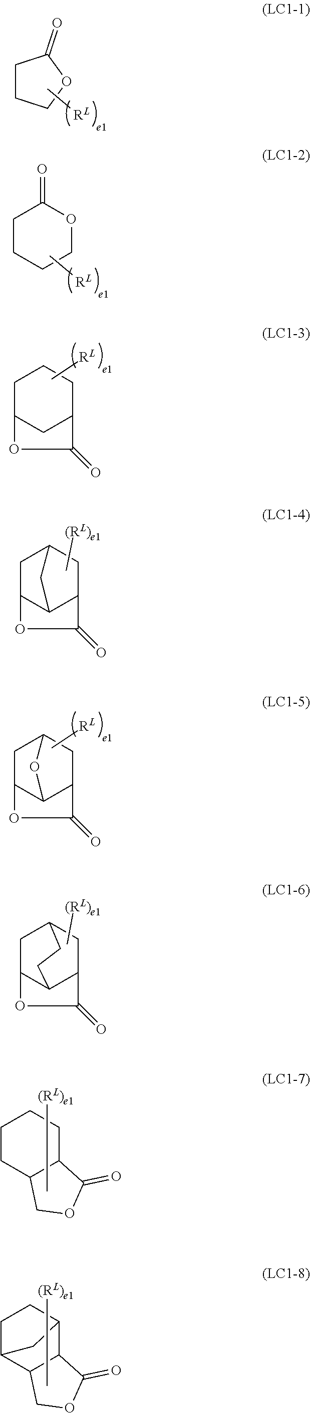

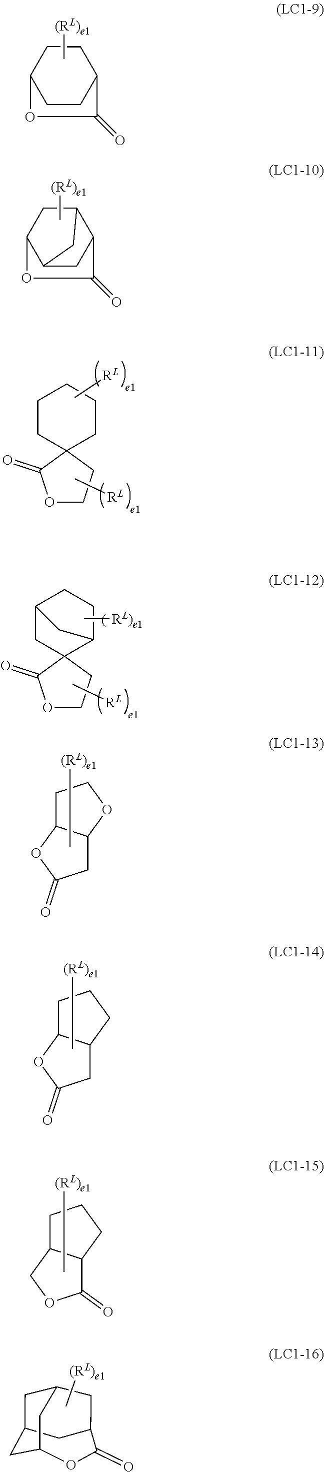

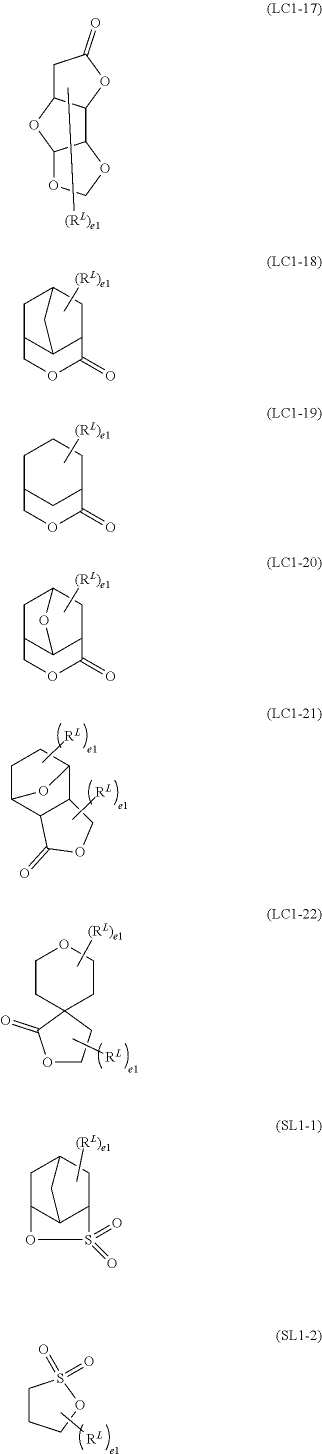

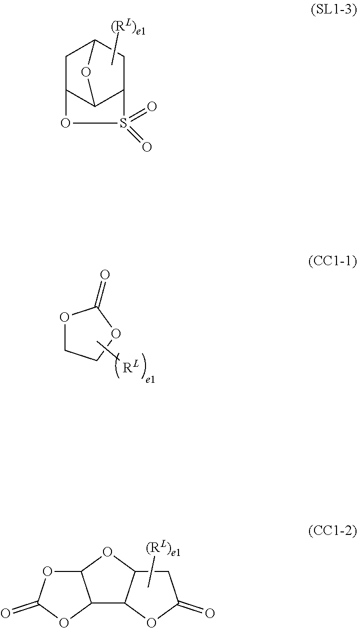

Examples of the repeating unit having a lactone group, a sultone group, or a carbonate group include a repeating unit represented by the following formula (AI-2).

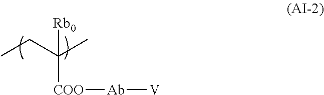

In the formula (AI-2), Rb₀ represents a hydrogen atom, a halogen atom, or an alkyl group having 1 to 4 carbon atoms. Preferred examples of the substituent that the alkyl group of Rb₀ may have include a hydroxy group and a halogen atom.

For Rb₀, the halogen atom may be a fluorine atom, a chlorine atom, a bromine atom, or an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent linking group that is a combination of the foregoing. In particular, Ab is preferably a single bond or a linking group represented by -Ab₁-CO₂—. Ab₁ is a linear or branched alkylene group or a monocyclic or polycyclic cycloalkylene group, and preferably a methylene group, an ethylene group, a cyclohexylene group, an adamantylene group, or a norbornylene group.

V represents a group formed by removing one hydrogen atom from a ring-member atom of a lactone structure represented by any one of the formulas (LC1-1) to (LC1-22), a group formed by removing one hydrogen atom from a ring-member atom of a sultone structure represented by any one of the formulas (SL1-1) to (SL1-3), or a group formed by removing one hydrogen atom from a ring-member atom of a cyclic carbonic acid ester structure represented by any one of the formulas (CC1-1) to (CC1-2).

When the repeating unit having a lactone group or a sultone group has an optical isomer, any optical isomer may be used. A single optical isomer may be used alone, or a plurality of optical isomers may be used in combination. In the case of mainly using one of the optical isomers, its optical purity (ee) is preferably 90 or more, and more preferably 95 or more.

The carbonate group is preferably a cyclic carbonic acid ester group.

For the repeating unit having a cyclic carbonic acid ester group, for example, the descriptions in [0127] to [0133] of WO2022/024928A can be referred to. The above descriptions are incorporated herein.

When the resin (A) includes the unit Y, the content of the unit Y relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

### Repeating Unit Having Photoacid Generation Group

The resin (A) may have, as another repeating unit, a repeating unit having a group that generates an acid upon irradiation with an actinic ray or a radiation (also referred to as “photoacid generation group”).

The repeating unit having a photoacid generation group may be a repeating unit represented by a formula (4).

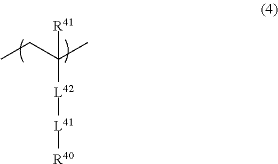

R⁴¹ represents a hydrogen atom or a methyl group. L⁴¹ represents a single bond or a divalent linking group. L⁴² represents a divalent linking group. R⁴⁰ represents a structural moiety that is decomposed upon irradiation with an actinic ray or a radiation to generate an acid in the side chain.

Specific examples of the repeating unit having a photoacid generation group include, for example, the repeating units described in [0094] to [0105] of JP2014-041327A, the repeating units described in [0094] of WO2018/193954A, and the repeating units described in [0138] of WO2022/024928A. The above descriptions are incorporated herein.

Examples of the repeating unit represented by the formula (4) include the repeating units described in Paragraphs [0094] to [0105] of JP2014-041327A, and the repeating units described in Paragraph [0094] of WO2018/193954A.

When the resin (A) includes a repeating unit having a photoacid generation group, the content of the repeating unit having a photoacid generation group relative to all the repeating units in the resin (A) is preferably 1 mol % or more, more preferably 3 mol % or more, and particularly preferably 5 mol % or more. The content of the repeating unit having a photoacid generation group relative to all the repeating units in the resin (A) is preferably 40 mol % or less, more preferably 30 mol % or less, and particularly preferably 20 mol % or less.

The resin (A) also preferably does not include a repeating unit having a photoacid generation group.

### Repeating Unit Represented by Formula (V-1) or Formula (V-2) Below

The resin (A) may have a repeating unit represented by a formula (V-1) below or a formula (V-2) below.

The repeating unit represented by the formula (V-1) below or the formula (V-2) below is preferably a repeating unit different from the above-described repeating units.

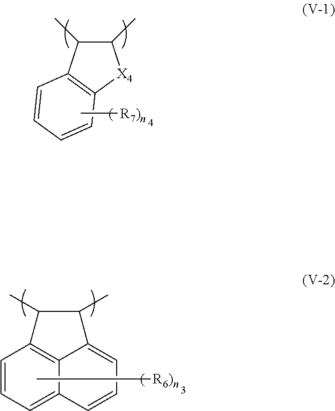

In the formulas,
R₆ and R₇ each independently represent a hydrogen atom, a hydroxyl group, an alkyl group, an alkoxy group, an acyloxy group, a cyano group, a nitro group, an amino group, a halogen atom, an ester group (—OCOR or —COOR: R is an alkyl group or a fluorinated alkyl group having 1 to 6 carbon atoms), or a carboxyl group. The alkyl group is preferably a linear, branched, or cyclic alkyl group having 1 to 10 carbon atoms.
n₃ represents an integer of 0 to 6.
n₄ represents an integer of 0 to 4.
X₄ is a methylene group, an oxygen atom, or a sulfur atom.

Examples of the repeating unit represented by the formula (V-1) or (V-2) are as follows.

Examples of the repeating unit represented by the formula (V-1) or (V-2) include the repeating units described in Paragraph [0100] of WO2018/193954A.

### Repeating Unit for Lowering Mobility of Main Chain

The resin (A) preferably has, from the viewpoint of suppressing excessive diffusion of the generated acid or pattern collapse during development, a relatively high glass transition temperature (Tg). Tg is preferably more than 90° C., more preferably more than 100° C., still more preferably more than 110° C., and particularly preferably more than 125° C. Note that, from the viewpoint of having a high dissolution rate in developers, Tg is preferably 400° C. or less, and more preferably 350° C. or less.

Note that, in this Specification, the glass transition temperatures (Tg) of polymers such as the resin (A) (hereafter, “Tg's of repeating units”) are calculated in the following manner. First, for the repeating units included in a polymer, the Tg's of homopolymers composed only of the repeating units are individually calculated by the Bicerano method. Subsequently, the mass ratios (%) of the repeating units relative to all the repeating units in the polymer are calculated. Subsequently, the Fox equation (described in Materials Letters 62 (2008) 3152, for example) is used to calculate Tg's for the mass ratios and the Tg's are summed up to determine the Tg(° C.) of the polymer.

The Bicerano method is described in Prediction of polymer properties, Marcel Dekker Inc, New York (1993). The calculation of Tg by the Bicerano method can be performed using the software for estimating properties of polymers, MDL Polymer (MDL Information Systems, Inc.).

In order to increase the Tg of the resin (A) (preferably, making Tg be more than 90° C.), the mobility of the main chain of the resin (A) is preferably lowered. Examples of the method for lowering the mobility of the main chain of the resin (A) include the following methods (a) to (e):
(a) introduction of a bulky substituent to the main chain;
(b) introduction of a plurality of substituents to the main chain;
(c) introduction of a substituent that induces interaction between the resins (A), to the vicinity of the main chain;
(d) formation of the main chain using a ring structure; and
(e) linkage of a ring structure to the main chain.

Note that the resin (A) preferably has a repeating unit whose homopolymer has a Tg of 130° C. or more.

Note that the repeating unit species whose homopolymer has a Tg of 130° C. or more is not particularly limited and is a repeating unit whose homopolymer has a Tg of 130° C. or more calculated by the Bicerano method. Note that the repeating units represented by a formula (A) to a formula (E) described later may, depending on the functional group species, belong to the repeating unit whose homopolymer has a Tg of 130° C. or more.

An example of specific means for achieving (a) above is a method of introducing, into the resin (A), a repeating unit represented by a formula (A).

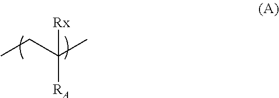

For the formula (A), R_{A} represents a group including a polycyclic structure. Rₓ represents a hydrogen atom, a methyl group, or an ethyl group. The group including a polycyclic structure is a group including a plurality of cyclic structures; the plurality of cyclic structures may be fused together or may not be fused together.

Specific examples of the repeating unit represented by the formula (A) include those described in Paragraphs [0107] to [0119] of WO2018/193954A.

An example of specific means for achieving (b) above is a method of introducing, into the resin (A), a repeating unit represented by a formula (B).

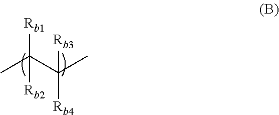

In the formula (B), R_{b1} to R_{b4} each independently represent a hydrogen atom or an organic group; at least two or more of R_{b1} to R_{b4} represent organic groups.

When at least one of the organic groups is a group whose cyclic structure is directly linked to the main chain in the repeating unit, the other organic group species is not particularly limited.

When none of the organic groups is a group whose cyclic structure is directly linked to the main chain in the repeating unit, at least two or more of the organic groups are substituents having three or more constituent atoms (except for hydrogen atoms).

Specific examples of the repeating unit represented by the formula (B) include those described in Paragraphs [0113] to [0115] of WO2018/193954A.

An example of specific means for achieving (c) above is a method of introducing, into the resin (A), a repeating unit represented by a formula (C).

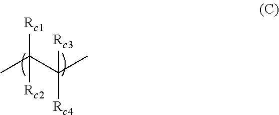

In the formula (C), R_{c1} to R_{c4} each independently represent a hydrogen atom or an organic group; at least one of R_{c1} to R_{c4} is a group including a hydrogen-bond-forming hydrogen atom positioned within three atoms from the carbon atom in the main chain. In particular, from the viewpoint of inducing the interaction between the main chains of the resin (A), it preferably has a hydrogen-bond-forming hydrogen atom positioned within two atoms (closer to the main chain side).

Specific examples of the repeating unit represented by the formula (C) include those described in Paragraphs [0119] to [0121] of WO2018/193954A.

An example of specific means for achieving (d) above is a method of introducing, into the resin (A), a repeating unit represented by a formula (D).

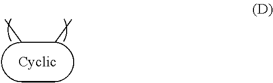

In the formula (D), “Cyclic” represents a group in which the ring structure forms the main chain. The number of atoms constituting the ring is not particularly limited.

Specific examples of the repeating unit represented by the formula (D) include those described in Paragraphs [0126] to [0127] of WO2018/193954A.

An example of specific means for achieving (e) above is a method of introducing, into the resin (A), a repeating unit represented by a formula (E).

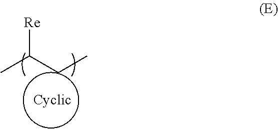

In the formula (E), Re each independently represent a hydrogen atom or an organic group. Examples of the organic group include alkyl groups, cycloalkyl groups, aryl groups, aralkyl groups, and alkenyl groups that may have substituents.

“Cyclic” is a cyclic group including a carbon atom of the main chain. The number of atoms included in the cyclic group is not particularly limited.

Specific examples of the repeating unit represented by the formula (E) include those described in Paragraphs [0131] to [0133] of WO2018/193954A.

Repeating Unit Having at Least One Group Species Selected from the Group Consisting of Lactone Group, Sultone Group, Carbonate Group, Hydroxy Group, Cyano Group, and Alkali-Soluble Group

The resin (A) may have a repeating unit having at least one group species selected from the group consisting of a lactone group, a sultone group, a carbonate group, a hydroxy group, a cyano group, and an alkali-soluble group.

In the resin (A), the repeating unit having a lactone group, a sultone group, or a carbonate group may be the repeating unit having been described above in <Repeating unit having lactone group, sultone group, or carbonate group>. Preferred contents are also the same as those having been described above in <Repeating unit having lactone group, sultone group, or carbonate group>.

The resin (A) may have a repeating unit having a hydroxy group or a cyano group. This results in improvement in adhesiveness to the substrate and affinity for the developer.

The repeating unit having a hydroxy group or a cyano group is preferably a repeating unit having an alicyclic hydrocarbon structure substituted with a hydroxy group or a cyano group.

The repeating unit having a hydroxy group or a cyano group preferably does not have an acid-decomposable group. Examples of the repeating unit having a hydroxy group or a cyano group include those described in Paragraphs [0081] to [0084] of JP2014-098921A.

The resin (A) may have a repeating unit having an alkali-soluble group.

The alkali-soluble group may be a carboxyl group, a sulfonamide group, a sulfonylimide group, a bissulfonylimide group, or an aliphatic alcohol group substituted, at the a position, with an electron-withdrawing group (for example, a hexafluoroisopropanol group), and is preferably a carboxyl group. When the resin (A) includes the repeating unit having an alkali-soluble group, increased resolution is provided in the contact hole application. Examples of the repeating unit having an alkali-soluble group include those described in Paragraphs [0085] and [0086] of JP2014-098921A.

### Repeating Unit Having Alicyclic Hydrocarbon Structure and not Exhibiting Acid-Decomposability

The resin (A) may have a repeating unit having an alicyclic hydrocarbon structure and not exhibiting acid-decomposability. This results in, during liquid immersion exposure, a reduction in leaching of, from the resist film to the immersion liquid, low-molecular-weight components. Examples of the repeating unit having an alicyclic hydrocarbon structure and not exhibiting acid-decomposability include a repeating unit derived from 1-adamantyl (meth)acrylate, diadamantyl (meth)acrylate, tricyclodecanyl (meth)acrylate, or cyclohexyl (meth)acrylate.

### Repeating Unit not Having Hydroxy Group or Cyano Group and Represented by Formula (III)

The resin (A) may have a repeating unit not having a hydroxy group or a cyano group and represented by a formula (III).

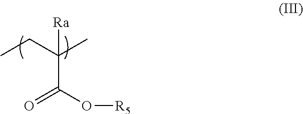

In the formula (III), R₅ represents a hydrocarbon group having at least one ring structure and not having a hydroxy group or a cyano group.

Ra represents a hydrogen atom, an alkyl group, or a —CH₂—O—Ra₂ group. In the formula, Ra₂ represents a hydrogen atom, an alkyl group, or an acyl group.

Examples of the repeating unit not having a hydroxy group or a cyano group and represented by the formula (III) include those described in Paragraphs [0087] to [0094] of JP2014-098921A.

### Repeating Unit Represented by Formula (AP-1)

The resin (A) also preferably has a repeating unit represented by the following formula (AP-1).

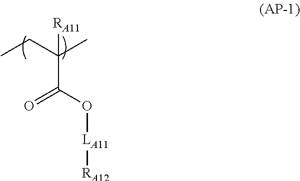

In the formula (AP-1), R_{A11} represents a hydrogen atom, a halogen atom, or an alkyl group. L_{A11} represents a single bond or a divalent linking group. R_{A12} represents a cyclic group including an SO₂ group.

Examples of the halogen atom represented by R_{A11} in the formula (AP-1) include a fluorine atom, a chlorine atom, a bromine atom, and an iodine atom.

The alkyl group represented by R_{A11} is preferably an alkyl group having 1 to 4 carbon atoms, and more preferably a methyl group. The alkyl group represented by R_{A11} may have a substituent. The substituent may be a hydroxyl group or a halogen atom.

R_{A11} is preferably a hydrogen atom or a methyl group.

The divalent linking group represented by L_{A11} in the formula (AP-1) is not particularly limited, but may be an alkylene group, a divalent linking group having a monocyclic or polycyclic alicyclic hydrocarbon structure, an ether group, an ester group, a carbonyl group, a carboxyl group, or a divalent linking group that is a combination of the foregoing.

L_{A11} is preferably a single bond or a linking group represented by -L_{A111}-CO₂—. L_{A111} represents a linear or branched alkylene group, or a monocyclic or polycyclic cycloalkylene group, and preferably represents a methylene group, an ethylene group, a cyclohexylene group, an adamantylene group, or a norbornylene group.

The cyclic group including the SO₂ group represented by R_{A12} in the formula (AP-1) is not particularly limited, but may be a monocyclic or polycyclic group having 3 to 20 carbon atoms. The cyclic group including the SO₂ group may further have, in addition to the SO₂ group, at least one heteroatom selected from the group consisting of a sulfur atom, an oxygen atom, and a nitrogen atom. The number of ring-member atoms of the cyclic group including the SO₂ group is preferably 4 to 30, and more preferably 5 to 20. The cyclic group including the SO₂ group is preferably a sultone group formed by removing one or more hydrogen atoms from the ring-member atoms of the sultone structure represented by any one of the above-described formulas (SL1-1) to (SL1-3).

When the resin (A) includes the repeating unit represented by the formula (AP-1), the content of the repeating unit represented by the formula (AP-1) relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

### Repeating Unit Represented by Formula (AP-2)

The resin (A) also preferably has a repeating unit represented by the following formula (AP-2).

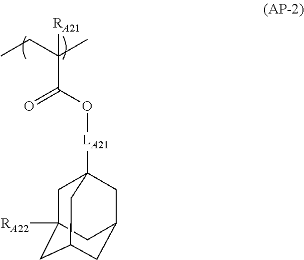

In the formula (AP-2), R_{A21} represents a hydrogen atom, a halogen atom, or an alkyl group. L_{A21} represents a single bond or a divalent linking group. R_{A22} represents an alkyl group.

Examples of the halogen atom represented by R_{A21} in the formula (AP-2) include a fluorine atom, a chlorine atom, a bromine atom, and an iodine atom.

The alkyl group represented by R_{A21} is preferably an alkyl group having 1 to 4 carbon atoms, and more preferably a methyl group.

R_{A21} is preferably a hydrogen atom or a methyl group.

The divalent linking group represented by L_{A21} in the formula (AP-2) is not particularly limited, but examples include —O—, —NR¹—, —S—, —SO—, —SO₂—, organic groups (preferably divalent organic groups), and groups that are combinations of two or more of these groups; and preferred are —O—, —CO—, —COO—, —OCOO—, —NR)—, —CONR¹—, —S—, —SO—, —SO₂—, alkylene groups, cycloalkylene groups, alkenylene groups, arylene groups, and groups that are combinations of two or more of these groups. R¹ represent a hydrogen atom or an alkyl group.

The alkylene group represented by L_{A21} is not particularly limited, but preferred are alkylene groups having 1 to 8 carbon atoms such as a methylene group, an ethylene group, a propylene group, a butylene group, a hexylene group, and an octylene group.

The number of carbon atoms of the cycloalkylene group represented by L_{A21} is not particularly limited, but is, for example, preferably 3 to 20, and more preferably 4 to 15. The cycloalkylene group may be a monocyclic cycloalkylene group such as a cyclopentylene group or a cyclohexylene group, or may be a polycyclic cycloalkylene group such as a norbornylene group, a tetracyclodecanylene group, a tetracyclododecanylene group, or an adamantylene group. One of the methylene groups constituting the cycloalkane ring of the cycloalkylene group may be replaced by a heteroatom such as an oxygen atom, a group having a heteroatom such as a carbonyl group or an ester bond, or a vinylidene group. In the cycloalkylene group, one or more ethylene groups constituting the cycloalkane ring may be replaced by a vinylene group.

The alkenylene group represented by L_{A21} is not particularly limited, but is, for example, preferably an alkenylene group having 2 to 8 carbon atoms.

The arylene group represented by L_{A21} is not particularly limited, but may be, for example, an arylene group having 6 to 20 carbon atoms, and is preferably an arylene group having 6 to 15 carbon atoms. The arylene group is preferably a phenylene group or a naphthylene group, and particularly preferably a phenylene group.

When R¹ represent an alkyl group, examples of the alkyl group include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

The alkyl group represented by R_{A22} in the formula (AP-2) is not particularly limited, but preferably represents a linear or branched alkyl group having 1 to 5 carbon atoms.

When the resin (A) includes the repeating unit represented by the formula (AP-2), the content of the repeating unit represented by the formula (AP-2) relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

### Repeating Unit Represented by Formula (AP-3)

The resin (A) also preferably has a repeating unit represented by the following formula (AP-3).

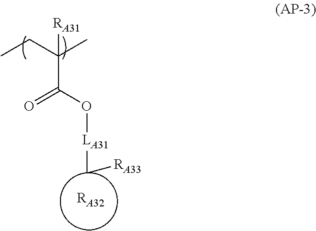

In the formula (AP-3), R_{A31} represents a hydrogen atom, a halogen atom, or an alkyl group. L_{A31} represents a single bond or a divalent linking group. R_{A32} represents an alicyclic hydrocarbon group. R_{A33} represents a substituent having a double bond.

Examples of the halogen atom represented by R_{A31} in the formula (AP-3) include a fluorine atom, a chlorine atom, a bromine atom, and an iodine atom.

The alkyl group represented by R_{A31} is preferably an alkyl group having 1 to 4 carbon atoms, and more preferably a methyl group.

R_{A31} is preferably a hydrogen atom or a methyl group.

The divalent linking group represented by L_{A31} in the formula (AP-3) is not particularly limited, but examples include —O—, —NR¹—, —S—, —SO—, —SO₂—, organic groups (preferably divalent organic groups), and groups that are combinations of two or more of these groups, and preferred are —O—, —CO—, —COO—, —OCOO—, —NR¹—, —CONR¹—, —S—, —SO—, —SO₂—, alkylene groups, cycloalkylene groups, alkenylene groups, arylene groups, and groups that are combinations of two or more of these groups. R¹ represent a hydrogen atom or an alkyl group.

The alkylene group represented by L_{A31} is not particularly limited, but is, for example, preferably an alkylene group having 1 to 8 carbon atoms such as a methylene group, an ethylene group, a propylene group, a butylene group, a hexylene group, or an octylene group.

The number of carbon atoms of the cycloalkylene group represented by L_{A31} is not particularly limited, but is, for example, preferably 3 to 20, and more preferably 4 to 15. The cycloalkylene group may be a monocyclic cycloalkylene group such as a cyclopentylene group or a cyclohexylene group, or may be a polycyclic cycloalkylene group such as a norbornylene group, a tetracyclodecanylene group, a tetracyclododecanylene group, or an adamantylene group. One of the methylene groups constituting the cycloalkane ring of the cycloalkylene group may be replaced by a heteroatom such as an oxygen atom, a group having a heteroatom such as a carbonyl group or an ester bond, or a vinylidene group. In the cycloalkylene group, one or more ethylene groups constituting the cycloalkane ring may be replaced by a vinylene group.

The alkenylene group represented by L_{A31} is not particularly limited, but is, for example, preferably an alkenylene group having 2 to 8 carbon atoms.

The arylene group represented by L_{A31} is not particularly limited, but may be, for example, an arylene group having 6 to 20 carbon atoms, and is preferably an arylene group having 6 to 15 carbon atoms. The arylene group is preferably a phenylene group or a naphthylene group, and particularly preferably a phenylene group.

When R¹ represent an alkyl group, examples of the alkyl group include alkyl groups having 20 or less carbon atoms such as a methyl group, an ethyl group, a propyl group, an isopropyl group, an n-butyl group, a sec-butyl group, a hexyl group, a 2-ethylhexyl group, an octyl group, and a dodecyl group, and preferred are alkyl groups having 8 or less carbon atoms.

The alicyclic hydrocarbon group represented by R_{A32} in the formula (AP-3) is not particularly limited, but may be a monocyclic or polycyclic alicyclic hydrocarbon group having 3 to 20 carbon atoms.

The substituent having a double bond represented by R_{A33} in the formula (AP-3) is preferably an alkenyl group or aryl group. The alkenyl group is not particularly limited, but is preferably an alkenyl group having 2 to 20 carbon atoms, and more preferably an allyl group. The aryl group is not particularly limited, but is preferably an aryl group having 6 to 20 carbon atoms, and more preferably a phenyl group or a naphthyl group.

R_{A33} particularly preferably represents an allyl group, a phenyl group, or a naphthyl group.

When the resin (A) includes the repeating unit represented by the formula (AP-3), the content of the repeating unit represented by the formula (AP-3) relative to all the repeating units in the resin (A) is preferably 1 mol % or more, and more preferably 10 mol % or more. The upper limit value relative to all the repeating units in the resin (A) is preferably 85 mol % or less, more preferably 80 mol % or less, still more preferably 70 mol % or less, and particularly preferably 60 mol % or less.

### Other Repeating Unit

Furthermore, the resin (A) may have another repeating unit other than the above-described repeating units.

For example, the resin (A) may have a repeating unit selected from the group consisting of a repeating unit having an oxathiane ring group, a repeating unit having an oxazolone ring group, a repeating unit having a dioxane ring group, and a repeating unit having a hydantoin ring group.

The resin (A) may have, in addition to such repeating structure units, for the purpose of adjusting, for example, dry etching resistance, standard developer suitability, substrate adhesiveness, resist profile, resolution, heat resistance, and sensitivity, various repeating structure units.

For the resin (A), particularly when the composition of the present invention is used as an actinic ray-sensitive or radiation-sensitive resin composition for ArF, all the repeating units are preferably constituted by a repeating unit derived from a compound having an ethylenically unsaturated bond. In particular, all the repeating units are also preferably constituted by a (meth)acrylate-based repeating unit. When all the repeating units are constituted by a (meth)acrylate-based repeating unit, all the repeating units can be a methacrylate-based repeating unit, all the repeating units can be an acrylate-based repeating unit, or all the repeating units can be a methacrylate-based repeating unit and an acrylate-based repeating unit; the acrylate-based repeating unit content relative to all the repeating units is preferably 50 mol % or less.

The resin (A) can be synthesized by standard procedures (for example, radical polymerization).

The resin (A) has a weight-average molecular weight (Mw) of, as a polystyrene-equivalent value determined by the GPC method, preferably 30000 or less, more preferably 1000 to 30000, still more preferably 3000 to 30000, and particularly preferably 5000 to 15000.

The resin (A) has a dispersity (molecular weight distribution, Mw/Mn) of preferably 1 to 5, more preferably 1 to 3, still more preferably 1.2 to 3.0, and particularly preferably 1.2 to 2.0. As the dispersity lowers, the resolution becomes higher, the resist profile becomes better, the sidewalls of the resist pattern become smoother, and the roughness performance becomes higher.

The content of the resin (A) in the composition of the present invention is, relative to the total solid content of the composition of the present invention, preferably 30.0 to 99.9 mass %, more preferably 40.0 to 99.9 mass %, and still more preferably 60.0 to 90.0 mass %.

Such resins (A) may be used alone or may be used in combination of two or more thereof. When two or more thereof are used, the total content thereof is preferably within such a preferred content range.

### Acid Diffusion Control Agent

The composition of the present invention may further include an acid diffusion control agent (also referred to as “compound (C)”).

The compound (C) is a compound different from the onium salt (B-1) and the onium salt (B-2).

The acid diffusion control agent serves as a quencher that traps the acid generated from the photoacid generator or the like upon exposure and that suppresses the reaction of the resin, caused by an excess of generated acid, in which action of the acid in the unexposed regions causes an increase in polarity.

The type of compound (C) is not particularly limited, and examples include a basic compound (CA), a low molecular weight compound (CB) having a nitrogen atom and having a group that leaves by action of an acid, and a compound (CC) whose acid diffusion control ability is reduced or lost upon irradiation with an actinic ray or a radiation.

Examples of the compound (CC) include an onium salt compound (CD) that becomes a weak acid relative to the photoacid generator, and a basic compound (CE) whose basicity is reduced or lost upon irradiation with an actinic ray or a radiation.

Specific examples of the basic compound (CA) include, for example, those described in Paragraphs [0132] to [0136] of WO2020/066824A; specific examples of the basic compound (CE) whose basicity is reduced or lost upon irradiation with an actinic ray or a radiation include those described in Paragraphs [0137] to [0155] of WO2020/066824A, and those described in Paragraph [0164] of WO2020/066824A; and, specific examples of the low molecular weight compound (CB) having a nitrogen atom and having a group that leaves by action of an acid include those described in Paragraphs [0156] to [0163] of WO2020/066824A.

Specific examples of the onium salt compound (CD) that becomes a weak acid relative to the photoacid generator include, for example, those described in Paragraphs [0305] to [0314] of WO2020/158337A.

In addition to those described above, for example, the publicly known compounds disclosed in Paragraphs [0627] to [0664] in US2016/0070167A, Paragraphs [0095] to [0187] in US2015/0004544A, Paragraphs [0403] to [0423] in US2016/0237190A, and Paragraphs [0259] to [0328] in US2016/0274458A can be suitably used as acid diffusion control agents.

When the composition of the present invention includes the compound (C), the content of the compound (C) relative to the total solid content of the composition of the present invention is preferably 0.01 to 30.0 mass %, more preferably 0.05 to 20.0 mass %, and still more preferably 0.1 to 15.0 mass %.

Such compounds (C) may be used alone or may be used in combination of two or more thereof. When two or more thereof are used, the total content thereof is preferably within such a preferred content range.

### Resin (D)

The composition of the present invention may further include a resin (D) (also referred to as “hydrophobic resin”) different from the resin (A).

However, the resin (D) satisfies the following requirement (i).

(i) The resin (D) has an SP value that is smaller than the SP value of the resin (A) and is 17.2 or less.

### Calculation Method of SP Value of Resin

A method for calculating the SP value (Solubility Parameter) of a resin will be described below.

1. The SP values of monomers corresponding to the repeating units constituting the resin are calculated using “HSPiP 5th Edition 5.1.08”.

2. The mass-based content ratios of the repeating units relative to the resin are multiplied by the SP values (obtained in the above 1.) of the monomers corresponding to the repeating units, summed up, and the resultant numerical value is defined as the SP value of the resin.

This calculation method is used to calculate the SP value (SP_{A}) of the resin (A) and the SP value (SP_{D}) of the resin (D). When two or more resins are used in combination, in the above 2. describing the calculation method, the mass-based content ratios of the resins and the SP values of the resins are multiplied, and the resultant values are summed up to determine the SP value of the resin.

The resin (D) is preferably designed so as to be localized in the surface of the resist film; unlike surfactants, the resin (D) does not necessarily have a hydrophilic group in the molecule, and does not necessarily contribute to homogeneous mixing of a polar substance and a nonpolar substance.

The effects of adding the resin (D) include control of the static and dynamic contact angles of the resist film surface with respect to water, and suppression of outgassing.

From the viewpoint of localization to the film surface layer, the resin (D) preferably has any one or more of a fluorine atom, a silicon atom, and a CH₃ partial structure included in the side chain portion of the resin, and more preferably has two or more thereof. The resin (D) preferably has a hydrocarbon group having 5 or more carbon atoms. The resin may have such a group in the main chain or, as a substituent, in a side chain.

Examples of the resin (D) include the compounds described in Paragraphs [0275] to [0279] of WO2020/004306A.

When the composition of the present invention includes the resin (D), the content of the resin (D) relative to the total solid content of the composition of the present invention is 0.01 to 10 mass %, and preferably 0.1 to 5 mass %.

Such resins (D) may be used alone or in combination of two or more thereof. When two or more thereof are used, the total content thereof is preferably within such a preferred content range.

When the composition of the present invention includes the resin (D), it preferably satisfies all of the following requirements (ii) and (iii):
(ii) for repeating units of the resin (D), a total content of repeating units not including fluorine atoms relative to all repeating units in the resin (D) is 80 mol % or more; and
(iii) a content of the resin (D) relative to a total solid content in the actinic ray-sensitive or radiation-sensitive resin composition is 0.01 to 10 mass %.

### Surfactant

The composition of the present invention may include a surfactant. In the case of including a surfactant, a pattern having higher adhesiveness and a less number of development defects can be formed.

The surfactant is preferably a fluorine-based and/or silicone-based surfactant.

Examples of the fluorine-based and/or silicone-based surfactant include the surfactants disclosed in Paragraphs [0218] and [0219] of WO2018/193954A.

Such surfactants may be used alone or in combination of two or more thereof.

When the composition of the present invention includes a surfactant, the surfactant content relative to the total solid content of the composition of the present invention is preferably 0.0001 to 2.0 mass %, more preferably 0.0005 to 1.0 mass %, and still more preferably 0.1 to 1.0 mass %.

Such surfactants may be used alone or may be used in combination of two or more thereof. When two or more thereof are used, the total content thereof is preferably within such a preferred content range.

### Solvent

The composition of the present invention preferably includes a solvent.

The solvent preferably includes at least one of (M1) a propylene glycol monoalkyl ether carboxylate or (M2) at least one selected from the group consisting of a propylene glycol monoalkyl ether, a lactate, an acetate, an alkoxypropionate, a chain ketone, a cyclic ketone, a lactone, and an alkylene carbonate. Note that the solvent may further include a component other than the components (M1) and (M2).

A combination of the above-described solvent and the above-described resin is preferred from the viewpoint of improving the coatability of the composition of the present invention and reducing the number of pattern development defects. The above-described solvent is well-balanced in terms of solubility of the above-described resin, boiling point, and viscosity, to thereby suppress, for example, unevenness of the film thickness of the resist film and generation of deposit during spin-coating.

Details of the component (M1) and the component (M2) are described in Paragraphs [0218] to [0226] in WO2020/004306A, and these contents are incorporated herein.

When the solvent further includes a component other than the components (M1) and (M2), the content of the component other than the components (M1) and (M2) relative to the total amount of the solvent is preferably 5 to 30 mass %.

The content of the solvent in the composition of the present invention is set such that the solid-content concentration is preferably 0.5 to 30 mass %, and more preferably 1 to 20 mass %. This further improves the coatability of the composition of the present invention.

### Other Additives

The composition of the present invention may further include a dissolution-inhibiting compound, a dye, a plasticizer, a photosensitizer, a light absorbent, and/or a compound that promotes solubility in a developer (for example, a phenol compound having a molecular weight of 1000 or less, or an alicyclic or aliphatic compound including a carboxyl group).

The “dissolution-inhibiting compound” is a compound that is decomposed by the action of an acid to cause a decrease in the degree of solubility in organic-based developers, and has a molecular weight of 3000 or less.

The content of fluorine atoms included in the total solid content of the composition of the present invention is preferably 1 mass % or less, more preferably 0.5 mass % or less, and still more preferably 0.1 mass % or less.

The fluorine atom content represents the mass ratio of fluorine atoms in the total solid content to all atoms of the total solid content in the composition of the present invention. For example, when the total solid content in the composition of the present invention is constituted by carbon atoms, hydrogen atoms, fluorine atoms, nitrogen atoms, oxygen atoms, and sulfur atoms, the fluorine atom content (mass %) can be calculated by the following formula (1a).

$$100 \times 19 \times [ F ] / ( 12 \times [ C ] + 1 \times [ H ] + 19 \times [ F ] + 14 \times [ N ] + 16 \times [ O ] + 32 \times [ S ] ) \qquad ( 1 a )$$

[C] represents the molar ratio of carbon atoms in the total solid content, H represents the molar ratio of hydrogen atoms in the total solid content, [F] represents the molar ratio of fluorine atoms in the total solid content, [N] represents the molar ratio of nitrogen atoms in the total solid content, [O] represents the molar ratio of oxygen atoms in the total solid content, and [S] represents the molar ratio of sulfur atoms in the total solid content. The molar ratio [C] of carbon atoms in the total solid content can be calculated from the number of carbon atoms, the molecular weight, and the content of each constituent component in the solid content. For example, the molar ratio of carbon atoms of the onium salt (B-1) can be calculated by the following formula (1b).

$${A}_{w} / {A}_{M} \times {A}_{C} \qquad ( 1 b )$$

A_{W} represents the amount of the onium salt (B-1) in the total solid content (the unit is “g” or “mass %”), A_{M} represents the molecular weight of the onium salt (B-1), and A_{C} represents the number of carbon atoms of the onium salt (B-1). For the other constituent components, similarly, the molar ratios of carbon atoms can be calculated; and the molar ratios are summed up to thereby calculate the molar ratio [C] of carbon atoms in the total solid content. In the formula, the carbon atoms can be replaced by other atoms to thereby similarly calculate the molar ratios of the other atoms. Even when the total solid content in the composition of the present invention includes atoms other than those described above, the atomic weight and molar ratio in the total solid content of the atoms can be used to similarly achieve the calculation. Alternatively, instead of the above-described method, for example, an analytical method such as elemental analysis on a resist film obtained by evaporating the solvent component of the composition of the present invention can also be used to achieve the calculation.

The composition of the present invention is also suitably used as a photosensitive composition for EUV exposure.

### Actinic Ray-Sensitive or Radiation-Sensitive Film and Pattern Forming Method

The present invention also relates to an actinic ray-sensitive or radiation-sensitive film formed from the composition of the present invention. The actinic ray-sensitive or radiation-sensitive film of the present invention is preferably a resist film.

The procedures of the pattern forming method using the composition of the present invention are not particularly limited, but preferably have the following steps:
Step 1: a step of using the composition of the present invention to form a resist film on a substrate;
Step 2: a step of exposing the resist film; and
Step 3: a step of developing the exposed resist film using a developer.

Hereinafter, procedures of the steps will be individually described in detail.

### Step 1: Resist Film Formation Step

The step 1 is a step of using the composition of the present invention to form a resist film on a substrate.

Examples of the method of using the composition of the present invention to form a resist film on a substrate include a method of applying the composition of the present invention onto a substrate.

Note that the composition of the present invention is preferably filtered through a filter before application as needed. The filter preferably has a pore size of 0.1 m or less, more preferably 0.05 m or less, and still more preferably 0.03 m or less. The filter is preferably formed of polytetrafluoroethylene, polyethylene, or nylon.

The composition of the present invention can be applied onto a substrate (for example, formed of silicon or silicon dioxide-covered silicon) used in the production of integrated circuit elements by an appropriate application method using a spinner, a coater, or the like. The application process is preferably spin-coating using a spinner. The spin-coating using a spinner is preferably performed at a rotation rate of 1000 to 3000 rpm (rotations per minute).

After application of the composition of the present invention, the substrate may be dried to form a resist film. Note that, as needed, as underlayers of the resist film, various underlying films (an inorganic film, an organic film, or an antireflection film) may be formed.

The drying process may be, for example, a process of performing heating to achieve drying. The heating can be performed using means included in an ordinary exposure device and/or an ordinary development device, or may alternatively be performed using a hot plate, for example. The heating temperature is preferably 80 to 150° C., more preferably 80 to 140° C., and still more preferably 80 to 130° C. The heating time is preferably 30 to 1000 seconds, more preferably 60 to 800 seconds, and still more preferably 60 to 600 seconds.

The film thickness of the resist film is not particularly limited, but is, from the viewpoint of enabling formation of more precise fine patterns, preferably 10 to 120 nm. In particular, in the case of employing EUV exposure, the film thickness of the resist film is more preferably 10 to 65 nm, and still more preferably 15 to 50 nm. In the case of employing ArF liquid immersion exposure, the film thickness of the resist film is more preferably 10 to 120 nm, and still more preferably 15 to 90 nm.

Note that, for an overlying layer of the resist film, a topcoat composition may be used to form a topcoat.

The topcoat composition preferably does not mix with the resist film, and can be uniformly applied for an overlying layer of the resist film. The topcoat is not particularly limited; a publicly known topcoat can be formed by a publicly known process; for example, on the basis of descriptions of Paragraphs [0072] to [0082] in JP2014-059543A, a topcoat can be formed.

For example, a topcoat including a basic compound and described in JP2013-61648A is preferably formed on the resist film. Specific examples of the basic compound that can be included in the topcoat include basic compounds that may be included in the composition of the present invention.

The topcoat also preferably includes a compound including at least one group or bond selected from the group consisting of an ether bond, a thioether bond, a hydroxy group, a thiol group, a carbonyl bond, and an ester bond.

### Step 2: Exposure Step

The step 2 is a step of exposing the resist film.

The exposure process may be a process of irradiating the formed resist film, through a predetermined mask, with an actinic ray or a radiation.

Examples of the actinic ray or the radiation include infrared light, visible light, ultraviolet light, far-ultraviolet light, extreme ultraviolet light, X-rays, and an electron beam; preferred is 250 nm or less; more preferred is 220 nm or less; particularly preferred is far-ultraviolet light having wavelengths of 1 to 200 nm; and specific examples thereof include the KrF excimer laser (248 nm), the ArF excimer laser (193 nm), the F₂ excimer laser (157 nm), EUV (13.5 nm), X-rays, and an electron beam.

After the exposure, before development, baking (heating) is preferably performed. The baking accelerates the reaction in the exposed regions, to provide higher sensitivity and a better pattern profile.

The heating temperature is preferably 80 to 150° C., more preferably 80 to 140° C., and still more preferably 80 to 130° C.

The heating time is preferably 10 to 1000 seconds, more preferably 10 to 180 seconds, and still more preferably 30 to 120 seconds.

The heating can be performed using means included in an ordinary exposure device and/or an ordinary development device, and may alternatively be performed using a hot plate, for example.

This step is also referred to as post-exposure baking.

### Step 3: Development Step

The step 3 is a step of using a developer to develop the exposed resist film to form a pattern.

The developer may be an alkali developer or may be a developer containing an organic solvent (hereafter, also referred to as organic-based developer).

Examples of the development process include a process of immersing, for a predetermined time, the substrate in a tank filled with the developer (dipping process), a process of puddling, with the developer, the surface of the substrate using surface tension and leaving the developer at rest for a predetermined time to achieve development (puddling process), a process of spraying the developer to the surface of the substrate (spraying process), and a process of scanning, at a constant rate, over the substrate rotated at a constant rate, a developer ejection nozzle to continuously eject the developer (dynamic dispensing process).

After the step of performing development, a step of performing exchange with another solvent to stop the development may be performed.

The development time is not particularly limited as long as the resin in the unexposed regions is sufficiently dissolved in the time, and is preferably 10 to 300 seconds, and more preferably 20 to 120 seconds.

The temperature of the developer is preferably 0 to 50° C., and more preferably 15 to 35° C.

The alkali developer employed is preferably an alkali aqueous solution including an alkali. The type of the alkali aqueous solution is not particularly limited, but may be, for example, an alkali aqueous solution including a quaternary ammonium salt represented by tetramethylammonium hydroxide, an inorganic alkali, a primary amine, a secondary amine, a tertiary amine, an alcoholamine, a cyclic amine, or the like. In particular, the alkali developer is preferably an aqueous solution of a quaternary ammonium salt represented by tetramethylammonium hydroxide (TMAH). To the alkali developer, an appropriate amount of an alcohol, a surfactant, or the like may be added. The alkali developer ordinarily preferably has an alkali concentration of 0.1 to 20 mass %. The alkali developer ordinarily preferably has a pH of 10.0 to 15.0.

The organic-based developer is preferably a developer containing at least one organic solvent selected from the group consisting of ketone-based solvents, ester-based solvents, alcohol-based solvents, amide-based solvents, ether-based solvents, and hydrocarbon-based solvents.

A plurality of such solvents may be mixed together, or such a solvent may be mixed with a solvent other than those described above or water. The developer as a whole has a moisture content of preferably less than 50 mass %, more preferably less than 20 mass %, still more preferably less than 10 mass %, and particularly preferably contains substantially no moisture.

In the organic-based developer, the content of the organic solvent relative to the total amount of the developer is preferably 50 mass % or more and 100 mass % or less, more preferably 80 mass % or more and 100 mass % or less, still more preferably 90 mass % or more and 100 mass % or less, and particularly preferably 95 mass % or more and 100 mass % or less.

### Other Step

The pattern forming method preferably includes a step of, after the step 3, using a rinse liquid to perform rinsing.

After the development step using an alkali developer, in the rinsing step, the rinse liquid employed may be, for example, pure water. Note that, to the pure water, an appropriate amount of surfactant may be added.

To the rinse liquid, an appropriate amount of surfactant may be added.

After the development step using an organic-based developer, in the rinsing step, the rinse liquid employed is not particularly limited as long as it does not dissolve the pattern, and can be a solution including an ordinary organic solvent. The rinse liquid employed is preferably a rinse liquid containing at least one organic solvent selected from the group consisting of hydrocarbon-based solvents, ketone-based solvents, ester-based solvents, alcohol-based solvents, amide-based solvents, and ether-based solvents.

The process of performing the rinsing step is not particularly limited; examples include a process of continuously ejecting, onto the substrate rotated at a constant rate, the rinse liquid (spin-coating process), a process of immersing, in a tank filled with the rinse liquid, the substrate for a predetermined time (dipping process), and a process of spraying, to the surface of the substrate, the rinse liquid (spraying process).

The pattern forming method may include a heating step (Post Bake) performed after the rinsing step. In this step, baking removes the developer and the rinse liquid remaining between and within the patterns. In addition, this step also provides an effect of annealing the resist pattern to address the rough surface of the pattern. The heating step after the rinsing step is performed ordinarily at 40 to 250° C. (preferably 90 to 200° C.) for ordinarily 10 seconds to 3 minutes (preferably 30 seconds to 120 seconds).

The formed pattern may be used as a mask for subjecting the substrate to etching treatment. Specifically, the pattern formed in the step 3 may be used as a mask for processing the substrate (or the underlayer film and the substrate), to form a pattern in the substrate.

The process of processing the substrate (or the underlayer film and the substrate) is not particularly limited, but is preferably a process of using the pattern formed in the step 3 as a mask for subjecting the substrate (or the underlayer film and the substrate) to dry etching, to thereby form a pattern in the substrate. The dry etching is preferably oxygen plasma etching.

Various materials used in the composition and the pattern forming method of the present invention (for example, a solvent, a developer, a rinse liquid, an antireflection film-forming composition, and a topcoat-forming composition) preferably do not include impurities such as metals. The content of impurities included in such materials is preferably 1 mass ppm (parts per million) or less, more preferably 10 mass ppb (parts per billion) or less, still more preferably 100 mass ppt or less, particularly preferably 10 mass ppt or less, and most preferably 1 mass ppt or less. The lower limit is not particularly limited, but is preferably 0 mass ppt or more. Examples of the metallic impurities include Na, K, Ca, Fe, Cu, Mg, Al, Li, Cr, Ni, Sn, Ag, As, Au, Ba, Cd, Co, Pb, Ti, V, W, and Zn.

The process of removing, from the various materials, impurities such as metals may be, for example, filtration using a filter. The details of filtration using a filter are described in Paragraph [0321] in WO2020/004306A.

Examples of the process of reducing the amount of impurities such as metals included in the various materials include a process of selecting, as raw materials constituting the various materials, raw materials having lower metal content, a process of subjecting raw materials constituting the various materials to filtration using a filter, and a process of performing distillation under conditions under which contamination is minimized by, for example, lining the interior of the apparatuses with TEFLON (registered trademark).

Instead of the filtration using a filter, an adsorption material may be used to remove impurities; alternatively, the filtration using a filter and the adsorption material may be used in combination. Such adsorption materials can be publicly known adsorption materials, and examples include inorganic-based adsorption materials such as silica gel and zeolite, and organic-based adsorption materials such as active carbon. In order to reduce the amount of impurities such as metals included in the various materials, ingress of metallic impurities in the production steps needs to be prevented. Whether or not metallic impurities are sufficiently removed from the production apparatuses can be determined by measuring the content of metallic components included in the washing liquid having been used for washing the production apparatuses. The content of metallic components included in the washing liquid having been used is preferably 100 mass ppt (parts per trillion) or less, more preferably 10 mass ppt or less, and still more preferably 1 mass ppt or less. The lower limit is not particularly limited, but is preferably 0 mass ppt or more.

To organic-based treatment liquids such as the rinse liquid, in order to prevent electrostatic buildup and the subsequent electrostatic discharge causing failure of the chemical solution pipe and various parts (such as a filter, an O-ring, and a tube), a conductive compound may be added. The conductive compound is not particularly limited, but may be, for example, methanol. The amount of addition is not particularly limited, but is, from the viewpoint of maintaining preferred development performance or rinsing performance, preferably 10 mass % or less, and more preferably 5 mass % or less. The lower limit is not particularly limited, but is preferably 0.01 mass % or more.

Examples of the chemical solution pipe include various pipes formed of SUS (stainless steel), or coated with polyethylene, polypropylene, or a fluororesin (such as polytetrafluoroethylene or a perfluoroalkoxy resin) treated so as to be antistatic. Similarly for the filter and the O-ring, polyethylene, polypropylene, or a fluororesin (such as polytetrafluoroethylene or a perfluoroalkoxy resin) treated so as to be antistatic can be used.

### Method for Producing Electronic Device

The present invention also relates to a method for producing an electronic device, the method including the above-described pattern forming method, and an electronic device produced by the production method.

Preferred embodiments of the electronic device of the present invention include embodiments of being mounted on electric and electronic apparatuses (home appliances, OA (Office Automation), media-related devices, optical devices, communication devices, and the like).

### EXAMPLES

Hereinafter, the present invention will be described further in detail with reference to Examples. In the following Examples, materials, usage amounts, ratios, details of treatments, and orders of treatments can be appropriately changed without departing from the spirit and scope of the present invention. Thus, the scope of the present invention should not be construed as being limited to the following Examples.

pKa of Acid (AC_{b1}) and Acid (AC_{b2})

The pKa (pKa^{B}1) of the acid (AC_{B1}) generated from the onium salt (B-1) upon irradiation with an actinic ray or a radiation, and the pKa (pKa^{B2}) of the acid (AC_{B2}) generated from the onium salt (B-2) upon irradiation with an actinic ray or a radiation were determined by the following method.

For each of the onium salts, a structure in which the anion moiety is protonated (for example, when the anion moiety is SO₃—, SO₃H) was calculated using software (Advanced Chemistry Development (ACD/Labs) Software V8.14 for Solaris (1994-2007 ACD/Labs)). When a plurality of onium salts were included as the onium salt (B-1), the calculated value of the onium salt species having the lowest pKa was used to calculate ΔpKa (pKa^{B1}-pKa^{B2}). When a plurality of onium salts were included as the onium salt (B-2), the calculated value of the onium salt species having the highest pKa was used to calculate ΔpKa (pKa^{B1}-pKa^{B2}).

### Fluorine Content of Onium Salt (B-1)

The fluorine content of the onium salt (B-1) represents the mass ratio (mass %) of fluorine atoms relative to all atoms of the onium salt (B-1), and was calculated by the following formula (1).

$$100 \times 19 \times {F}_{B 1} / {MW}_{B 1} \qquad ( 1 )$$

In the formula (1), F_{B}1 represents the number of fluorine atoms included in the onium salt (B-1), and MW_{B1} represents the molecular weight of the onium salt (B-1).

### Fluorine Content of Onium Salt (B-2)

The fluorine content of the onium salt (B-2) represents the mass ratio (mass %) of fluorine atoms to all atoms of the onium salt (B-2), and can be calculated by the following formula (2).

$$100 \times 19 \times {F}_{B 2} / {MW}_{B 2} \qquad ( 2 )$$

In the formula (2), F_{B2} represents the number of fluorine atoms included in the onium salt (B-2), and MW_{B2} represents the molecular weight of the onium salt (B-2).

### Onium Salt (B-1)

As the onium salt (B-1), B1-1 to B1-18 were used. B1-1 to B1-18 can act as acid diffusion control agents whose acid diffusion control ability is reduced or lost upon irradiation with an actinic ray or a radiation.

As acid diffusion control agents that were not the onium salt (B-1), Z₁-1 to Z₁-4 were used. For convenience, Z₁-1 to Z₁-4 are also described in the column of Onium salt (B-1) in a Table below.

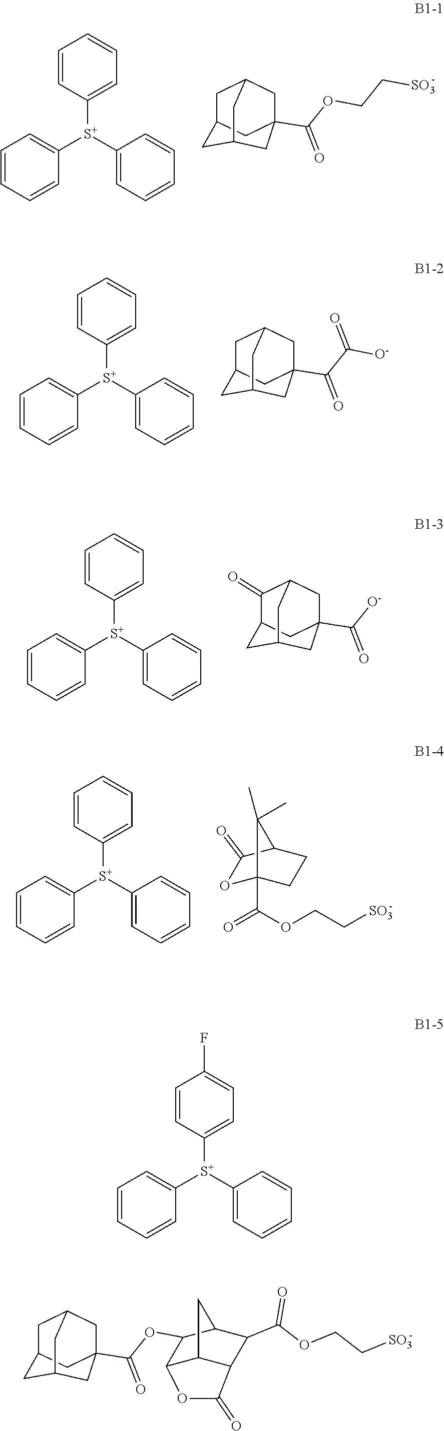

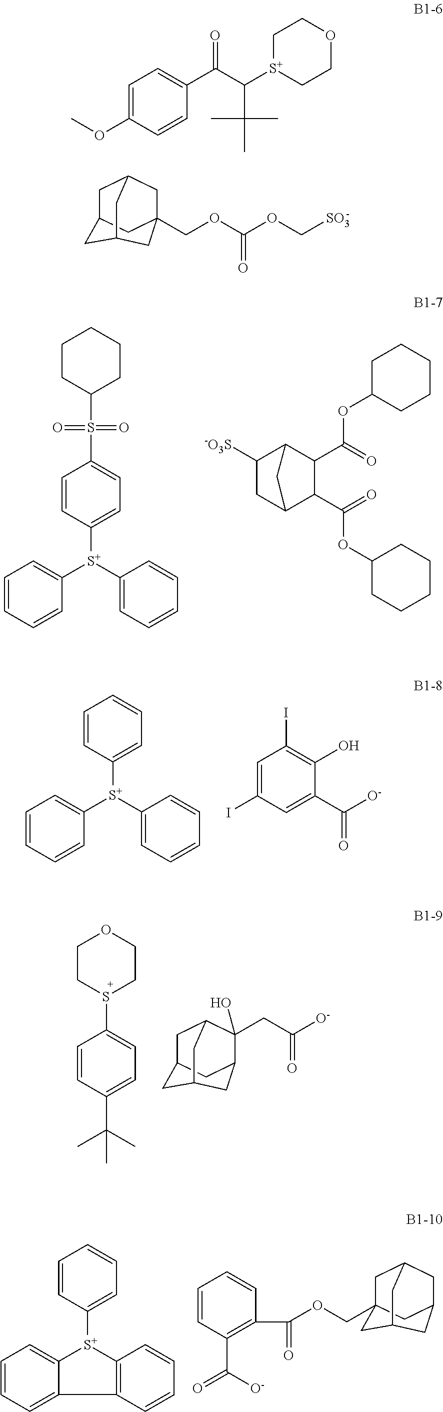

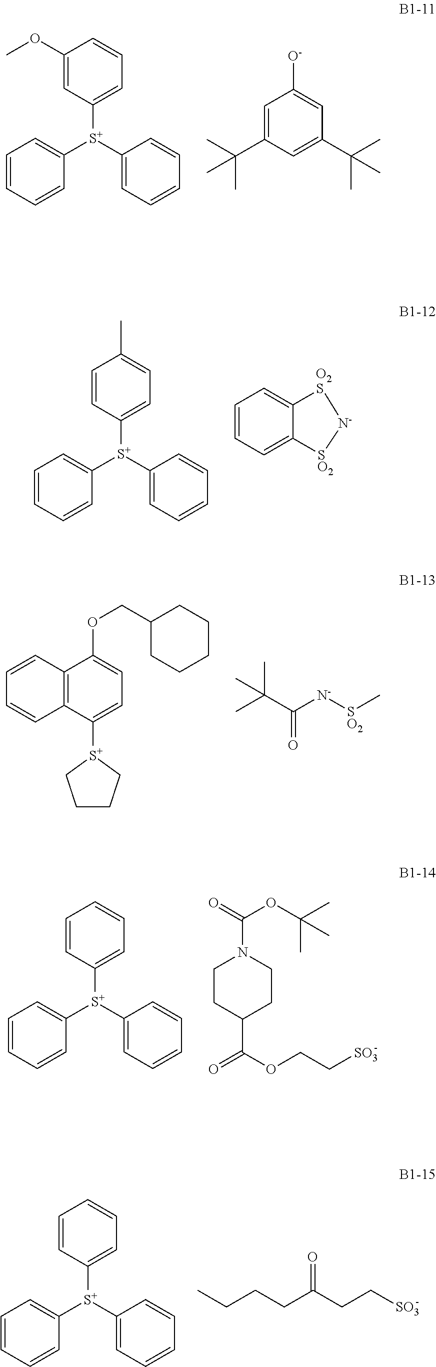

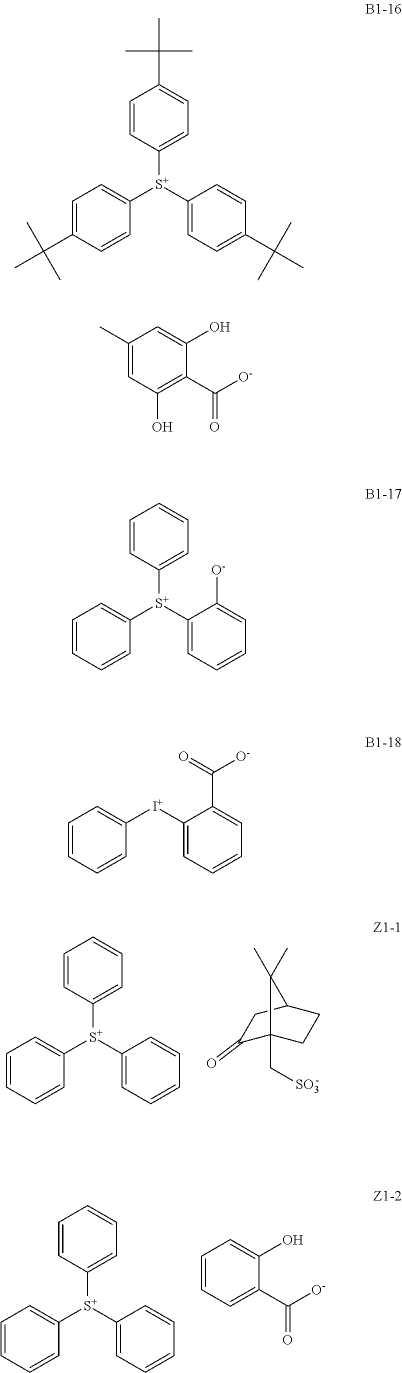

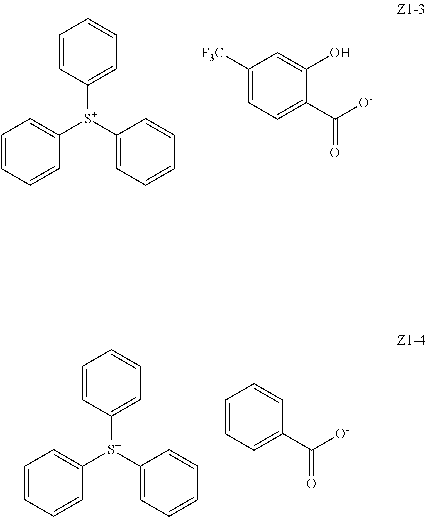 [SMILES: c1ccc([S+](c2ccccc2)c2ccccc2)cc1 ; O=C([O-])c1ccc(C(F)(F)F)cc1O ; c1ccc([S+](c2ccccc2)c2ccccc2)cc1 ; O=C([O-])c1ccccc1]

The following Table 1 describes the fluorine content of the onium salts (B-1) and the pKa (pKa^{B}1) of the acids (AC_{B1}) generated from the onium salts (B-1).

TABLE 1

| Onium salt (B-1) | Fluorine content (mass %) | pKa^{B1} |
|---|---|---|
| B1-1 | 0% | 1.07 |
| B1-2 | 0% | 2.81 |
| B1-3 | 0% | 4.42 |
| B1-4 | 0% | 1.04 |
| B1-5 | 2.5% | 1.06 |
| B1-6 | 0% | 0.11 |
| B1-7 | 0% | 1.75 |
| B1-8 | 0% | 2.07 |
| B1-9 | 0% | 4.66 |
| B1-10 | 0% | 3.37 |
| B1-11 | 0% | 10.21 |
| B1-12 | 0% | −1.10 |
| B1-13 | 0% | 5.55 |
| B1-14 | 0% | 1.07 |
| B1-15 | 0% | 1.36 |
| B1-16 | 0% | 1.46 |
| B1-17 | 0% | 5.29 |
| B1-18 | 0% | 1.81 |
| Z1-1 | 0% | 1.17 |
| Z1-2 | 0% | 3.01 |
| Z1-3 | 12.2% | 2.45 |
| Z1-4 | 0% | 4.20 |

Onium Salt (n-2)

As the onium salt (n-2), B2-1 to n2-30 were used. B2-1 to B2-30 can act as photoacid generators.

As a photoacid generator that was not the onium salt (n-2), Z2-1 was used. For convenience, Z2-1 is also described in the column of Onium salt (n-2) in a Table below.

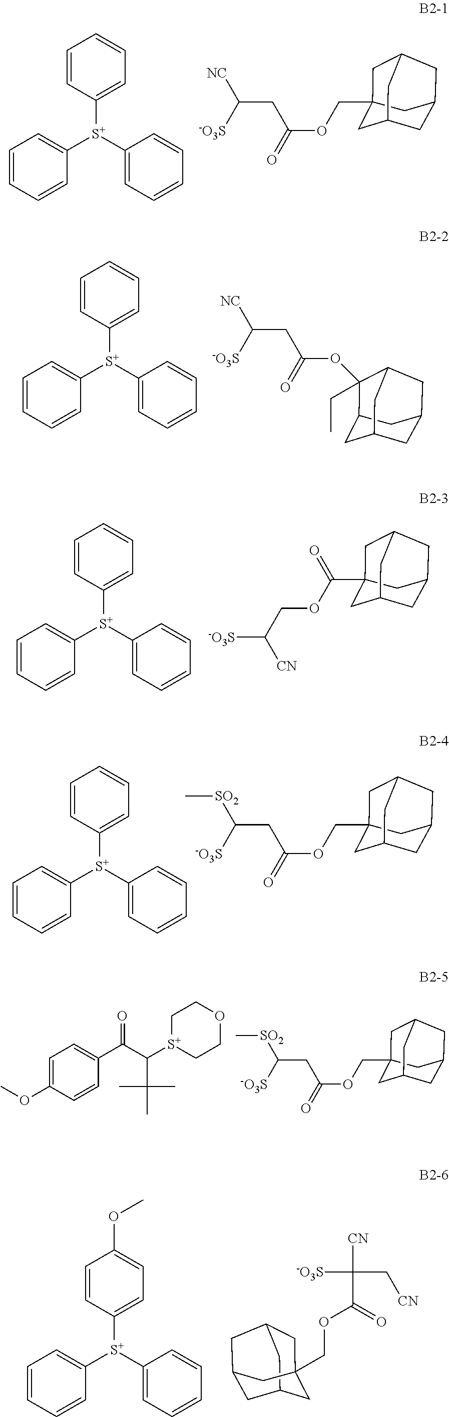

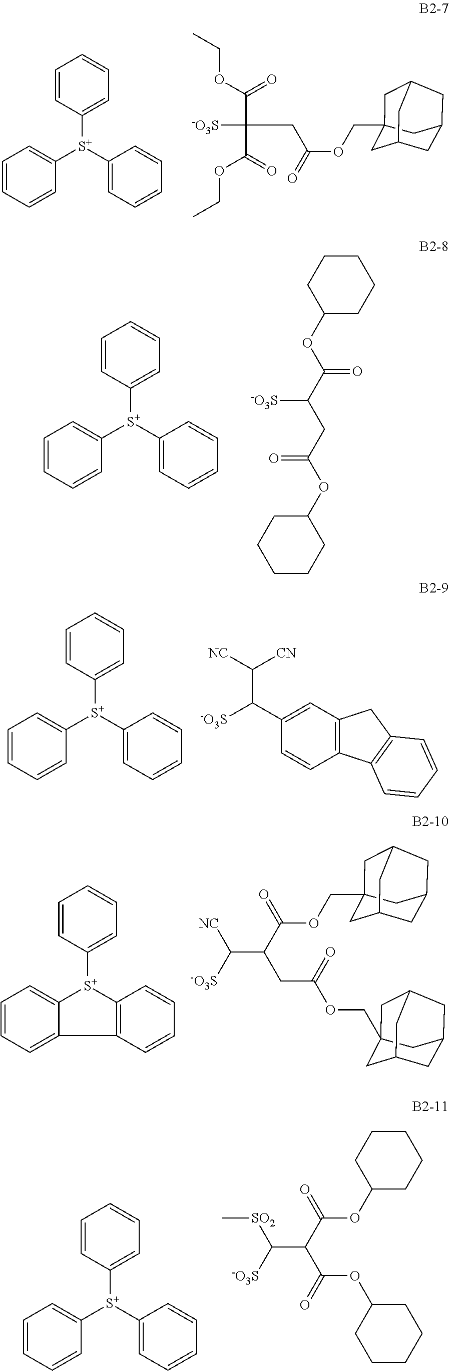

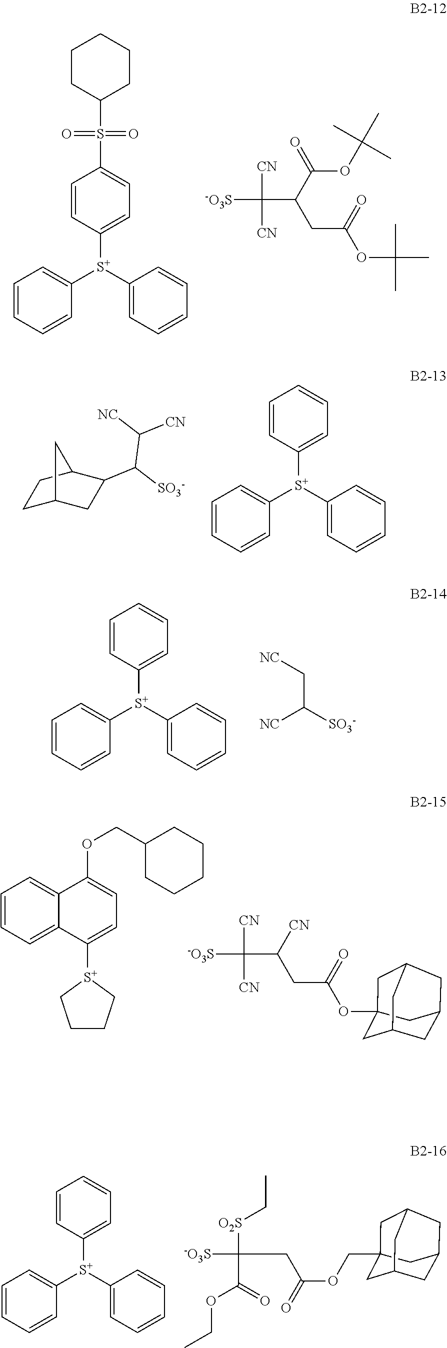

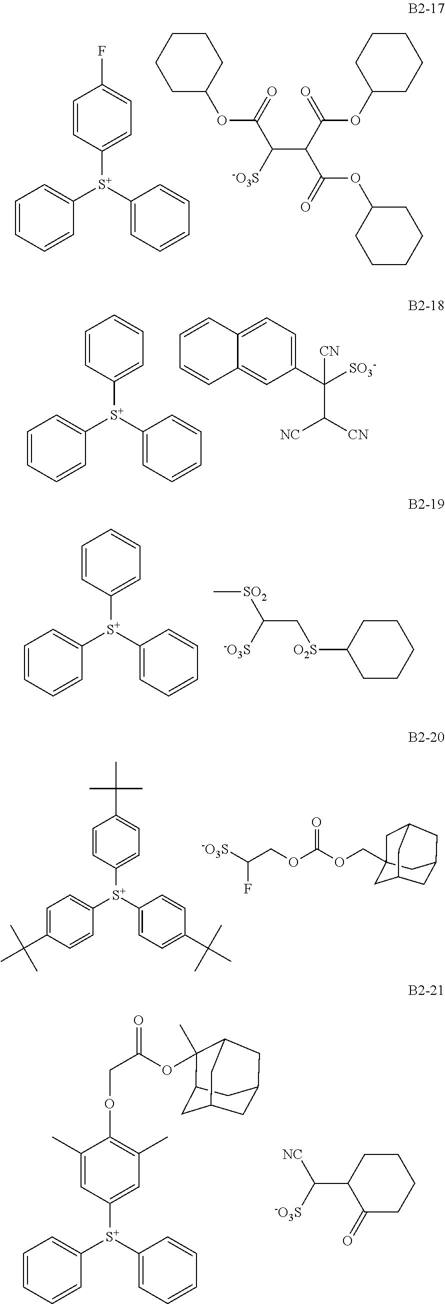

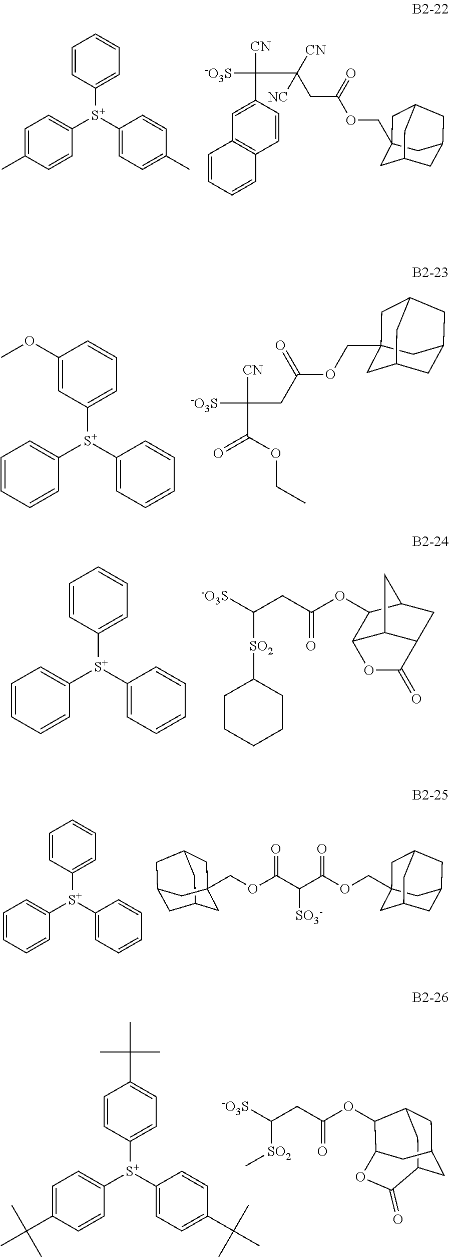

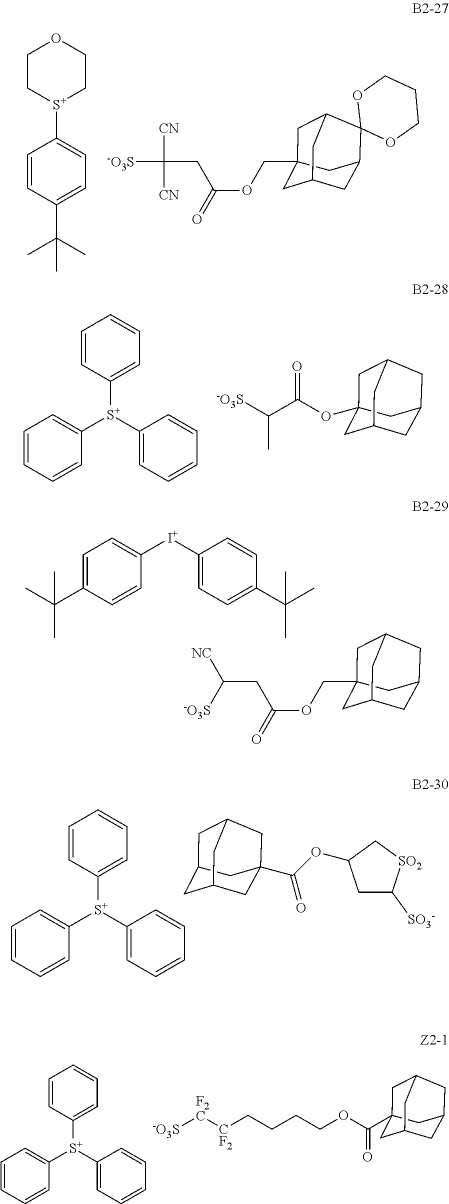

The following Table 2 describes the fluorine content of the onium salts (B-2) and the pKa (pKa^{B2}) of the acids (AC_{B2}) generated from the onium salts (B-2).

TABLE 2

| Onium salt (B-2) | Fluorine content (mass %) | pKa^{B2} |
|---|---|---|
| B2-1 | 0% | −1.21 |
| B2-2 | 0% | −1.23 |
| B2-3 | 0% | −1.48 |
| B2-4 | 0% | −0.90 |
| B2-5 | 0% | −0.90 |
| B2-6 | 0% | −2.90 |
| B2-7 | 0% | −1.00 |
| B2-8 | 0% | 0.08 |
| B2-9 | 0% | −0.57 |
| B2-10 | 0% | −1.37 |
| B2-11 | 0% | −1.38 |
| B2-12 | 0% | −3.92 |
| B2-13 | 0% | −0.30 |
| B2-14 | 0% | −1.67 |
| B2-15 | 0% | −4.21 |
| B2-16 | 0% | −2.18 |
| B2-17 | 2.5% | −0.39 |
| B2-18 | 0% | −3.22 |
| B2-19 | 0% | −1.26 |
| B2-20 | 2.5% | −0.81 |
| B2-21 | 0% | −1.21 |
| B2-22 | 0% | −2.83 |
| B2-23 | 0% | −2.38 |
| B2-24 | 0% | −0.87 |
| B2-25 | 0% | −0.75 |
| B2-26 | 0% | −0.94 |
| B2-27 | 0% | −3.77 |
| B2-28 | 0% | 0.56 |
| B2-29 | 0% | −1.21 |
| B2-30 | 0% | −0.64 |
| Z2-1 | 11.2% | −2.75 |

Synthesis examples of the onium salts (B-2) will be described below.

### Synthesis Example 1: Synthesis of B2-4

### Synthesis of Intermediate B2-4-1

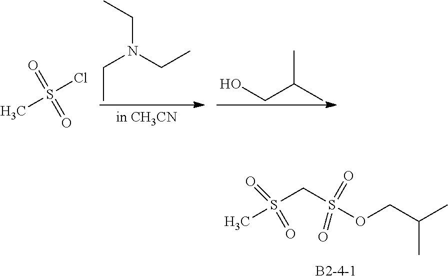

To a mixed solution of 66.3 g (0.65 mol) of triethylamine and 175 ml of acetonitrile under stirring at −40° C. under a nitrogen atmosphere, 50.0 g (0.44 mol) of methanesulfonyl chloride was slowly added dropwise. After stirring for 1 hour in this state, 16.2 g (0.22 mol) of 2-butanol was slowly added dropwise, and the mixture was stirred for an additional 2 hours. After removing the precipitated triethylamine hydrochloride by filtration, a solution prepared by adding 400 ml of ethyl acetate to the filtrate was added to 300 ml of a 1 mol/1 aqueous hydrochloric acid solution ice-cooled to 10° C. or less. After performing liquid-liquid separation and removing the aqueous layer, the organic layer was washed three times with 300 ml of water, and the solvent was removed by concentration under a reduced pressure. The obtained residue was dissolved in 20 ml of ethyl acetate, and 120 ml of hexane was added while stirring at room temperature (23° C.), resulting in crystal precipitation. After stirring for 30 minutes in this state, the crystals were collected by filtration to obtain 31.2 g of an intermediate B2-4-1 (yield: 62%). ¹H NMR (CDCl₃): 4.56, 4.22, 3.25, 2.11, 1.01 ppm

### Synthesis of Intermediate B2-4-2

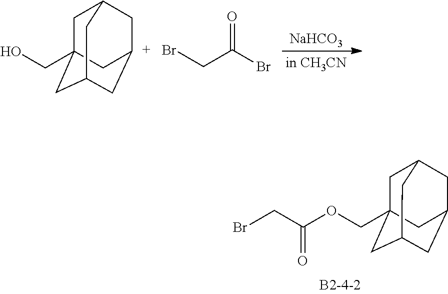

To a mixed solution of 10 g (0.060 mol) of 1-adamantanemethanol, 11.1 g (0.13 mol) of sodium hydrogencarbonate, and 120 ml of acetonitrile under stirring under ice-cooling at 5° C. or less, 13.4 g (0.066 mol) of bromoacetic acid bromide was slowly added dropwise. After stirring for 1 hour under ice-cooling in this state, 100 ml of water was slowly added dropwise. Methylene chloride (200 ml) and 100 ml of water were added to perform liquid-liquid separation, the aqueous layer was removed, and then the organic layer was washed three times with 200 ml of water. The organic layer was concentrated under a reduced pressure to remove the solvent, and 16 g of a crude intermediate B2-4-2 was obtained. This crude product was not further purified and was directly used for the next reaction.

### Synthesis of Intermediate B2-4-3

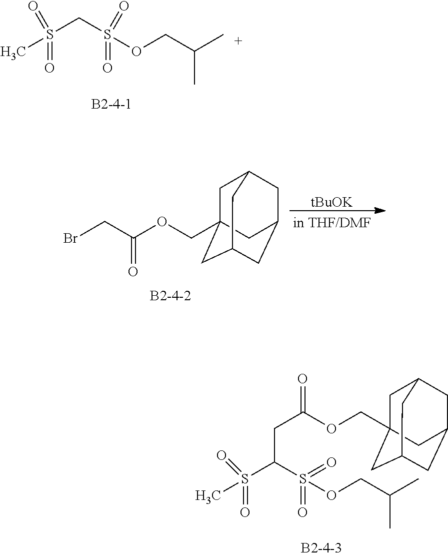 [SMILES: "tBuOK" ; CC(C)COS(=O)(=O)CS(C)(=O)=O ; O=C(CBr)OCC12CC3CC(CC(C3)C1)C2 ; CC(C)COS(=O)(=O)C(CC(=O)OCC12CC3CC(CC(C3)C1)C2)S(C)(=O)=O]

To a mixed solution of 5.0 g (0.022 mol) of the intermediate B2-4-1, 50 ml of tetrahydrofuran (THF), and 20 ml of N,N-dimethylformamide (DMF), 2.6 g (0.023 mol) of tert-butoxypotassium was slowly added at 0° C. under a nitrogen atmosphere, and the mixture was stirred for 10 minutes. Subsequently, 6.9 g (0.024 mol) of the intermediate B2-4-2 was slowly added, and stirring was continued at room temperature (23° C.) for 5 hours. The reaction solution was added to 70 ml of a 1 mol/1 aqueous hydrochloric acid solution under ice-cooling at 10° C. or less. Ethyl acetate (150 ml) was added to perform liquid-liquid separation, and the aqueous layer was removed; subsequently, the organic layer was washed three times with 70 ml of water, and concentrated under a reduced pressure to thereby distill off the solvent. The obtained residue was purified by silica gel column chromatography (hexane/ethyl acetate=4/1 (volumetric ratio)) to thereby obtain 3.5 g of an intermediate B2-4-3 (yield: 37%). ¹H NMR (CDCl₃): 5.06, 4.21, 3.79, 3.34-3.18, 3.27, 2.06, 2.00, 1.78-1.61, 1.54, 1.00 ppm

### Synthesis of Intermediate B2-4-4

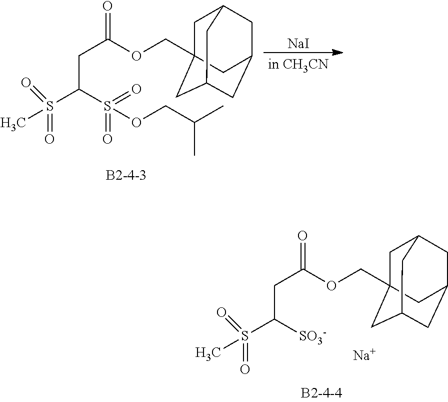

To a mixed solution of 3.0 g (6.9 mmol) of the intermediate B2-4-3 and 50 ml of acetonitrile, 1.1 g (7.6 mmol) of sodium iodide was added, and the mixture was stirred at 50° C. for 3 hours. The precipitated crystals were collected by filtration to obtain 2.4 g of an intermediate B2-4-4 (yield: 87%).

¹H NMR (DMSO-d6): 4.27, 3.65, 3.13, 2.98-2.80, 1.94, 1.73-1.56, 1.50 ppm

### Synthesis of B2-4

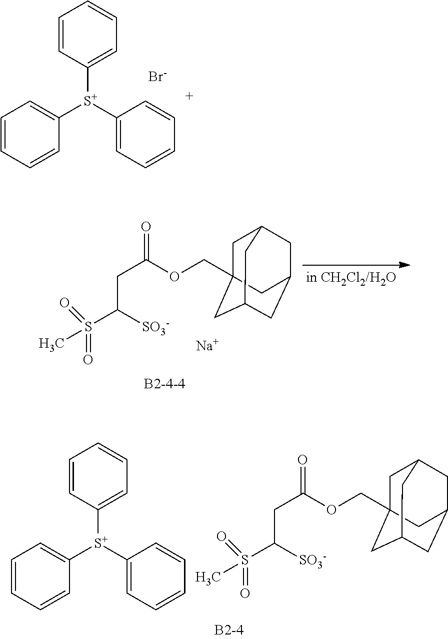

To a mixed solvent of 2.1 g (52 mmol of the intermediate B32-4-4, 35 ml of methylene chloride, and 35 ml of water, 1.8 g (5.4 mmol) of triphenylsulfonium bromide was added, and the mixture was stirred at room temperature (23° C.) for 1 hour. After the reaction, the organic layer was extracted, washed once with 35 ml of a 0.1 mol/1 aqueous hydrochloric acid solution and four times with 35 ml of water, and then concentrated under a reduced pressure. To the residue, 30 ml of tert-butyl methyl ether was added and stirred at room temperature, and the solid obtained by filtration was vacuum-dried to thereby obtain 3 g of B2-4 (yield: 88%). ¹H NMR (CDCl₃): 7.82-7.66, 4.76, 3.68, 3.31, 3.35-3.12, 1.95, 1.74-1.58, 1.52 ppm

The other onium salts (B-2) were also synthesized in the same manner as described above.

B1-1 was synthesized according to the method described in JP2010-155824A. The other onium salts (B-1) were synthesized in the same manner.

### Resin (A)

As the resin (A) (resin that is subjected to action of an acid to undergo an increase in polarity), A-1 to A-20 described in Table 3 were used.

Table 3 describes the contents (mol %; sequentially described from the left) of repeating units described later in the resin (A), the weight-average molecular weight (Mw) of the resin (A), and the dispersity (Mw/Mn) of the resin (A). The weight-average molecular weight (Mw) and the dispersity (Mw/Mn) were measured by GPC (carrier: tetrahydrofuran (THF)) (polystyrene-equivalent amounts). The content of each repeating unit was measured by ¹³C-NMR (Nuclear Magnetic Resonance).

Table 3 also describes the SP value (SP_{A}) of each resin.

In the present Examples, the SP values of the resins were calculated in the following manner.

### Calculation Method of SP Values of Resins

The method for calculating the SP value of such a resin will be described below.
1. The SP values of monomers corresponding to the repeating units constituting the resin were calculated using “HSPiP 5th Edition 5.1.08”.
2. The mass-based content ratios of the repeating units relative to the resin were multiplied by the SP values (obtained in the above 1.) of the monomers corresponding to the repeating units, summed up, and the resultant numerical value was defined as the SP value of the resin.

This calculation method was used to calculate the SP value (SP_{A}) of the resin (A) and the SP value (SP_{D}) of the resin (D). When two or more resins were used in combination, in the above 2. describing the calculation method, the mass-based content ratios of the resins and the SP values of the resins were multiplied, and the resultant values were summed up to determine the SP value of the resin.

TABLE 3

| | Contents of repeating units | | | | | | |
|---|---|---|---|---|---|---|---|
| Resin (A) | (mol %) | | | | Mw | Mw/Mn | SP_{A} |
| A-1 | 50 | 50 | — | — | 6500 | 1.52 | 18.05 |
| A-2 | 45 | 55 | — | — | 8300 | 1.65 | 18.78 |
| A-3 | 40 | 30 | 30 | — | 7800 | 1.55 | 18.72 |
| A-4 | 40 | 50 | 10 | — | 12000 | 1.68 | 17.59 |
| A-5 | 50 | 50 | — | — | 5500 | 1.49 | 18.95 |
| A-6 | 25 | 30 | 30 | 15 | 8600 | 1.63 | 18.96 |
| A-7 | 40 | 10 | 30 | 20 | 9600 | 1.72 | 18.28 |
| A-8 | 40 | 5 | 55 | — | 10200 | 1.64 | 17.99 |
| A-9 | 30 | 20 | 40 | 10 | 7500 | 1.54 | 19.00 |
| A-10 | 40 | 10 | 40 | 10 | 7000 | 1.61 | 18.10 |
| A-11 | 40 | 10 | 10 | 40 | 6500 | 1.63 | 18.39 |
| A-12 | 40 | 30 | 30 | — | 5900 | 1.59 | 18.59 |
| A-13 | 10 | 30 | 60 | — | 5200 | 1.53 | 18.33 |
| A-14 | 25 | 15 | 60 | — | 6200 | 1.48 | 18.83 |
| A-15 | 50 | 50 | — | — | 7000 | 1.73 | 18.62 |
| A-16 | 30 | 10 | 60 | — | 11500 | 1.56 | 19.35 |
| A-17 | 35 | 10 | 55 | — | 8400 | 1.58 | 19.09 |
| A-18 | 40 | 10 | 50 | — | 9200 | 1.66 | 19.57 |
| A-19 | 40 | 60 | — | — | 6500 | 1.55 | 19.12 |
| A-20 | 30 | 20 | 50 | — | 7600 | 1.56 | 19.56 |

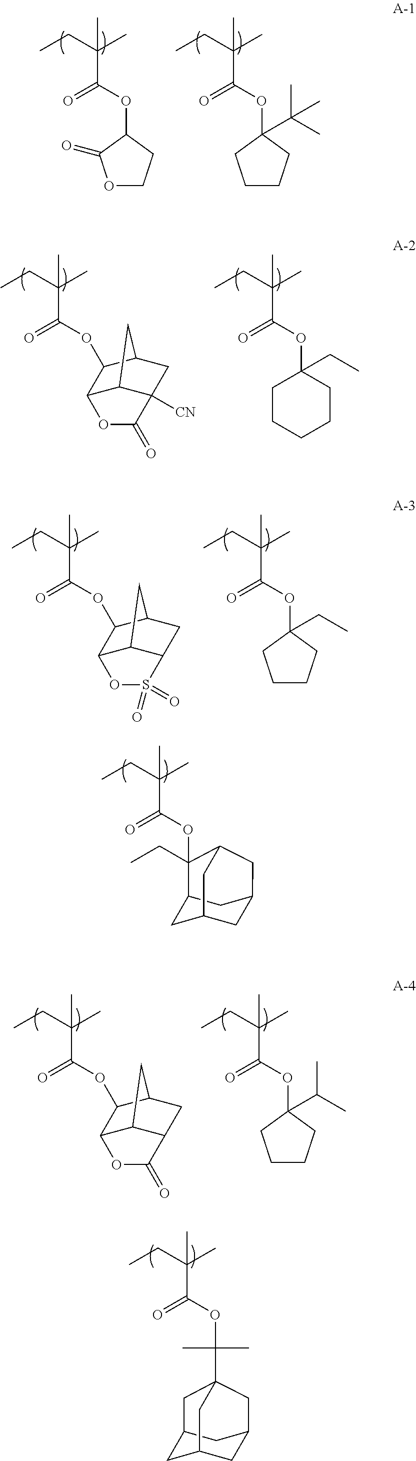

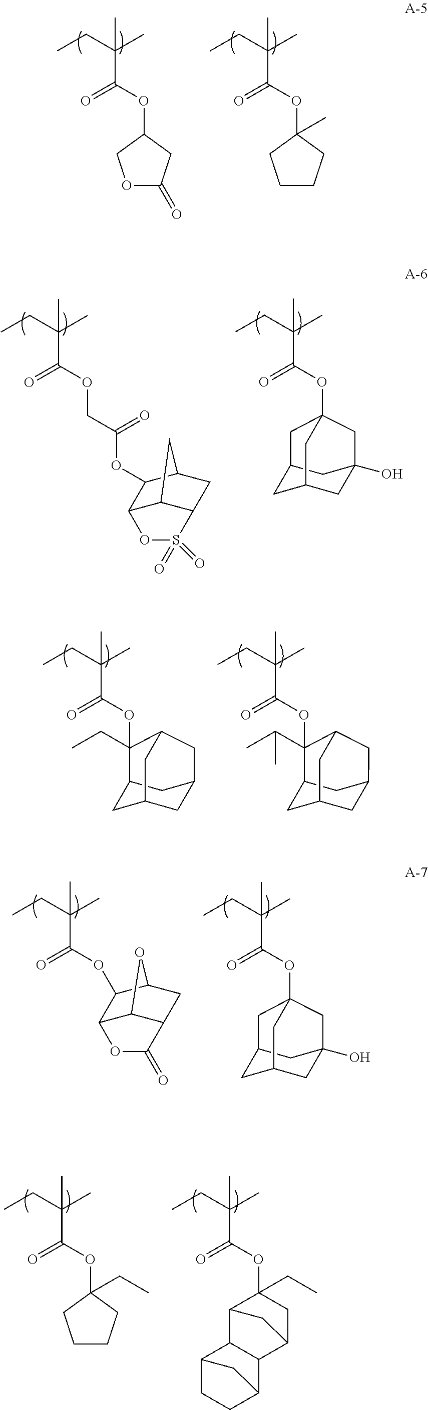

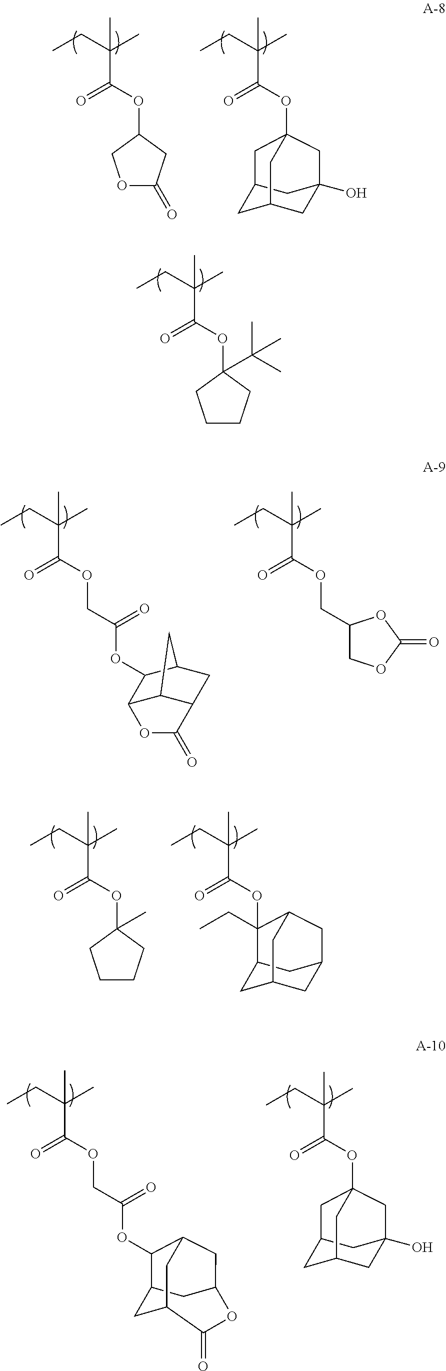

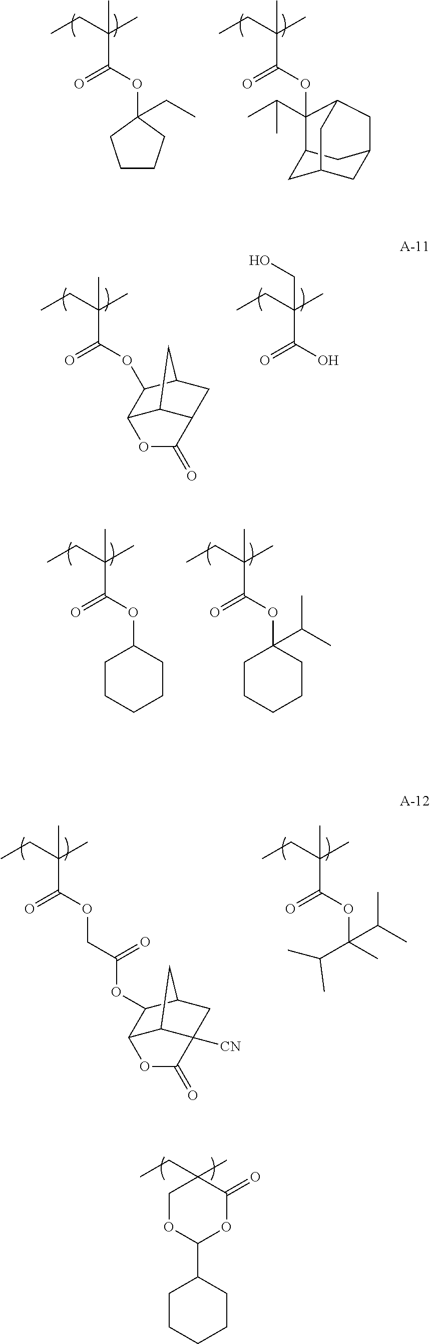

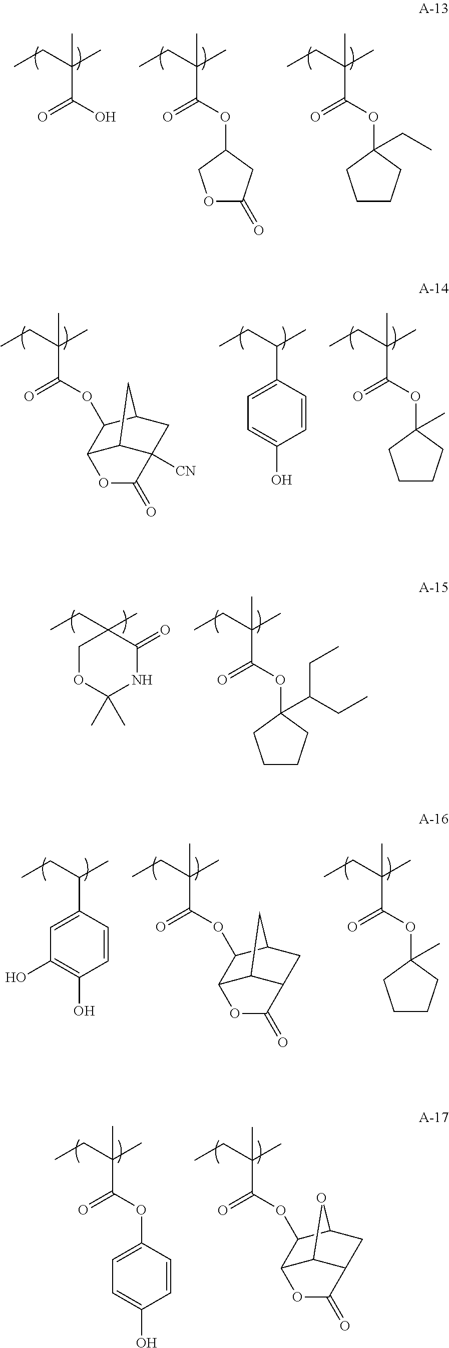

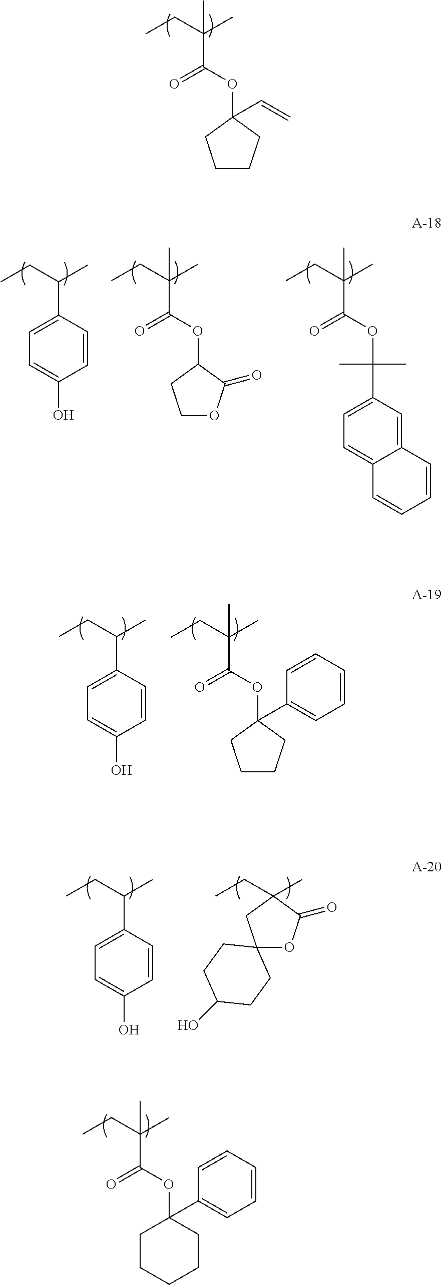

### Basic Compounds

As basic compounds, C-1 to C-4 were used. C-1 to C-4 can act as acid diffusion control agents.

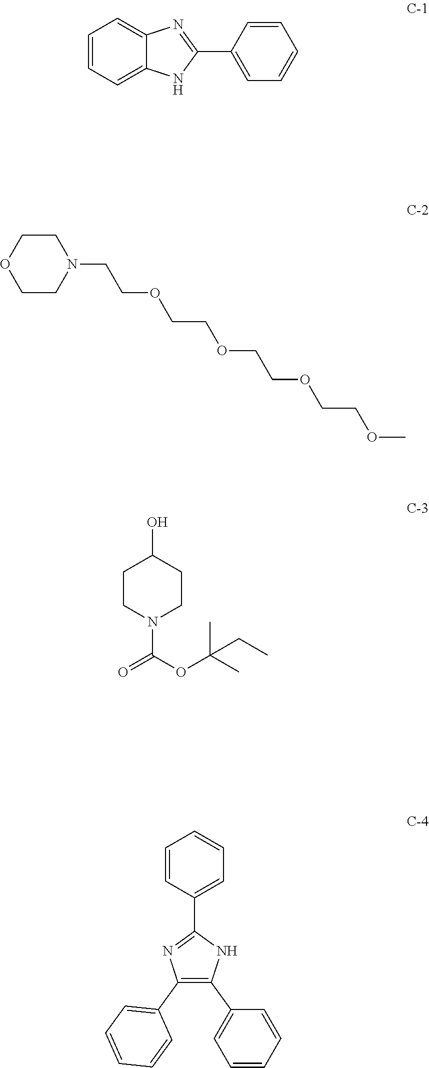 [SMILES: c1ccc(-c2nc3ccccc3[nH]2)cc1 ; COCCOCCOCCOCCN1CCOCC1 ; CCC(C)(C)OC(=O)N1CCC(O)CC1 ; c1ccc(-c2nc(-c3ccccc3)c(-c3ccccc3)[nH]2)cc1]

### Resin (D)

As the resin (D), D-1 to D-6 described in Table 4 were used.

Table 4 describes the contents (mol %; sequentially described from the left) of the repeating units described later in the resin (D), the weight-average molecular weight (Mw) of the resin (D), and the dispersity (Mw/Mn) of the resin (D). The weight-average molecular weight (Mw) and the dispersity (Mw/Mn) were measured by GPC (carrier: tetrahydrofuran (THF)) (polystyrene-equivalent amounts). The content of each repeating unit was measured by ¹³C-NMR (Nuclear Magnetic Resonance).

Table 4 also describes the SP value (SP_{D}) of each resin.

TABLE 4

| | Contents of repeating units | | | | | | |
|---|---|---|---|---|---|---|---|
| Resin (D) | (mol %) | | | | Mw | Mw/Mn | [SP_{D}] |
| D-1 | 50 | 50 | — | — | 12000 | 1.51 | 16.87 |
| D-2 | 60 | 30 | 10 | — | 15000 | 1.50 | 16.04 |
| D-3 | 100 | — | — | — | 13000 | 1.50 | 16.23 |
| D-4 | 70 | 25 | 5 | — | 10000 | 1.53 | 16.17 |
| D-5 | 60 | 25 | 10 | 5 | 9000 | 1.54 | 16.26 |
| D-6 | 50 | 35 | 10 | 5 | 7000 | 1.45 | 17.03 |

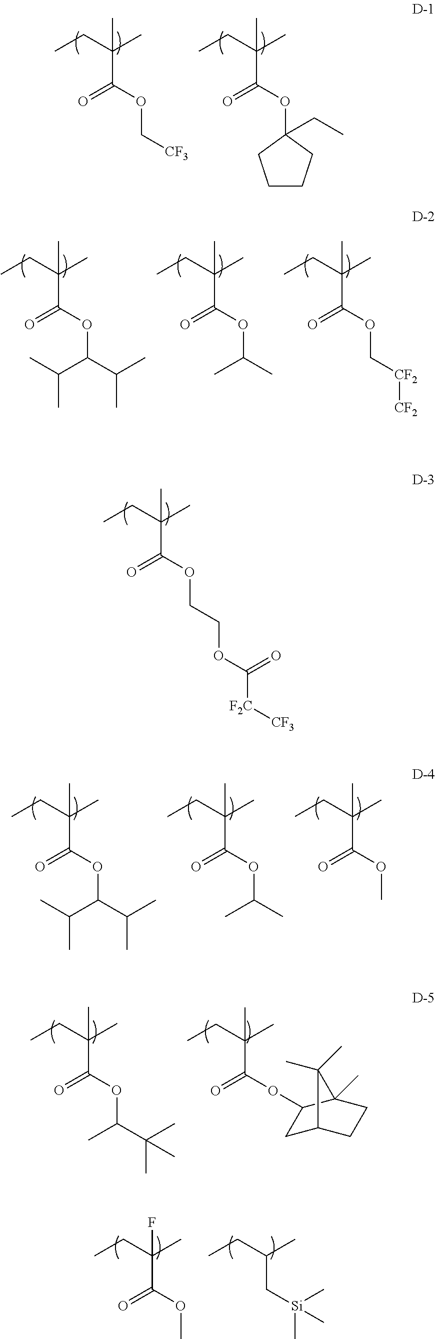

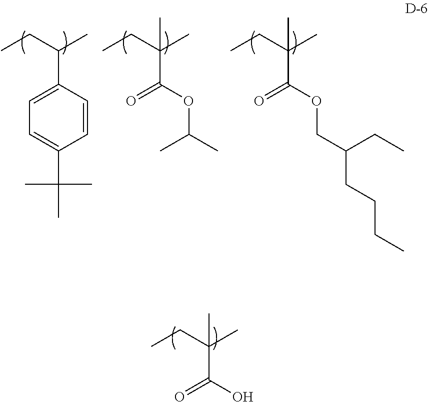

### Surfactant

As a surfactant, E-1 was used.
E-1: PolyFox PF-6320 (manufactured by OMNOVA Solutions Inc.; fluorine-based) Solvents

The solvents employed are as follows.
S1: propylene glycol monomethyl ether acetate (PGMEA)
S2: propylene glycol monomethyl ether (PGME)
S3: 7-butyrolactone
S4: ethyl lactate
S5: cyclohexanone
S6: 2-heptanone

### ArF Exposure

### Preparation of Resist Compositions

In the solvents described in Tables 5 to 8, the non-solvent components described in Tables 5 to 8 were dissolved to prepare solutions having a solid-content concentration of 4.0 mass %, and the solutions were filtered through a polyethylene filter having a pore size of 0.02 m, to prepare resist compositions (RA-1 to RA-87 and RZ-1 to RZ-10).

Note that the solid content means all the components other than the solvent. The obtained resist compositions were used in Examples and Comparative Examples.

In Tables 5 to 8, the columns “mass %” indicate the content (mass %) of each component relative to the total solid content in the resist composition. Tables 5 to 8 also describe the amounts (mass ratios) of the solvents used.

When two or more components were used, the types and contents (mass %) thereof are individually indicated so as to be separated by “/” (the types and contents are sequentially described from the left).

Tables 5 to 8 describe ΔpKa (pKa^{B1}-pKa^{B2}), which is the difference between the pKa (pKa^{B1}) of the acid (AC_{B1}) generated from the onium salt (B-1) and the pKa (pKa^{B2}) of the acid (AC_{B2}) generated from the onium salt (B-2) in each resist composition.

TABLE 5

| | Resin | | Onium | | Onium | | Basic | | Resin | | | | | | |
|---|---|---|---|---|---|---|---|---|---|---|---|---|---|---|---|
| | (A) | | salt (B-1) | | salt (B-2) | | compound | | (D) | | Surfactant | | Solvent | | |
| Resist | | mass | | mass | | mass | | mass | | mass | | mass | | Mass | |
| composition | Type | % | Type | % | Type | % | Type | % | Type | % | Type | % | Type | ratio | ΔpKa |
| RA-1 | A-1 | 84.5 | B1-1 | 2.6 | B2-1 | 11.2 | C-1 | 0.1 | D-2 | 1.5 | E-1 | 0.1 | S1/S2 | 70/30 | 2.28 |
| RA-2 | A-1 | 82.4 | B1-2 | 2.2 | B2-4 | 12.2 | C-3 | 0.2 | D-4 | 3.0 | — | — | S1/S2 | 80/20 | 3.71 |
| RA-3 | A-1 | 84.8 | B1-15 | 3.3 | B2-4 | 10.7 | C-3 | 0.2 | D-5 | 1.0 | — | — | S1/S3 | 80/20 | 2.26 |
| RA-4 | A-1 | 83.3 | B1-16 | 4.3 | B2-8 | 10.4 | — | — | D-6 | 2.0 | — | — | S1/S2 | 90/10 | 1.38 |
| RA-5 | A-1 | 84.9 | B1-3 | 3.3 | B2-7 | 11.8 | — | — | — | — | — | — | S1/S3 | 75/25 | 5.42 |
| RA-6 | A-1/ | 42.3/ | B1-1 | 2.6 | B2-1 | 11.2 | C-1 | 0.1 | D-2 | 1.5 | — | — | S1/S2 | 70/30 | 2.28 |
| | A-13 | 42.3 | | | | | | | | | | | | | |
| RA-7 | A-2 | 82.3 | B1-5 | 3.6 | B2-9 | 11.1 | — | — | D-4 | 3.0 | — | — | S1/ | 70/ | 1.63 |
| | | | | | | | | | | | | | S2/S4 | 25/5 | |
| RA-8 | A-2 | 84.1 | B1-11 | 4.1 | B2-24 | 10.8 | — | — | D-1 | 1.0 | — | — | S1/S2 | 60/40 | 11.08 |
| RA-9 | A-3 | 83.2 | B1-12 | 5.3 | B2-22 | 10.5 | — | — | D-5 | 1.0 | — | — | S1/S2 | 70/30 | 1.73 |
| RA-10 | A-3 | 79.7 | B1-4 | 5.3 | B2-26 | 11.8 | C-4 | 0.2 | D-4 | 3.0 | — | — | S1/ | 70/ | 1.98 |
| | | | | | | | | | | | | | S2/S3 | 25/5 | |
| RA-11 | A-3 | 86.1 | B1-3 | 2.2 | B2-28 | 10.2 | — | — | D-2 | 1.5 | — | — | S1/S2 | 70/30 | 3.86 |
| RA-12 | A-4 | 84.6 | B1-2 | 2.2 | B2-4 | 12.2 | C-3 | 0.2 | D-3 | 0.8 | — | — | S1/S2 | 50/50 | 3.71 |
| RA-13 | A-4 | 81.1 | B1-14 | 2.8 | B2-5 | 13.1 | — | — | D-4 | 3.0 | — | — | S1/S3 | 85/15 | 1.97 |
| RA-14 | A-4 | 82.2 | B1-16 | 5.0 | B2-20 | 11.8 | — | — | D-5 | 1.0 | — | — | S1/ | 70/ | 2.27 |
| | | | | | | | | | | | | | S2/S6 | 25/5 | |
| RA-15 | A-4 | 84.1 | B1-6 | 4.4 | B2-2 | 10.0 | — | — | D-2 | 1.5 | — | — | S1/S2 | 75/25 | 1.34 |
| RA-16 | A-5 | 84.1 | B1-2 | 2.2 | B2-4 | 12.2 | — | — | D-2 | 1.5 | — | — | S1/S2 | 60/40 | 3.71 |
| RA-17 | A-5 | 77.1 | B1-15 | 3.3 | B2-3 | 16.4 | C-2 | 0.2 | D-4 | 3.0 | — | — | S1/ | 70/ | 2.84 |
| | | | | | | | | | | | | | S2/S5 | 25/5 | |
| RA-18 | A-5 | 84.0 | B1-4 | 6.6 | B2-7 | 8.4 | — | — | D-1 | 1.0 | — | — | S1/S2 | 70/30 | 2.04 |
| RA-19 | A-5 | 85.2 | B1-6 | 2.9 | B2-18 | 10.9 | — | — | D-5 | 1.0 | — | — | S1/S2 | 90/10 | 3.33 |
| RA-20 | A-6 | 83.0 | B1-2 | 2.2 | B2-11 | 13.3 | — | — | D-2 | 1.5 | — | — | S1/S3 | 80/20 | 4.19 |
| RA-21 | A-6 | 88.3 | B1-4 | 2.6 | B2-14 | 8.0 | C-2 | 0.1 | D-1 | 1.0 | — | — | S1/ | 80/ | 2.71 |
| | | | | | | | | | | | | | S2/S3 | 10/10 | |
| RA-22 | A-6 | 83.3 | B1-4 | 3.3 | B2-4 | 11.4 | — | — | D-4 | 2.0 | — | — | S1/S2 | 70/30 | 1.94 |
| RA-23 | A-6 | 86.8 | B1-10 | 2.0 | B2-13 | 10.4 | — | — | D-5 | 0.8 | — | — | S1/ | 35/ | 3.67 |
| | | | | | | | | | | | | | S2/S4 | 60/5 | |
| RA-24 | A-6 | 83.0 | B1-12 | 2.4 | B2-23 | 13.1 | — | — | D-2 | 1.5 | — | — | S1/S2 | 40/60 | 1.28 |
| RA-25 | A-7 | 84.1 | B1-1 | 4.6 | B2-1 | 9.1 | C-1 | 0.2 | D-2 | 2.0 | — | — | S1/S2 | 95/5 | 2.28 |

TABLE 6

| | Resin | | Onium | | Onium | | Basic | | Resin | | | | | | |
|---|---|---|---|---|---|---|---|---|---|---|---|---|---|---|---|
| | (A) | | salt (B-1) | | salt (B-2) | | compound | | (D) | | Surfactant | | Solvent | | |
| Resist | | mass | | mass | | mass | | mass | | mass | | mass | | Mass | |
| composition | Type | % | Type | % | Type | % | Type | % | Type | % | Type | % | Type | ratio | ΔpKa |
| RA-26 | A-7 | 81.7 | B1-1 | 3.9 | B2-22 | 13.4 | — | — | D-5 | 1.0 | — | — | S1/S2 | 80/20 | 3.90 |
| RA-27 | A-7 | 85.5 | B1-3 | 2.2 | B2-19 | 11.3 | — | — | D-5 | 1.0 | — | — | S1/S4 | 95/5 | 5.68 |
| RA-28 | A-7 | 81.9 | B1-10 | 3.4 | B2-25 | 13.2 | — | — | D-2 | 1.5 | — | — | S1/S2 | 70/30 | 4.12 |
| RA-29 | A-7 | 84.6 | B1-17 | 1.3 | B2-11 | 13.3 | — | — | D-1 | 0.8 | — | — | S1/S3 | 90/10 | 6.67 |
| RA-30 | A-8 | 80.9 | B1-1 | 2.6 | B2-5 | 13.1 | C-2 | 0.3 | D-4 | 3.0 | E-1 | 0.1 | S1/S2 | 70/30 | 1.97 |
| RA-31 | A-8 | 82.5 | B1-4 | 2.6 | B2-21 | 13.9 | — | — | D-1 | 1.0 | — | — | S1/S4 | 90/10 | 2.25 |
| RA-32 | A-8 | 78.1 | B1-8 | 7.0 | B2-28 | 13.4 | — | — | D-2 | 1.5 | — | — | S1/S2 | 50/50 | 1.51 |
| RA-33 | A-8 | 86.5 | B1-16 | 5.0 | B2-14 | 6.5 | — | — | D-6 | 2.0 | — | — | S1/S3 | 85/15 | 3.13 |
| RA-34 | A-8 | 83.7 | B1-13 | 5.4 | B2-15 | 9.2 | C-3 | 0.2 | D-2 | 1.5 | — | — | S1/S2 | 70/30 | 9.76 |
| RA-35 | A-9 | 84.1 | B1-1 | 3.3 | B2-4 | 11.4 | C-2 | 0.2 | D-5 | 1.0 | — | — | S1/S2/ | 85/10/5 | 1.97 |
| | | | | | | | | | | | | | S3 | | |
| RA-36 | A-9 | 85.4 | B1-7 | 4.0 | B2-13 | 9.8 | — | — | D-3 | 0.8 | — | — | S1/S2/ | 65/20/ | 2.05 |
| | | | | | | | | | | | | | S3/S4 | 10/5 | |
| RA-37 | A-9 | 80.3 | B1-7 | 3.0 | B2-25 | 15.0 | C-3 | 0.2 | D-2 | 1.5 | — | — | S1/S2/ | 75/20/5 | 2.50 |
| | | | | | | | | | | | | | S5 | | |
| RA-38 | A-9 | 83.0 | B1-8 | 3.1 | B2-8 | 11.9 | — | — | D-6 | 2.0 | — | — | S1/S2 | 70/30 | 1.99 |
| RA-39 | A-9 | 85.4 | B1-7 | 4.0 | B2-13/ | 6.0/3.8 | — | — | D-3 | 0.8 | — | — | S1/S2 | 80/20 | 2.05 |
| | | | | | B2-18 | | | | | | | | | | |
| RA-40 | A-10 | 81.5 | B1-2 | 3.4 | B2-26 | 13.7 | C-1 | 0.2 | D-1 | 1.2 | — | — | S1/S2 | 40/60 | 3.75 |
| RA-41 | A-10 | 82.9 | B1-3 | 2.2 | B2-8 | 11.9 | — | — | D-4 | 3.0 | — | — | S1/ | 85/10/5 | 4.34 |
| | | | | | | | | | | | | | S3/S4 | | |
| RA-42 | A-10 | 82.2 | B1-5 | 7.1 | B2-2 | 8.6 | — | — | D-6 | 2.0 | E-1 | 0.1 | S1/S2 | 75/25 | 2.29 |
| RA-43 | A-10 | 82.6 | B1-8 | 3.1 | B2-11 | 13.3 | — | — | D-2 | 1.0 | — | — | S1/S2 | 80/20 | 3.45 |
| RA-44 | A-10 | 84.4 | B1-9 | 2.1 | B2-27 | 12.5 | C-3 | 0.2 | D-3 | 0.8 | — | — | S1/S2/ | 75/20/5 | 8.43 |
| | | | | | | | | | | | | | S4 | | |
| RA-45 | A-10 | 85.8 | B1-18 | 3.1 | B2-29 | 10.3 | — | — | D-3 | 0.8 | — | — | S1/S2 | 80/20 | 3.02 |
| RA-46 | A-10 | 89.3 | B1-18 | 1.5 | B2-14 | 8.0 | — | — | D-5 | 1.2 | — | — | S1/S2 | 70/30 | 3.48 |
| RA-47 | A-11 | 83.4 | B1-5 | 2.7 | B2-30 | 12.9 | — | — | D-1 | 1.0 | — | — | S1/S2 | 60/40 | 1.70 |
| RA-48 | A-11 | 83.5 | B1-11 | 2.4 | B2-3 | 10.9 | C-4 | 0.2 | D-4 | 3.0 | — | — | S1/S2 | 50/50 | 11.69 |
| RA-49 | A-11 | 81.2 | B1-10 | 2.7 | B2-10 | 15.1 | — | — | D-3 | 1.0 | — | — | S1/S2/ | 80/15/5 | 4.74 |
| | | | | | | | | | | | | | S4 | | |
| RA-50 | A-12 | 84.2 | B1-1 | 3.3 | B2-1 | 10.5 | — | — | D-6 | 2.0 | — | — | S1/S2 | 50/50 | 2.28 |

TABLE 7

| | Resin | | Onium | | Onium | | Basic | | Resin | | | | | | |
|---|---|---|---|---|---|---|---|---|---|---|---|---|---|---|---|
| | (A) | | salt (B-1) | | salt (B-2) | | compound | | (D) | | Surfactant | | Solvent | | |
| Resist | | mass | | mass | | mass | | mass | | mass | | mass | | Mass | |
| composition | Type | % | Type | % | Type | % | Type | % | Type | % | Type | % | Type | ratio | ΔpKa |
| RA-51 | A-12 | 82.3 | B1-2 | 3.4 | B2-17 | 12.8 | — | — | D-2 | 1.5 | — | — | S1/S2 | 60/40 | 3.20 |
| RA-52 | A-12 | 78.5 | B1-7 | 4.0 | B2-16 | 13.8 | C-4 | 0.2 | D-4 | 3.5 | — | — | S1/S2/ | 75/15/ | 3.93 |
| | | | | | | | | | | | | | S3 | 10 | |
| RA-53 | A-13 | 81.7 | B1-16 | 5.0 | B2-20 | 11.8 | — | — | D-2 | 1.5 | — | — | S1/S2 | 70/30 | 2.27 |
| RA-54 | A-13 | 80.6 | B1-7 | 4.0 | B2-12 | 14.9 | — | — | D-1 | 0.5 | — | — | S1/S2 | 80/20 | 5.67 |
| RA-55 | A-13 | 82.6 | B1-10 | 3.4 | B2-21 | 13.0 | — | — | D-5 | 1.0 | — | — | S1/S2 | 65/35 | 4.58 |
| RA-56 | A-13 | 83.4 | B1-13 | 2.4 | B2-15 | 13.4 | — | — | D-3 | 0.8 | — | — | S1/S4 | 90/10 | 9.76 |
| RA-57 | A-14 | 78.8 | B1-3 | 5.7 | B2-1 | 13.7 | C-3 | 0.3 | D-2 | 1.5 | — | — | S1/S2/ | 70/25/ | 5.63 |
| | | | | | | | | | | | | | S5 | 5 | |
| RA-58 | A-14 | 81.9 | B1-14 | 2.8 | B2-4 | 12.2 | — | — | D-4 | 3.0 | E-1 | 0.1 | S1/S2 | 60/40 | 1.97 |
| RA-59 | A-14 | 77.2 | B1-8 | 4.6 | B2-2 | 17.2 | — | — | D-1 | 1.0 | — | — | S1/S2 | 80/20 | 3.30 |
| RA-60 | A-14 | 83.2 | B1-15 | 1.1 | B2-5 | 14.7 | — | — | D-5 | 1.0 | — | — | S1/S2 | 80/20 | 2.26 |
| RA-61 | A-14 | 80.8 | B1-6 | 2.9 | B2-16 | 13.8 | — | — | D-6 | 2.5 | — | — | S1/S2 | 60/40 | 2.29 |
| RA-62 | A-14 | 83.6 | B1-7 | 5.0 | B2-30 | 11.4 | — | — | — | — | — | — | S1/S2 | 70/30 | 2.39 |
| RA-63 | A-15 | 82.2 | B1-5 | 5.3 | B2-23 | 11.5 | — | — | D-3 | 1.0 | — | — | S1/S2/ | 65/30/ | 3.44 |
| | | | | | | | | | | | | | S6 | 5 | |
| RA-64 | A-15 | 82.8 | B1-9 | 3.2 | B2-27 | 11.0 | — | — | D-4 | 3.0 | — | — | S1 | 100 | 8.43 |
| RA-65 | A-15 | 85.0 | B1-17 | 1.7 | B2-24 | 12.4 | C-1 | 0.1 | D-1 | 0.8 | — | — | S1/S3 | 90/10 | 6.16 |
| RA-66 | A-16 | 85.1 | B1-1 | 3.3 | B2-1 | 10.5 | — | — | D-5 | 1.0 | E-1 | 0.1 | S1/S2 | 70/30 | 2.28 |
| RA-67 | A-16 | 78.0 | B1-2 | 5.0 | B2-4 | 16.0 | C-2 | 0.2 | D-2 | 0.8 | — | — | S1/S2/ | 80/10/ | 3.71 |
| | | | | | | | | | | | | | S3 | 10 | |
| RA-68 | A-16 | 82.7 | B1-8 | 6.2 | B2-29 | 10.3 | — | — | D-3 | 0.8 | — | — | S1/S2 | 70/30 | 3.28 |
| RA-69 | A-16 | 73.4 | B1-14 | 6.4 | B2-5 | 17.2 | — | — | D-4 | 3.0 | — | — | S1/S2 | 70/30 | 1.97 |
| RA-70 | A-16 | 79.8 | B1-5 | 3.6 | B2-20 | 14.6 | — | — | D-6 | 2.0 | — | — | S1/S4 | 85/15 | 1.87 |
| RA-71 | A-17 | 85.8 | B1-2 | 3.4 | B2-3 | 9.6 | C-1 | 0.2 | D-1 | 1.0 | — | — | S1/S2/ | 70/20/ | 4.29 |
| | | | | | | | | | | | | | S3/S4 | 5/5 | |
| RA-72 | A-17 | 84.2 | B1-4 | 2.6 | B2-6 | 12.2 | — | — | D-1 | 1.0 | — | — | S1/S2 | 60/40 | 3.94 |
| RA-73 | A-17 | 84.9 | B1-12 | 2.9 | B2-18 | 10.2 | — | — | D-6 | 2.0 | — | — | S1/S2 | 95/5 | 2.12 |
| RA-74 | A-17 | 77.4 | B1-10 | 7.2 | B2-28 | 12.4 | — | — | D-4 | 3.0 | — | — | S1/S3/ | 85/10/ | 2.81 |
| | | | | | | | | | | | | | S4 | 5 | |
| RA-75 | A-18 | 83.3 | B1-7 | 4.0 | B2-30 | 12.2 | — | — | D-3 | 0.5 | — | — | S1/S2 | 80/20 | 2.39 |

TABLE 8

| | Resin | | Onium | | Onium | | Basic | | Resin | | | | | | |
|---|---|---|---|---|---|---|---|---|---|---|---|---|---|---|---|
| | (A) | | salt (B-1) | | salt (B-2) | | compound | | (D) | | Surfactant | | Solvent | | |
| Resist | | mass | | mass | | mass | | mass | | mass | | mass | | Mass | |
| composition | Type | % | Type | % | Type | % | Type | % | Type | % | Type | % | Type | ratio | ΔpKa |
| RA-76 | A-18 | 85.2 | B1-1 | 4.6 | B2-19 | 9.2 | C-4 | 0.2 | D-5 | 0.8 | — | — | S1/S2/ | 80/15/ | 2.33 |
| | | | | | | | | | | | | | S5 | 5 | |
| RA-77 | A-18 | 77.1 | B1-8 | 4.6 | B2-18 | 16.3 | — | — | D-2 | 2.0 | — | — | S1/S3 | 95/5 | 5.29 |
| RA-78 | A-18 | 81.3 | B1-9 | 2.1 | B2-25 | 14.1 | — | — | D-6 | 2.5 | — | — | S1/S2 | 70/30 | 5.41 |
| RA-79 | A-19 | 75.8 | B1-3 | 4.9 | B2-7 | 17.7 | — | — | D-2 | 1.5 | E-1 | 0.1 | S1/S2 | 90/10 | 5.42 |
| RA-80 | A-19 | 82.2 | B1-4 | 4.0 | B2-17 | 12.8 | — | — | D-5 | 1.0 | — | — | S1/S2/ | 80/15/ | 1.43 |
| | | | | | | | | | | | | | S3 | 5 | |
| RA-81 | A-19 | 84.2 | B1-5 | 4.4 | B2-9 | 10.4 | — | — | D-1 | 1.0 | — | — | S1/S2 | 40/60 | 1.63 |
| RA-82 | A-19 | 80.2 | B1-13 | 1.8 | B2-10 | 16.0 | — | — | D-6 | 2.0 | — | — | S1/S2 | 65/35 | 6.92 |
| RA-83 | A-19 | 82.2 | B1-4/ | 2.0/2.0 | B2-17 | 14.6 | — | — | D-5 | 1.0 | — | — | S1/S4 | 90/10 | 1.43 |
| | | | B1-16 | | | | | | | | | | | | |
| RA-84 | A-20 | 84.9 | B1-1 | 3.9 | B2-2 | 10.0 | C-1 | 0.2 | D-5 | 1.0 | — | — | S1/S2/ | 75/20/ | 2.30 |
| | | | | | | | | | | | | | S5 | 5 | |
| RA-85 | A-20 | 79.6 | B1-7 | 4.0 | B2-12 | 14.9 | — | — | D-2 | 1.5 | — | — | S1/S2 | 50/50 | 5.67 |
| RA-86 | A-20 | 80.5 | B1-7 | 5.0 | B2-17 | 13.7 | — | — | D-3 | 0.8 | — | — | S1/S2/ | 65/30/ | 2.14 |
| | | | | | | | | | | | | | S4 | 5 | |
| RA-87 | A-20 | 84.6 | B1-15 | 2.2 | B2-6 | 12.2 | — | — | D-5 | 1.0 | — | — | S1/S2 | 80/20 | 4.26 |
| RZ-1 | A-1 | 85.0 | Z1-1 | 2.3 | B2-1 | 11.2 | — | — | D-2 | 1.5 | — | — | S1/S2 | 70/30 | 2.38 |
| RZ-2 | A-1 | 85.4 | Z1-2 | 1.9 | B2-1 | 11.2 | — | — | D-2 | 1.5 | — | — | S1/S2 | 70/30 | 4.22 |
| RZ-3 | A-1 | 85.1 | Z1-3 | 2.2 | B2-1 | 11.2 | — | — | D-2 | 1.5 | — | — | S1/S2 | 70/30 | 3.66 |
| RZ-4 | A-1 | 85.5 | Z1-4 | 1.8 | B2-1 | 11.2 | — | — | D-2 | 1.5 | — | — | S1/S2 | 70/30 | 5.41 |
| RZ-5 | A-1 | 83.0 | B1-1 | 2.6 | Z2-1 | 12.9 | — | — | D-2 | 1.5 | — | — | S1/S2 | 70/30 | 3.82 |
| RZ-6 | A-14 | 78.6 | Z1-1 | 6.2 | B2-1 | 13.7 | — | — | D-2 | 1.5 | — | — | S1/S2 | 70/30 | 2.38 |
| RZ-7 | A-14 | 79.8 | Z1-2 | 5.0 | B2-1 | 13.7 | — | — | D-2 | 1.5 | — | — | S1/S2 | 70/30 | 4.22 |
| RZ-8 | A-14 | 79.0 | Z1-3 | 5.8 | B2-1 | 13.7 | — | — | D-2 | 1.5 | — | — | S1/S2 | 70/30 | 3.66 |
| RZ-9 | A-14 | 80.0 | Z1-4 | 4.8 | B2-1 | 13.7 | — | — | D-2 | 1.5 | — | — | S1/S2 | 70/30 | 5.41 |
| RZ-10 | A-14 | 75.9 | B1-1 | 6.9 | Z2-1 | 15.7 | — | — | D-2 | 1.5 | — | — | S1/S2 | 70/30 | 3.82 |

Pattern forming method (1): ArF exposure, alkali development (positive), Examples 1-1 to 1-59, and Comparative Examples X1-1 to X1-5

Each of the resist compositions described in Tables 9 and 10 was applied onto a 6-inch Si wafer having been subjected to hexamethyldisilazane (HMDS) treatment in advance, using a spin coater Mark8 manufactured by Tokyo Electron Ltd., and dried on a hot plate at 100° C. for 60 seconds to obtain a resist film having a film thickness of 90 nm. Here, 1 inch is 0.0254 m.

The wafer on which the resist film was formed was subjected to pattern exposure through an exposure mask using an ArF excimer laser scanner (manufactured by ASML, PAS5500/1500, wavelength: 193 nm, NA: 0.50). Subsequently, the resist film was baked at a temperature of 115° C. for 60 seconds, then developed with a 2.38 mass % aqueous tetramethyl ammonium hydroxide solution (TMAHaq) for 30 seconds, rinsed with pure water, and then spin-dried. This provided a resist pattern of a 1:1 line-and-space pattern having a line width of 50 nm.

### Performance Evaluation

### LWR (Line Width Roughness) Performance

For a 50 nm 1:1 line-and-space pattern resolved at the optimal exposure dose for resolving a line pattern having an average line width of 50 nm, line widths at 50 points were measured when observed from above the pattern using a critical dimension scanning electron microscope (SEM (Hitachi, Ltd., S-9380II)), and the standard deviation (a) of the line widths was determined. The measurement variation of the line widths was evaluated on the basis of 36, and the value of 3a was defined as LWR (nm). The smaller the value of LWR, the better the LWR performance. The LWR is preferably 4.8 nm or less, more preferably 4.2 nm or less, and particularly preferably 3.9 nm or less.

### Pattern Profile

In the 1:1 line-and-space pattern having a line width of 50 nm, the pattern cross-sectional profile of the line portion was visually observed using a scanning electron microscope (S-4800 manufactured by Hitachi, Ltd.). The pattern cross-sectional profile was determined to be any one of “square”, “tapered”, “slightly tapered”, “reverse-tapered”, and “slightly reverse-tapered”.

The “tapered” and the “slightly tapered” refer to profiles in which the width of the line portion gradually increases from the upper portion of the pattern toward the lower portion of the pattern. The “slightly tapered” has a smaller increase rate of the width of the line portion than the “tapered”.

The “reverse-tapered” and the “slightly reverse-tapered” refer to profiles in which the width of the line portion gradually decreases from the upper portion of the pattern toward the lower portion of the pattern. The “slightly reverse-tapered” has a smaller decrease rate of the width of the line portion than the “reverse-tapered”.

The pattern cross-sectional profile is preferably square.

The results will be described in Tables 9 to 10.

TABLE 9

| | Resist composition | LWR (nm) | Pattern profile |
|---|---|---|---|
| Example 1-1 | RA-1 | 3.6 | Square |
| Example 1-2 | RA-2 | 3.6 | Square |
| Example 1-3 | RA-3 | 4.4 | Square |
| Example 1-4 | RA-4 | 3.9 | Square |
| Example 1-5 | RA-5 | 3.6 | Square |
| Example 1-6 | RA-6 | 3.7 | Square |
| Example 1-7 | RA-7 | 3.8 | Square |
| Example 1-8 | RA-8 | 3.8 | Square |
| Example 1-9 | RA-9 | 3.7 | Square |
| Example 1-10 | RA-10 | 3.6 | Square |
| Example 1-11 | RA-11 | 3.6 | Square |
| Example 1-12 | RA-12 | 3.8 | Square |
| Example 1-13 | RA-13 | 3.5 | Square |
| Example 1-14 | RA-14 | 3.8 | Square |
| Example 1-15 | RA-15 | 4.5 | Square |
| Example 1-16 | RA-16 | 3.5 | Square |
| Example 1-17 | RA-17 | 4.4 | Square |
| Example 1-18 | RA-18 | 3.9 | Square |
| Example 1-19 | RA-19 | 4.4 | Square |
| Example 1-20 | RA-20 | 3.7 | Square |
| Example 1-21 | RA-21 | 3.9 | Square |
| Example 1-22 | RA-22 | 3.5 | Square |
| Example 1-23 | RA-23 | 3.6 | Square |
| Example 1-24 | RA-24 | 3.6 | Square |
| Example 1-25 | RA-25 | 3.7 | Square |
| Example 1-26 | RA-26 | 3.6 | Square |
| Example 1-27 | RA-27 | 3.6 | Square |
| Example 1-28 | RA-28 | 3.6 | Square |
| Example 1-29 | RA-29 | 3.8 | Square |
| Example 1-30 | RA-30 | 3.6 | Square |
| Example 1-31 | RA-31 | 3.8 | Square |
| Example 1-32 | RA-32 | 3.7 | Square |

TABLE 10

| | Resist composition | LWR (nm) | Pattern profile |
|---|---|---|---|
| Example 1-33 | RA-33 | 3.9 | Square |
| Example 1-34 | RA-34 | 3.6 | Square |
| Example 1-35 | RA-35 | 3.5 | Square |
| Example 1-36 | RA-36 | 4.0 | Square |
| Example 1-37 | RA-37 | 3.5 | Square |
| Example 1-38 | RA-38 | 3.9 | Square |
| Example 1-39 | RA-39 | 3.8 | Square |
| Example 1-40 | RA-40 | 3.9 | Square |
| Example 1-41 | RA-41 | 3.7 | Square |
| Example 1-42 | RA-42 | 4.1 | Square |
| Example 1-43 | RA-43 | 3.6 | Square |
| Example 1-44 | RA-44 | 3.9 | Square |
| Example 1-45 | RA-45 | 3.9 | Square |
| Example 1-46 | RA-46 | 3.5 | Square |
| Example 1-47 | RA-47 | 4.2 | Square |
| Example 1-48 | RA-48 | 3.6 | Square |
| Example 1-49 | RA-49 | 3.9 | Square |
| Example 1-50 | RA-50 | 3.8 | Square |
| Example 1-51 | RA-51 | 3.8 | Square |
| Example 1-52 | RA-52 | 3.6 | Square |
| Example 1-53 | RA-53 | 3.9 | Square |
| Example 1-54 | RA-54 | 3.9 | Square |
| Example 1-55 | RA-55 | 3.7 | Square |
| Example 1-56 | RA-56 | 3.8 | Square |
| Example 1-57 | RA-63 | 4.2 | Square |
| Example 1-58 | RA-64 | 3.7 | Square |
| Example 1-59 | RA-65 | 3.9 | Square |
| Comparative | RZ-1 | 4.9 | Tapered |
| Example X1-1 | | | |
| Comparative | RZ-2 | 4.9 | Tapered |
| Example X1-2 | | | |
| Comparative | RZ-3 | 5.2 | Slightly tapered |
| Example X1-3 | | | |
| Comparative | RZ-4 | 4.9 | Tapered |
| Example X1-4 | | | |
| Comparative | RZ-5 | 5.3 | Slightly tapered |
| Example X1-5 | | | |

Pattern forming method (2): ArF exposure, organic-solvent development (negative), Examples 2-1 to 2-59, and Comparative Examples X₂-1 to X₂-5

Each of the resist compositions described in Tables 11 and 12 was applied onto a 6-inch Si wafer having been subjected to hexamethyldisilazane (HMDS) treatment in advance, using a spin coater Mark8 manufactured by Tokyo Electron Ltd., and dried on a hot plate at 100° C. for 60 seconds to obtain a resist film having a film thickness of 90 nm. Here, 1 inch is 0.0254 m.

The wafer on which the resist film was formed was subjected to pattern exposure through an exposure mask using an ArF excimer laser scanner (manufactured by ASML, PAS5500/1500, wavelength: 193 nm, NA: 0.50). Subsequently, the resist film was baked at a temperature of 115° C. for 60 seconds, then developed with n-butyl acetate for 30 seconds, and spin-dried. This provided a resist pattern of a 1:1 line-and-space pattern having a line width of 50 nm.

The LWR performance and the pattern profiles were evaluated by the same methods as in the above-described performance evaluation of the pattern forming method (1).

The results will be described in Table 11.

TABLE 11

| | Resist composition | LWR (nm) | Pattern profile |
|---|---|---|---|
| Example 2-1 | RA-1 | 3.8 | Square |
| Example 2-2 | RA-2 | 3.8 | Square |
| Example 2-3 | RA-3 | 4.6 | Square |
| Example 2-4 | RA-4 | 4.1 | Square |
| Example 2-5 | RA-5 | 3.8 | Square |
| Example 2-6 | RA-6 | 3.9 | Square |
| Example 2-7 | RA-7 | 4.0 | Square |
| Example 2-8 | RA-8 | 4.0 | Square |
| Example 2-9 | RA-9 | 3.9 | Square |
| Example 2-10 | RA-10 | 3.8 | Square |
| Example 2-11 | RA-11 | 3.8 | Square |
| Example 2-12 | RA-12 | 4.0 | Square |
| Example 2-13 | RA-13 | 3.7 | Square |
| Example 2-14 | RA-14 | 4.0 | Square |
| Example 2-15 | RA-15 | 4.7 | Square |
| Example 2-16 | RA-16 | 3.7 | Square |
| Example 2-17 | RA-17 | 4.6 | Square |
| Example 2-18 | RA-18 | 4.1 | Square |
| Example 2-19 | RA-19 | 4.6 | Square |
| Example 2-20 | RA-20 | 3.9 | Square |
| Example 2-21 | RA-21 | 4.1 | Square |
| Example 2-22 | RA-22 | 3.7 | Square |
| Example 2-23 | RA-23 | 3.8 | Square |
| Example 2-24 | RA-24 | 3.8 | Square |
| Example 2-25 | RA-25 | 3.9 | Square |
| Example 2-26 | RA-26 | 3.8 | Square |
| Example 2-27 | RA-27 | 3.8 | Square |
| Example 2-28 | RA-28 | 3.8 | Square |
| Example 2-29 | RA-29 | 4.0 | Square |
| Example 2-30 | RA-30 | 3.8 | Square |
| Example 2-31 | RA-31 | 4.0 | Square |
| Example 2-32 | RA-32 | 3.9 | Square |

TABLE 12

| | Resist composition | LWR (nm) | Pattern profile |
|---|---|---|---|
| Example 2-33 | RA-33 | 4.1 | Square |
| Example 2-34 | RA-34 | 3.8 | Square |
| Example 2-35 | RA-35 | 3.7 | Square |
| Example 2-36 | RA-36 | 4.2 | Square |
| Example 2-37 | RA-37 | 3.7 | Square |
| Example 2-38 | RA-38 | 4.1 | Square |
| Example 2-39 | RA-39 | 4.0 | Square |
| Example 2-40 | RA-40 | 4.1 | Square |
| Example 2-41 | RA-41 | 3.9 | Square |
| Example 2-42 | RA-42 | 4.3 | Square |
| Example 2-43 | RA-43 | 3.8 | Square |
| Example 2-44 | RA-44 | 4.1 | Square |
| Example 2-45 | RA-45 | 4.1 | Square |
| Example 2-46 | RA-46 | 3.7 | Square |
| Example 2-47 | RA-47 | 4.4 | Square |
| Example 2-48 | RA-48 | 3.8 | Square |
| Example 2-49 | RA-49 | 4.1 | Square |
| Example 2-50 | RA-50 | 4.0 | Square |
| Example 2-51 | RA-51 | 4.0 | Square |
| Example 2-52 | RA-52 | 3.8 | Square |
| Example 2-53 | RA-53 | 4.1 | Square |
| Example 2-54 | RA-54 | 4.1 | Square |
| Example 2-55 | RA-55 | 3.9 | Square |
| Example 2-56 | RA-56 | 4.0 | Square |
| Example 2-57 | RA-63 | 4.4 | Square |
| Example 2-58 | RA-64 | 3.9 | Square |
| Example 2-59 | RA-65 | 4.1 | Square |
| Comparative | RZ-1 | 5.1 | Reverse-tapered |
| Example X2-1 | | | |
| Comparative | RZ-2 | 5.1 | Reverse-tapered |
| Example X2-2 | | | |
| Comparative | RZ-3 | 5.4 | Slightly reverse- |
| Example X2-3 | | | tapered |
| Comparative | RZ-4 | 5.1 | Reverse-tapered |
| Example X2-4 | | | |
| Comparative | RZ-5 | 5.5 | Slightly reverse- |
| Example X2-5 | | | tapered |

EUV exposure

### Preparation of Resist Compositions

The same procedures as in the above-described preparation of the resist compositions (RA-1 to RA-87 and RZ-1 to RZ-10) were performed except that the solid-content concentration was changed from 4.0 mass % to 2.0 mass %, and the filtering of the obtained mixed solution through a polyethylene filter having a pore size of 0.02 m was changed to filtering of the obtained mixed solution first through a polyethylene filter having a pore size of 50 nm, then through a nylon filter having a pore size of 10 nm, and finally through a polyethylene filter having a pore size of 5 nm in this order, to prepare resist compositions (ERA-1 to ERA-87 and ERZ-1 to ERZ-10). In other words, the types and contents (mass %) of the components other than the solvents, the types of the solvents, and the mass ratios of the solvents included in ERA-1 to ERA-87 and ERZ-1 to ERZ-10 are respectively the same as those described above for RA-1 to RA-87 and RZ-1 to RZ-10 described in Tables 5 to 8.

Pattern forming method (3): EUV exposure, alkali development (positive), Examples 3-1 to 3-41 and Comparative Examples X₃-1 to X₃-5

An underlayer film-forming composition AL412 (manufactured by Brewer Science, Inc.) was applied onto a silicon wafer, and baked at 205° C. for 60 seconds to form an underlayer film having a film thickness of 20 nm. On the underlayer film, a resist composition described in Tables 13 and 14 was applied and baked at 100° C. for 60 seconds to form a resist film having a film thickness of 30 nm.

An EUV exposure apparatus (manufactured by Exitech Ltd., Micro Exposure Tool, NA: 0.3, Quadrupole, outer sigma: 0.68, inner sigma: 0.36) was used to subject the obtained silicon wafer having the resist film to pattern irradiation. Note that the reticle employed was a mask having a line size of 25 nm and line:space=1:1.

The exposed resist film was baked at 90° C. for 60 seconds, subsequently developed with an aqueous tetramethylammonium hydroxide solution (2.38 mass %) for 30 seconds, and subsequently rinsed with pure water for 30 seconds. Subsequently, this was spin-dried to obtain a positive pattern.

### Performance Evaluation

### LWR Performance

For a 25 nm (1:1) line-and-space pattern resolved at the optimal exposure dose for resolving a line pattern having an average line width of 25 nm, line widths at 50 points were measured when observed from above the pattern using a critical dimension scanning electron microscope (SEM (Hitachi, Ltd., S-9380II)), and the standard deviation (σ) of the line widths was determined. The measurement variation of the line widths was evaluated on the basis of 3σ, and the value of 3σ was defined as LWR (nm). The smaller the value of LWR, the better the LWR performance. The LWR is preferably 4.5 nm or less, more preferably 4.0 nm or less, and particularly preferably 3.7 nm or less.

### Pattern Profile

In the 1:1 line-and-space pattern having a line width of 25 nm, the pattern cross-sectional profile of the line portion was visually observed using a scanning electron microscope (S-4800 manufactured by Hitachi, Ltd.). The pattern cross-sectional profile was determined to be any one of “square”, “tapered”, “slightly tapered”, “reverse-tapered”, and “slightly reverse-tapered”. The cross-sectional profile is preferably square.

The results will be described in Tables 13 to 14.

TABLE 13

| | Resist composition | LWR (nm) | Pattern profile |
|---|---|---|---|
| Example 3-1 | ERA-1 | 3.4 | Square |
| Example 3-2 | ERA-2 | 3.4 | Square |
| Example 3-3 | ERA-3 | 4.2 | Square |
| Example 3-4 | ERA-12 | 3.6 | Square |
| Example 3-5 | ERA-13 | 3.3 | Square |
| Example 3-6 | ERA-14 | 3.6 | Square |
| Example 3-7 | ERA-22 | 3.3 | Square |
| Example 3-8 | ERA-29 | 3.6 | Square |
| Example 3-9 | ERA-31 | 3.6 | Square |
| Example 3-10 | ERA-34 | 3.4 | Square |
| Example 3-11 | ERA-37 | 3.3 | Square |
| Example 3-12 | ERA-43 | 3.4 | Square |
| Example 3-13 | ERA-46 | 3.3 | Square |
| Example 3-14 | ERA-57 | 3.3 | Square |
| Example 3-15 | ERA-58 | 3.3 | Square |
| Example 3-16 | ERA-59 | 3.7 | Square |
| Example 3-17 | ERA-60 | 4.2 | Square |
| Example 3-18 | ERA-61 | 4.3 | Square |
| Example 3-19 | ERA-62 | 3.3 | Square |
| Example 3-20 | ERA-66 | 3.4 | Square |
| Example 3-21 | ERA-67 | 3.4 | Square |
| Example 3-22 | ERA-68 | 3.7 | Square |
| Example 3-23 | ERA-69 | 3.4 | Square |

TABLE 14

| | Resist composition | LWR (nm) | Pattern profile |
|---|---|---|---|
| Example 3-24 | ERA-70 | 4.3 | Square |
| Example 3-25 | ERA-71 | 3.7 | Square |
| Example 3-26 | ERA-72 | 3.6 | Square |
| Example 3-27 | ERA-73 | 3.7 | Square |
| Example 3-28 | ERA-74 | 3.5 | Square |
| Example 3-29 | ERA-75 | 3.8 | Square |
| Example 3-30 | ERA-76 | 3.4 | Square |
| Example 3-31 | ERA-77 | 3.4 | Square |
| Example 3-32 | ERA-78 | 3.7 | Square |
| Example 3-33 | ERA-79 | 3.5 | Square |
| Example 3-34 | ERA-80 | 3.8 | Square |
| Example 3-35 | ERA-81 | 4.0 | Square |
| Example 3-36 | ERA-82 | 3.7 | Square |
| Example 3-37 | ERA-83 | 3.6 | Square |
| Example 3-38 | ERA-84 | 3.5 | Square |
| Example 3-39 | ERA-85 | 3.4 | Square |
| Example 3-40 | ERA-86 | 3.9 | Square |
| Example 3-41 | ERA-87 | 4.2 | Square |
| Comparative | ERZ-6 | 4.8 | Tapered |
| Example X3-1 | | | |
| Comparative | ERZ-7 | 4.8 | Tapered |
| Example X3-2 | | | |
| Comparative | ERZ-8 | 5.1 | Slightly tapered |
| Example X3-3 | | | |
| Comparative | ERZ-9 | 4.8 | Tapered |
| Example X3-4 | | | |
| Comparative | ERZ-10 | 5.2 | Slightly tapered |
| Example X3-5 | | | |

### Pattern Forming Method (4): EUV Exposure, Organic-Solvent Development (Negative), Examples 4-1 to 4-41, and Comparative Examples X4-1 to X4-5

An underlayer film-forming composition AL412 (manufactured by Brewer Science, Inc.) was applied onto a silicon wafer, and baked at 205° C. for 60 seconds to form an underlayer film having a film thickness of 20 nm. On the underlayer film, a resist composition described in Tables 15 and 16 was applied and baked at 100° C. for 60 seconds to form a resist film having a film thickness of 30 nm.

An EUV exposure apparatus (manufactured by Exitech Ltd., Micro Exposure Tool, NA: 0.3, Quadrupole, outer sigma: 0.68, inner sigma: 0.36) was used to subject the obtained silicon wafer having the resist film to pattern irradiation. Note that the reticle employed was a mask having a line size of 25 nm and line:space=1:1.

The exposed resist film was baked at 90° C. for 60 seconds, and subsequently developed with n-butyl acetate for 30 seconds; and this was spin-dried to obtain a negative pattern.

The LWR performance and pattern profiles were evaluated by the same method as in the above-described performance evaluation of the pattern forming method (3).

The results will be described in Tables 15 to 16.

TABLE 15

| | Resist composition | LWR (nm) | Pattern profile |
|---|---|---|---|
| Example 4-1 | ERA-1 | 3.6 | Square |
| Example 4-2 | ERA-2 | 3.6 | Square |
| Example 4-3 | ERA-3 | 4.4 | Square |
| Example 4-4 | ERA-12 | 3.8 | Square |
| Example 4-5 | ERA-13 | 3.5 | Square |
| Example 4-6 | ERA-14 | 3.8 | Square |
| Example 4-7 | ERA-22 | 3.5 | Square |
| Example 4-8 | ERA-29 | 3.8 | Square |
| Example 4-9 | ERA-31 | 3.8 | Square |
| Example 4-10 | ERA-34 | 3.6 | Square |
| Example 4-11 | ERA-37 | 3.5 | Square |
| Example 4-12 | ERA-43 | 3.6 | Square |
| Example 4-13 | ERA-46 | 3.5 | Square |
| Example 4-14 | ERA-57 | 3.5 | Square |
| Example 4-15 | ERA-58 | 3.5 | Square |
| Example 4-16 | ERA-59 | 3.9 | Square |
| Example 4-17 | ERA-60 | 4.4 | Square |
| Example 4-18 | ERA-61 | 4.5 | Square |
| Example 4-19 | ERA-62 | 3.5 | Square |
| Example 4-20 | ERA-66 | 3.6 | Square |
| Example 4-21 | ERA-67 | 3.6 | Square |
| Example 4-22 | ERA-68 | 3.9 | Square |
| Example 4-23 | ERA-69 | 3.6 | Square |

TABLE 16

| | Resist composition | LWR (nm) | Pattern profile |
|---|---|---|---|
| Example 4-24 | ERA-70 | 4.5 | Square |
| Example 4-25 | ERA-71 | 3.9 | Square |
| Example 4-26 | ERA-72 | 3.8 | Square |
| Example 4-27 | ERA-73 | 3.9 | Square |
| Example 4-28 | ERA-74 | 3.7 | Square |
| Example 4-29 | ERA-75 | 4.0 | Square |
| Example 4-30 | ERA-76 | 3.6 | Square |
| Example 4-31 | ERA-77 | 3.6 | Square |
| Example 4-32 | ERA-78 | 3.9 | Square |
| Example 4-33 | ERA-79 | 3.7 | Square |
| Example 4-34 | ERA-80 | 4.0 | Square |
| Example 4-35 | ERA-81 | 4.2 | Square |
| Example 4-36 | ERA-82 | 3.9 | Square |
| Example 4-37 | ERA-83 | 3.8 | Square |
| Example 4-38 | ERA-84 | 3.7 | Square |
| Example 4-39 | ERA-85 | 3.6 | Square |
| Example 4-40 | ERA-86 | 4.1 | Square |
| Example 4-41 | ERA-87 | 4.4 | Square |
| Comparative | ERZ-6 | 4.9 | Reverse-tapered |
| Example X4-1 | | | |
| Comparative | ERZ-7 | 4.9 | Reverse-tapered |
| Example X4-2 | | | |
| Comparative | ERZ-8 | 5.2 | Slightly reverse- |
| Example X4-3 | | | tapered |
| Comparative | ERZ-9 | 4.9 | Reverse-tapered |
| Example X4-4 | | | |
| Comparative | ERZ-10 | 5.3 | Slightly reverse- |
| Example X4-5 | | | tapered |

The results of Tables 9 to 16 have demonstrated that the resist compositions used in the Examples can form patterns having high LWR performance and good pattern profiles.

The present invention can provide an actinic ray-sensitive or radiation-sensitive resin composition, a resist film, and a pattern forming method that can form a pattern having high LWR performance and a good pattern profile and a method for producing an electronic device including the pattern forming method.

The present invention has been described in detail and with reference to specific embodiments thereof, however, it would be apparent to those skilled in the art that various changes and modifications can be made therein without departing from the spirit and scope of the present invention.

This application is based on a Japanese patent application (JP2023-170588) filed on Sep. 29, 2023, the contents of which are incorporated herein by reference.

What is claimed is:

1. An actinic ray-sensitive or radiation-sensitive resin composition comprising:
a resin (A) that is subjected to action of an acid to undergo an increase in polarity;
an onium salt (B-1) that generates an acid (AC_{B1}) upon irradiation with an actinic ray or a radiation; and
an onium salt (B-2) that generates an acid (AC_{B2}) upon irradiation with an actinic ray or a radiation,
wherein the acid (AC_{B1}) has a pKa larger than a pKa of the acid (AC_{B2}) by 1.0 or more,
the onium salt (B-1) contains no fluorine atom, or when the onium salt (B-1) contains a fluorine atom, a content of the fluorine atom relative to all atoms contained in the onium salt (B-1) is 3 mass % or less,
the onium salt (B-2) contains no fluorine atom, or when the onium salt (B-2) contains a fluorine atom, a content of the fluorine atom relative to all atoms contained in the onium salt (B-2) is 3 mass % or less,
the onium salt (B-1) is at least one selected from the group consisting of an onium salt represented by the following formula (b1-1) and an onium salt represented by the following formula (b1-2), and
the onium salt (B-2) is an onium salt represented by the following formula (b2-1), 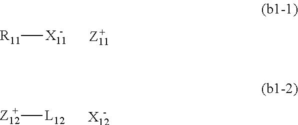
wherein, in the formula (b1-1) and the formula (b1-2), R₁ represents an organic group, L₁₂ represents a single bond or a divalent linking group, X₁₁⁻ represents —O—, —COO—, —SO₃—, or —SO₂N⁻Y(R₁₁₁)ₖ, R₁₁₁ represents an alkyl group, a cycloalkyl group, or an aryl group, Y₁₁ represents —CO—, —SO—, —SO₂—, or a single bond, k represents 0 or 1; when k represents 0, R₁₁₁ is not present, and Y₁₁ is bonded to R₁₁; when k represents 1, R₁₁₁ may be bonded to R₁₁; X₁₂⁻ represents —O—, —COO—, —SO₃—, or —SO₂N⁻Y₁₂(R₁₁₂)ₕ, R₁₁₂ represents an alkyl group, a cycloalkyl group, or an aryl group, Y₁₂ represents —CO—, —SO—, —SO₂—, or a single bond, h represents 0 or 1; when h represents 0, R₁₁₂ is not present, and Y₁₂ is bonded to L₁₂ or Z₁₂⁺; when h represents 1, R₁₁₂ may be bonded to L₁₂ or Z₁₂⁺; Z₁₁⁺ represents an organic cation, Z₁₂⁺ represents an organic cation group,
provided that R₁₁—X₁₁⁻ in the formula (b1-1) is not an anion represented by any of the following formulas (i)-1 to (i)-3 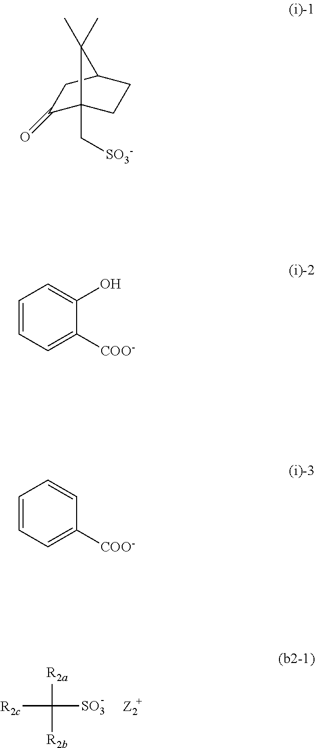
wherein, in the formula (b2-1), R₂ₐ represents an electron-withdrawing group, R_{2b} and R_{2c} each independently represent a hydrogen atom or an organic group, at least two selected from the group consisting of R₂ₐ, R_{2b}, and R_{2c} may be bonded together to form a ring, provided that R_{2b} and R_{2c} do not simultaneously represent hydrogen atoms, and Z₂⁺ represents an organic cation.

2. The actinic ray-sensitive or radiation-sensitive resin composition according to claim 1, wherein, in the formula (b2-1), R₂ₐ represents a cyano group, a nitro group, a dicyanomethyl group, or a group represented by the following formula (1A): 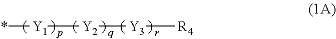
wherein, in the formula (1A), Y₁ and Y₃ each independently represent —O— or —NR₃—, R₃ represents a hydrogen atom or an alkyl group, Y₂ represents —C(═O)— or —SO₂—, R₄ represents an alkyl group, a cycloalkyl group, or an aryl group, at least two selected from the group consisting of R₃ and R₄ may be bonded together to form a ring, p and r each independently represent 0 or 1, q represents 1 or 2, and * represents a bonding site.

3. The actinic ray-sensitive or radiation-sensitive resin composition according to claim 1, wherein the onium salt (B-1) is at least one selected from the group consisting of onium salts each represented by any one of the following formulas (b1-2a) to (b1-2e) and the onium salt represented by the formula (b1-2): 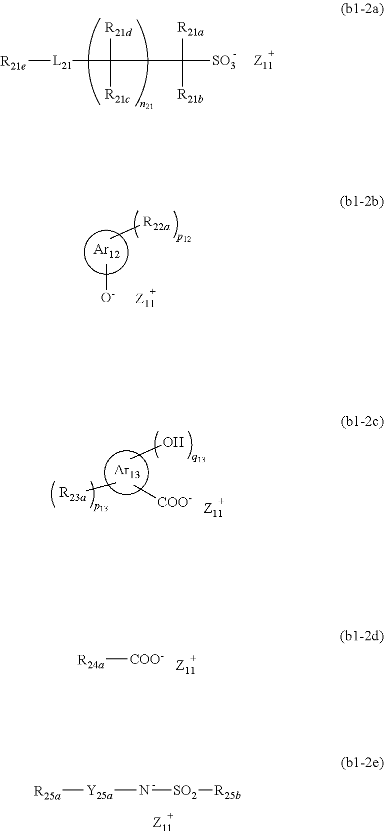
wherein, in the formula (b1-2a), R₂₁ₐ to R₂₁ₑ each independently represent a hydrogen atom or an organic group, provided that at least one selected from the group consisting of R_{21c} and R_{21d} represents a group selected from the group consisting of a cyano group, a nitro group, a group represented by the following formula (2A), and a group represented by the following formula (2B), and R₂₁ₐ and R_{21b} each do not represent groups selected from the group consisting of a cyano group, a nitro group, the group represented by the following formula (2A), and the group represented by the following formula (2B); L₂₁ represents a single bond or a divalent linking group, n₂₁ represents an integer of 1 to 4; when n₂₁ represents an integer of 2 or more, a plurality of R_{21c} may be same or different, and a plurality of R_{21d} may be same or different; at least two selected from the group consisting of R₂₁ₐ, R_{21b}, R_{21c}, R_{21d}, and L₂₁ may be bonded together to form a ring, Z₁₁⁺ represents an organic cation, 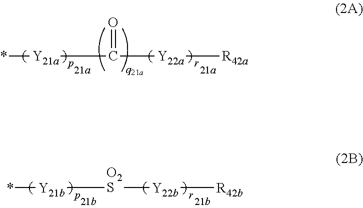
wherein, in the formula (2A), Y₂₁ₐ and Y₂₂ₐ each independently represent —O— or —NR₃₂ₐ—, R₃₂ₐ represents a hydrogen atom or an alkyl group, R₄₂ₐ represents an alkyl group, a cycloalkyl group, or an aryl group, p₂₁ₐ and r₂₁ₐ each independently represent 0 or 1, provided that p₂₁ₐ and r₂₁ₐ do not simultaneously represent 0, q₂₁ₐ represents 1 or 2, * represents a bonding site,
in the formula (2B), Y_{21b} and Y₂₂b each independently represent —O— or —NR_{32b}—, R_{32b} represents a hydrogen atom or an alkyl group, R_{42b} represents an alkyl group, a cycloalkyl group, or an aryl group, p_{21b} and r_{21b} each independently represent 0 or 1, * represents a bonding site,
in the formula (b1-2b), R₂₂ₐ represents a halogen atom, a hydroxy group, or an organic group other than a carboxyl group, Ar₁₂ represents an aromatic group, p₁₂ represents an integer of 0 or more; when p₁₂ represents an integer of 2 or more, a plurality of R₂₂ₐ may be same or different; Z₁₁⁺ represents an organic cation,
in the formula (b1-2c), Ar₁₃ represents an aromatic group, R₂₃ₐ represents a halogen atom or an organic group, p₁₃ and q₁₃ each independently represent an integer of 0 or more; when p₁₃ represents an integer of 2 or more, a plurality of R₂₃ₐ may be same or different, provided that p₁₃ and q₁₃ do not simultaneously represent 0; when q₁₃ represents 1, p₁₃ represents an integer of 1 or more; Z₁₁⁺ represents an organic cation,
in the formula (b1-2d), R₂₄ₐ represents an organic group, provided that when R₂₄ₐ has an aromatic ring, the carbon atom of —COO⁻ specified in the formula (b1-2d) is not directly bonded to the aromatic ring; Z₁₁ represents an organic cation,
in the formula (b1-2e), Y₂₅ₐ represents —CO—, —SO—, —SO₂—, or a single bond, R₂₅ₐ and R_{25b} each independently represent an alkyl group, a cycloalkyl group, or an aryl group, R₂₅ₐ and R_{25b} may be bonded together to form a ring, and Z₁₁⁺ represents an organic cation.

4. The actinic ray-sensitive or radiation-sensitive resin composition according to claim 1, further comprising a resin (D) different from the resin (A),
wherein the resin (D) has an SP value that is smaller than an SP value of the resin (A) and is 17.2 or less.

5. The actinic ray-sensitive or radiation-sensitive resin composition according to claim 1, wherein the onium salt (B-1) contains no fluorine atom.

6. The actinic ray-sensitive or radiation-sensitive resin composition according to claim 1, wherein the onium salt (B-2) contains no fluorine atom.

7. The actinic ray-sensitive or radiation-sensitive resin composition according to claim 1, wherein the resin (A) has a repeating unit represented by the following formula (AP-1): 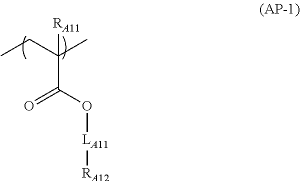
wherein, in e formula (AP-1), R_{A11} represents a hydrogen atom, a halogen atom, or an alkyl group, L_{A11} represents a single bond or a divalent linking group, and R_{A12} represents a cyclic group including an SO₂ group.

8. The actinic ray-sensitive or radiation-sensitive resin composition according to claim 1, wherein the resin (A) has a repeating unit represented by the following formula (AP-2): 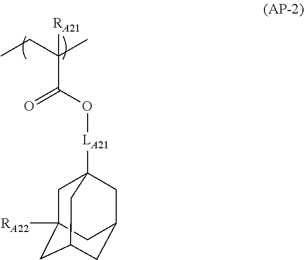
wherein, in the formula (AP-2), R_{A21} represents a hydrogen atom, a halogen atom, or an alkyl group, L_{A21} represents a single bond or a divalent linking group, and R_{A22} represents an alkyl group.

9. The actinic ray-sensitive or radiation-sensitive resin composition according to claim 1, wherein the resin (A) has a repeating unit represented by the following formula (AP-3): 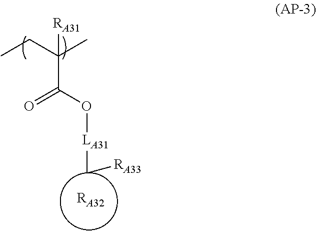
wherein, in the formula (AP-3), R_{A31} represents a hydrogen atom, a halogen atom, or an alkyl group, L_{A31} represents a single bond or a divalent linking group, R_{A32} represents an alicyclic hydrocarbon group, and R_{A33} represents a substituent having a double bond.

10. The actinic ray-sensitive or radiation-sensitive resin composition according to claim 4, wherein
among repeating units of the resin (D), a total content of repeating units containing no fluorine atom relative to all repeating units in the resin (D) is 80 mol % or more, and a content of the resin (D) relative to a total solid content in the actinic ray-sensitive or radiation-sensitive resin composition is 0.01 to 10 mass %.

11. A resist film formed with the actinic ray-sensitive or radiation-sensitive resin composition according to claim 1.

12. A pattern forming method comprising: forming, on a substrate, a resist film with the actinic ray-sensitive or radiation-sensitive resin composition according to claim 1; exposing the resist film; and developing the exposed resist film with a developer.

13. A method for producing an electronic device, the method comprising the pattern forming method according to claim 12.
